(19) United States
(12) Patent Application Publication
(10) Pub. No.: US 2026/0290466 A1
(43) Pub. Date: Sep. 24, 2026

(54) MEMORY SYSTEM

(71) Applicant: Kioxia Corporation, Tokyo (JP)

(72) Inventors: Yuki MANDAI, Tokyo (JP); Masanobu SHIRAKAWA, Chigasaki (JP)

(73) Assignee: Kioxia Corporation, Tokyo (JP)

(21) Appl. No.: 19/316,180

(22) Filed: Sep. 2, 2025

(30) Foreign Application Priority Data
Mar. 21, 2025 (JP) 2025-046698

(51) Int. Cl. G11C 16/26

(52) U.S. Cl. CPC G11C 16/26

(57) ABSTRACT

According to one embodiment, a memory system includes the following configuration. The memory device includes first and second memory cells provided in first and second layers, respectively. For the first and second memory cells, the controller converts a read bit location of first read data using a first correction value corresponding to the first layer into physical locations of the first and second memory cells with reference to a conversion table and acquires first data corresponding to the first layer. For the first and second memory cells, the controller converts a read bit location of second read data using a second correction value corresponding to the second layer into physical locations of the first and second memory cells with reference to the conversion table and acquires second data corresponding to the second layer. The first and second data are merged to acquire third data.

### CROSS-REFERENCE TO RELATED APPLICATIONS

This application is based upon and claims the benefit of priority from Japanese Patent Application No. 2025-046698, filed Mar. 21, 2025, the entire contents of which are incorporated herein by reference.

### FIELD

Embodiments described herein relate generally to a memory system.

### BACKGROUND

A memory system including a NAND flash memory capable of storing data in a nonvolatile manner and a memory controller that controls the NAND flash memory has been known.

### BRIEF DESCRIPTION OF THE DRAWINGS

FIG. 1 is a block diagram illustrating an example of a configuration of a memory system according to an embodiment.

FIG. 2 is a block diagram illustrating an example of a configuration of a memory device included in the memory system according to the embodiment.

FIG. 3 is a circuit diagram illustrating an example of a circuit configuration of a memory cell array included in the memory device according to the embodiment.

FIG. 4 is a perspective view illustrating an example of a structure of the memory cell array included in the memory device according to the embodiment.

FIG. 5 is a plan view illustrating an example of a planar layout of the memory cell array included in the memory device according to the embodiment.

FIGS. 6 to 9 are cross-sectional views illustrating one example of a cross-sectional structure of the memory cell array included in the memory device according to the embodiment.

FIG. 10 is a block diagram illustrating an example of a configuration of a sense amplifier module and a data register included in the memory device according to the embodiment.

FIG. 11 is a diagram illustrating an example of a circuit configuration of a sense amplifier unit included in the sense amplifier module according to the embodiment.

FIG. 12 is a circuit diagram illustrating an example of a connection relationship between the data register and an input/output circuit included in the memory device according to the embodiment.

FIG. 13 is a schematic diagram illustrating an example of data allocation used in the memory system according to the embodiment.

FIG. 14 is a schematic diagram illustrating an example of threshold voltage distribution of the memory cell transistors for each layer in the memory system according to the embodiment.

FIG. 15 is a flowchart illustrating an example of operation processing at the time of power input in the memory system according to the embodiment.

FIG. 16 is a diagram illustrating an example of a connection relationship between a physical location of the memory cell transistor, and a column address, and an input/output bus in the memory device according to the embodiment.

FIG. 17 is a diagram illustrating an example of conversion for reproducing, into a physical location, a read bit location of read data in the memory system according to the embodiment.

FIG. 18 is a diagram illustrating another example of the connection relationship between the physical location of the memory cell transistor, and the column address, and the input/output bus in the memory device according to the embodiment.

FIG. 19 is a diagram illustrating another example of conversion for reproducing, into the physical location, the read bit location of read data in the memory system according to the embodiment.

FIG. 20 is a diagram illustrating an example of a connection relationship between a physical location of a memory cell transistor, and a column address, an input/output bus in a redundancy memory unit provided in a target page of the memory system according to the embodiment.

FIG. 21 is a diagram illustrating an example of reproducing, into the physical location, the read bit location of the read data in a case where there is no replacement of the main column with the redundancy column according to the embodiment and in a case where there is a replacement thereof.

FIG. 22 is a diagram illustrating a circuit configuration for replacing a defective column in a target page with the redundancy column according to the embodiment.

FIG. 23 is a flowchart illustrating an example of a read operation in the memory system according to the embodiment.

FIG. 24 is a flowchart illustrating an example of a retry sequence in the read operation according to the embodiment.

FIGS. 25 and 26 are diagrams illustrating a concept of tracking in the retry sequence according to the embodiment.

FIG. 27 is a flowchart illustrating an example of tracking in the retry sequence according to the embodiment.

FIG. 28 is a diagram illustrating a counter that counts the number of on-cells for each group in the memory system according to the embodiment.

FIG. 29 is a flowchart illustrating processing of group-by-group shift read and merging group-by-group shift read results in the read operation according to the embodiment.

FIGS. 30, 31 and 32 are diagrams illustrating a conversion for reproducing, into the physical location, the read bit location of the read data and a method of merging the shift read results for each group in the memory system according to the embodiment.

FIG. 33 is a diagram illustrating conversion from read data reproduced into a physical location to a read bit location according to the embodiment.

FIGS. 34 to 41 are diagrams illustrating an adjacency influence degree set based on a state of a target memory cell transistor and a state of an adjacent memory cell transistor according to the embodiment.

FIGS. 42 and 43 are a flowchart illustrating an example of reading using adjacency correction in the retry sequence according to the embodiment.

FIG. 44 is a diagram illustrating an example in which the read bit location to which the state information calculated from the reading result of the target page is allocated is converted into the physical location of the memory cell transistor according to the embodiment.

FIG. 45 is a diagram illustrating the adjacency influence degree of the reading bit acquired based on the adjacency influence degree table according to the embodiment.

FIG. 46 is a diagram illustrating a state of shift read according to each adjacency influence degree with respect to a lower layer group according to the embodiment.

FIG. 47 is a diagram illustrating a method of shift read and merging shift read results according to each adjacency influence degree with respect to the lower layer group according to the embodiment.

FIG. 48 is a diagram illustrating a state of shift read according to each adjacency influence degree with respect to a middle layer group according to the embodiment.

FIG. 49 is a diagram illustrating a method of shift read and merging shift read results according to each adjacency influence degree with respect to the middle layer group according to the embodiment.

FIG. 50 is a diagram illustrating a state of shift read according to each adjacency influence degree with respect to an upper layer group according to the embodiment.

FIG. 51 is a diagram illustrating a method of shift read and merging shift read results according to each adjacency influence degree with respect to the upper layer group according to the embodiment.

FIG. 52 is a diagram illustrating conversion from read data reproduced into a physical location to a read bit location according to the embodiment.

FIG. 53 is a flowchart illustrating an example of soft bit data generation processing in the memory system according to the embodiment.

FIG. 54 is a schematic diagram illustrating an example of setting of an LLR table in the memory system according to the embodiment.

FIG. 55 is a flowchart illustrating an example of a read voltage optimization operation in the memory system according to the embodiment.

FIG. 56 is a schematic diagram illustrating an example of fail bits between two adjacent states in the memory system according to the embodiment.

FIG. 57 is a table illustrating an example of setting of the shift amount of the read voltage in shift amount calculation processing in the memory system according to the embodiment.

FIG. 58 is a table illustrating an example of a shift value history table used in the memory system according to the embodiment.

FIG. 59 is a flowchart illustrating an example of shift amount calculation processing of the memory system according to the embodiment.

### DETAILED DESCRIPTION

In general, according to one embodiment, a memory system includes a memory device and a controller configured to control the memory device. The memory device includes: a first memory cell provided in a first layer above a substrate; a second memory cell provided in a second layer above the first layer; a first word line connected to the first memory cell and the second memory cell; a first bit line connected to the first memory cell; and a second bit line connected to the second memory cell. The controller is configured to: store a first conversion table in which read bit locations of read data obtained by reading from the first memory cell and the second memory cell are associated with physical locations of the first memory cell and the second memory cell; cause the memory device to execute reading using a first correction value of a first read voltage corresponding to the first layer on the first memory cell and the second memory cell; receive first read data read using the first correction value from the memory device; convert a read bit location of the first read data into physical locations of the first memory cell and the second memory cell with reference to the first conversion table; acquire first data corresponding to the first layer from first conversion data converted into the physical locations; cause the memory device to execute read using a second correction value of the first read voltage corresponding to the second layer on the first memory cell and the second memory cell; receive second read data read using the second correction value from the memory device; convert a read bit location of the second read data into the physical locations of the first memory cell and the second memory cell with reference to the first conversion table; acquire second data corresponding to the second layer from second conversion data converted into the physical locations; and merge the first data and the second data to acquire third data.

Hereinafter, embodiments will be described with reference to the drawings. In the following description, components having the same function and configuration are denoted by the same reference numerals. In addition, the following embodiment exemplifies an apparatus and a method for embodying the technical idea of this example embodiment, and does not identify the material, shape, structure, arrangement, and the like of the components as follows.

The functional block can be implemented as any one of hardware and computer software or a combination of both. It is not essential that the functional blocks are distinguished as in the following examples. For example, some functions may be executed by a functional block different from the illustrated functional block.

Further, the exemplary functional blocks may be divided into finer functional sub-blocks.

### EMBODIMENTS

Hereinafter, a memory system 1 according to an example embodiment will be described.

### 1. Configuration

### 1.1 Configuration of Memory System 1

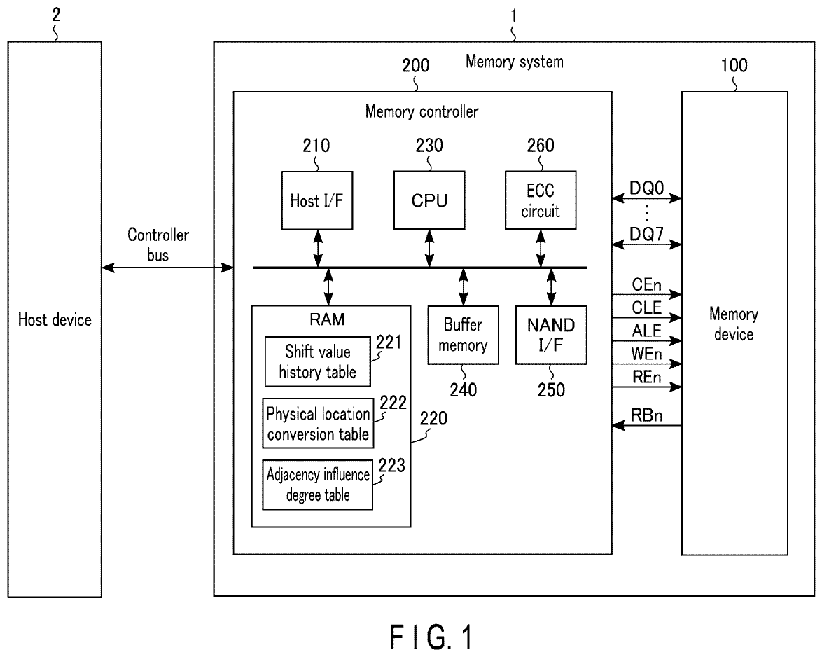

FIG. 1 is a block diagram illustrating an example of a configuration of a memory system 1 according to an embodiment. As illustrated in FIG. 1, the memory system 1 includes, for example, a memory device 100 and a memory controller 200. A combination of the memory controller 200 and the memory device 100 may configure one semiconductor memory device. Examples of such a semiconductor memory device include a memory card such as an SD™ card, a solid state drive (SSD), and the like.

The memory device 100 includes a plurality of memory cell transistors and stores data in a nonvolatile manner. The memory device 100 is, for example, a three-dimensional stacked NAND flash memory in which a plurality of memory cell transistors is three-dimensionally stacked above a semiconductor substrate. The memory device 100 is connected to the memory controller 200 by a NAND bus. The memory device 100 operates based on an instruction from the memory controller 200. For example, an 8-bit signal DQ [7:0] is transmitted and received between the memory device 100 and the memory controller 200. The signal DQ [7:0] may include data, an address, a command, and the like.

In addition, the memory device 100 receives, for example, a chip enable signal CEn, a command latch enable signal CLE, an address latch enable signal ALE, a write enable signal WEn, and a read enable signal REn from the memory controller 200. The chip enable signal CEn is a signal for enabling the memory device 100, and is asserted at, for example, a Low (“L”) level. The command latch enable signal CLE is a signal indicating that the signal DQ is a command, and is asserted at a high (“H”) level, for example. The address latch enable signal ALE is a signal indicating that the signal DQ is an address, and is asserted at the “H” level, for example. The write enable signal WEn is a signal for taking the received signal into the memory device 100, and is asserted at a “L” level, for example, every time a command, an address, data, or the like is received from the memory controller 200. That is, the signal DQ [7:0] is taken into the memory device 100 every time the write enable signal WEn is toggled. The read enable signal REn is a signal for the memory controller 200 to read data from the memory device 100, and is asserted at the “L” level, for example.

In addition, the memory device 100 transmits a ready/busy signal RBn to the memory controller 200. The ready/busy signal RBn is a signal indicating whether the memory device 100 is in a ready state or a busy state. The ready state is a state in which the memory device 100 can receive a command from the memory controller 200. The busy state is a state in which the memory device 100 cannot receive a command from the memory controller 200. For example, an “H” level of the ready/busy signal RBn indicates that the memory device 100 is in a ready state, and an “L” level of the ready/busy signal RBn indicates that the memory device 100 is in a busy state.

### 1.2 Configuration of Memory Controller 200

Next, a configuration of the memory controller 200 included in the memory system 1 according to the embodiment will be described. In response to a request (instruction) from the host device 2, the memory controller 200 instructs the memory device 100 to perform a data read operation, a data write operation, a data erase operation, and the like. In addition, the memory controller 200 manages a storage space of the memory device 100. The memory controller 200 includes, for example, a host interface circuit (host I/F) 210, an embedded memory (random access memory (RAM)) 220, a processor (central processing unit (CPU)) 230, a buffer memory 240, a NAND interface circuit (NAND I/F) 250, and an error checking and correcting (ECC) circuit 260.

The host interface circuit 210 is connected to the host device 2 via a controller bus and manages communication with the host device 2. The host interface circuit 210 transfers a request and data received from the host device 2 to the CPU 230 and the buffer memory 240. In addition, the host interface circuit 210 transfers data in the buffer memory 240 to the host device 2 in response to an instruction from the CPU 230.

The RAM 220 is used as, for example, a work area of the CPU 230. The RAM 220 stores firmware for managing the memory device 100, various management tables, and the like. The RAM 220 stores, for example, a shift value history table 221, a physical location conversion table 222, and an adjacency influence degree table 223.

Details of the shift value history table 221, the physical location conversion table 222, and the adjacency influence degree table 223 will be described later. As the RAM 220, for example, a semiconductor memory such as a static random access memory (SRAM) or a dynamic random access memory (DRAM) is used.

The CPU 230 controls the entire operation of the memory controller 200. For example, upon receiving a read request including a command and a logical address from the host device 2, the CPU 230 issues a read instruction including a command and a physical address in response to the received read request. Then, the issued read instruction is transferred to the memory device 100, and the memory device 100 executes the read operation based on the read instruction. The CPU 230 can execute the write operation and the erase operation similarly to the read operation. In addition, the CPU 230 can execute various processing for managing the memory device 100, such as wear leveling. Furthermore, the CPU 230 can execute various arithmetic processing such as data encryption processing and randomization processing.

The buffer memory 240 temporarily stores read data received by the memory controller 200 from the memory device 100. In addition, the buffer memory 240 temporarily stores write data and the like received by the memory controller 200 from the host device 2. As the buffer memory 240, for example, a semiconductor memory such as a DRAM is used. The buffer memory 240 may be externally connected to the memory controller 200 or may be integrated with the RAM 220.

The NAND interface circuit 250 is connected to the memory device 100 via the NAND bus, and manages communication between the memory device 100 and the memory controller 200. The NAND interface circuit 250 transfers the instruction issued by the CPU 230 to the memory device 100. At the time of the read operation, the NAND interface circuit 250 transfers the read data received from the memory device 100 to the buffer memory 240. At the time of the write operation, the NAND interface circuit 250 transfers the write data held in the buffer memory 240 to the memory device 100.

The error checking and correcting circuit 260 executes processing related to error correction of data stored in the memory device 100. During the write operation, the error checking and correcting circuit 260 generates a parity based on the write data received from the host device 2 and gives the generated parity to the write data. During the read operation, the error checking and correcting circuit 260 generates a syndrome based on the read data received from the memory device 100, and detects and corrects an error in the read data based on the generated syndrome.

### 1.3 Configuration of Memory Device 100

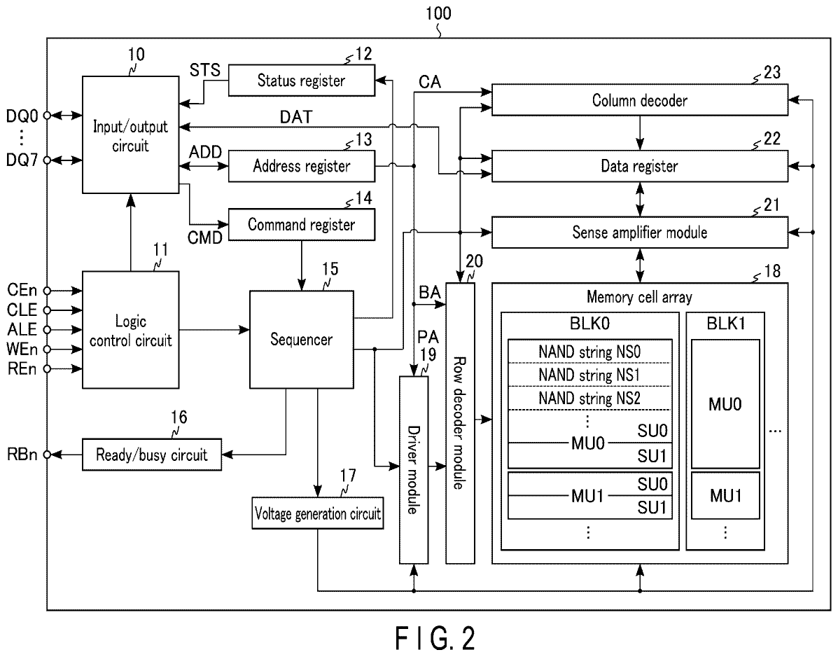

Next, a configuration of the memory device 100 included in the memory system 1 according to the embodiment will be described. FIG. 2 is a block diagram illustrating an example of a configuration of the memory device 100 included in the memory system 1 according to the embodiment. In FIG. 2, a connection of each block is indicated by an arrow line, but the connection between the blocks is not limited to the illustrated connection.

As illustrated in FIG. 2, the memory device 100 includes, for example, an input/output circuit 10, a logic control circuit 11, a status register 12, an address register 13, a command register 14, a sequencer 15, a ready/busy circuit 16, a voltage generation circuit 17, a memory cell array 18, a driver module 19, a row decoder module 20, a sense amplifier module 21, a data register 22, and a column decoder 23.

The input/output circuit 10 controls input and output of a signal DQ [7:0] between the memory device 100 and the memory controller 200. The input/output circuit 10 transmits data DAT (write data) received from the memory controller 200 to the data register 22. The input/output circuit 10 transmits an address ADD received from the memory controller 200 to the address register 13. The input/output circuit 10 transmits a command CMD received from the memory controller 200 to the command register 14. The input/output circuit 10 transmits status information STS received from the status register 12, data DAT (read data) received from the data register 22, address ADD received from the address register 13, and the like to the memory controller 200.

The logic control circuit 11 receives, for example, a chip enable signal CEn, a command latch enable signal CLE, an address latch enable signal ALE, a write enable signal WEn, and a read enable signal REn from the memory controller 200. Then, the logic control circuit 11 controls the input/output circuit 10 and the sequencer 15 according to the signals received from the memory controller 200.

The status register 12 temporarily stores the status information STS received from the sequencer 15, for example, in each of the write operation, the read operation, and the erase operation. The status information STS includes, for example, information for notifying the memory controller 200 whether or not the write operation, the read operation, the erase operation, and the like are normally ended.

The address register 13 temporarily stores the address ADD received from the input/output circuit 10. The address ADD may include, for example, a page address PA, a block address BA, a column address CA, and the like. For example, the address register 13 transmits the page address PA to the driver module 19, transmits the block address BA to the row decoder module 20, and transmits the column address CA to the column decoder 23.

The command register 14 temporarily stores the command CMD received from the input/output circuit 10. The command CMD is associated with an operation that the memory device 100 can execute. The command CMD stored by the command register 14 is referred to by the sequencer 15.

The sequencer 15 controls the entire operation of the memory device 100. For example, the sequencer 15 can control the status register 12, the ready/busy circuit 16, the voltage generation circuit 17, the driver module 19, the row decoder module 20, the sense amplifier module 21, the data register 22, and the column decoder 23. Then, the sequencer 15 executes the write operation, the read operation, the erase operation, and the like according to the command CMD stored by the command register 14.

The ready/busy circuit 16 generates a ready/busy signal RBn based on the operation state of the sequencer 15. Then, the ready/busy circuit 16 transmits the generated ready/busy signal RBn to the memory controller 200.

The voltage generation circuit 17 generates a voltage necessary for a write operation, a read operation, an erase operation, and the like under the control of the sequencer 15. Then, the voltage generation circuit 17 supplies the generated voltage to the memory cell array 18, the driver module 19, the sense amplifier module 21, the data register 22, the column decoder 23, and the like.

The memory cell array 18 includes a plurality of blocks BLK (BLK1, BLK2, . . . ). The block BLK is a set of a plurality of memory cell transistors each of which stores data in a nonvolatile manner. The block BLK is used, for example, as a unit of erasing data. That is, the data stored by the plurality of memory cell transistors included in the same block BLK can be collectively erased. Each of the blocks BLK includes a plurality of memory units MU (MU0, MU1, . . . ). Each of the memory units MU includes a plurality of string units SU (SU0, SU1). The string unit SU includes a plurality of NAND strings NS (NS0, NS1, NS2, . . . ). The NAND string NS includes a plurality of memory cell transistors connected in series. Each of the memory cell transistors is associated with one word line and one bit line.

The driver module 19 generates a voltage to be used in the read operation, the write operation, the erase operation, and the like, and applies the generated voltage to the row decoder module 20. Specifically, the driver module 19 and the row decoder module 20 are connected by a plurality of signal lines. Then, the driver module 19 applies a plurality of types of voltages set for the read operation, the write operation, the erase operation, and the like to the plurality of signal lines based on a page address PA.

The row decoder module 20 is connected between a plurality of signal lines connected to the driver module 19 and a plurality of wirings provided in each of the plurality of blocks BLK in the memory cell array 18. The row decoder module 20 selects one block BLK in the memory cell array 18 based on the block address BA. For example, the row decoder module 20 transfers the voltage applied to each of the plurality of signal lines by the driver module 19 to a word line or the like in the selected block BLK.

The sense amplifier module 21 determines data stored in the memory cell transistor based on the voltage of the bit line during the read operation. Then, the sense amplifier module 21 transfers the determination result to the data register 22 as read data. In addition, the sense amplifier module 21 applies a voltage to each bit line according to write data received from the data register 22 during the write operation.

The data register 22 includes a plurality of latch circuits. The plurality of latch circuits can store write data, read data, and the like. The data register 22 temporarily stores the write data received from the input/output circuit 10 at the time of the write operation and transfers the write data to the sense amplifier module 21. The data register 22 temporarily stores read data received from the sense amplifier module 21 at the time of the read operation and transfers the read data to the input/output circuit 10. The input/output circuit 10 and the data register 22 are connected via, for example, eight data buses.

For example, the column decoder 23 decodes the column address CA in each of the write operation, the read operation, and the erase operation. Then, the column decoder 23 selects the latch circuit in the data register 22 according to the decoding result.

### 1.3.1 Circuit Configuration of Memory Cell Array 18

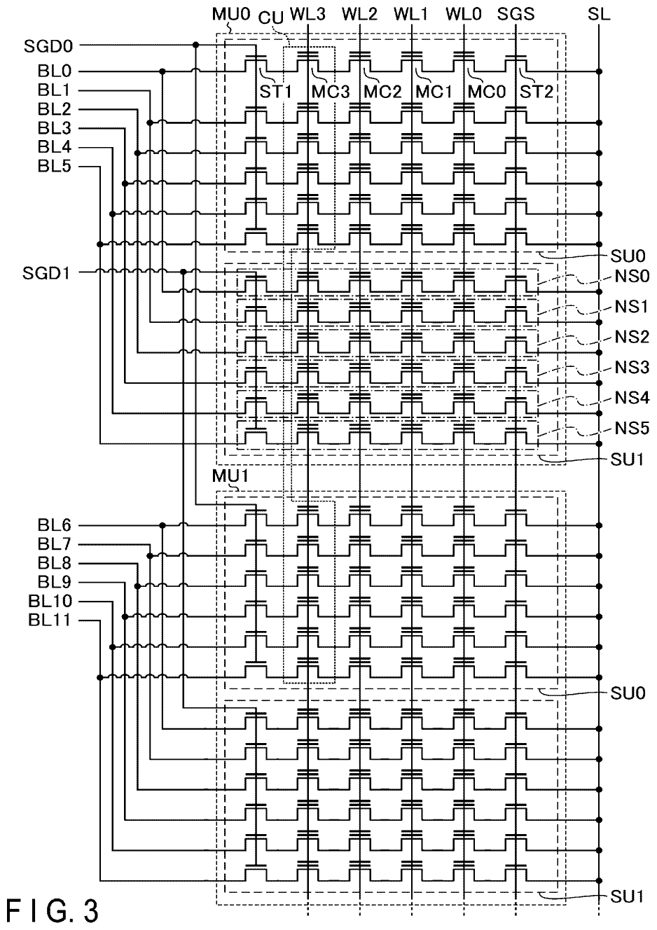

Next, a circuit configuration of the memory cell array 18 included in the memory device 100 of the memory system 1 according to the embodiment will be described. FIG. 3 is a circuit diagram illustrating an example of a circuit configuration of the memory cell array 18 included in the memory device 100 according to the embodiment. FIG. 3 illustrates a circuit configuration of two memory units MU0 and MU1 in the memory cell array 18.

As illustrated in FIG. 3, each block BLK includes, for example, word lines WL0 to WL3, select gate lines SGD0 and SGD1, and a select gate line SGS. In the present example, each of the memory units MU includes two string units SU0 and SU1. In this example, each of the string units SU includes six NAND strings NS0 to NS5.

The word lines WL0 to WL3, the select gate lines SGD0 and SGD1, and the select gate line SGS are connected to the row decoder module 20. The word lines WL0 to WL3, the select gate lines SGD0 and SGD1, and the select gate line SGS can be independently controlled by the row decoder module 20. A plurality of bit lines BL is allocated for each block BLK. The source line SL is shared among the plurality of blocks BLK, for example. The source lines may be independently provided among the plurality of blocks BLK.

The plurality of NAND strings NS included in the same string unit SU are associated with different bit lines BL. In addition, the NAND strings NS of the same number included in the same memory unit MU are connected to the common bit line BL. Specifically, the NAND strings NS0 to NS5 included in the string unit SU0 of the memory unit MU0 are connected to the bit lines BL0 to BL5, respectively. Similarly, the NAND strings NS0 to NS5 included in the string unit SU1 of the memory unit MU0 are connected to the bit lines BL0 to BL5, respectively. In addition, the NAND strings NS0 to NS5 included in the string unit SU0 of the memory unit MU1 are connected to the bit lines BL6 to BL11, respectively. Similarly, the NAND strings NS0 to NS5 included in the string unit SU1 of the memory unit MU1 are connected to the bit lines BL6 to BL11, respectively.

Each NAND string NS includes, for example, four memory cell transistors MC0 to MC3 and selection transistors ST1 and ST2. The memory cell transistor MC includes a control gate and a charge storage layer, and stores data in a nonvolatile manner. The memory cell transistor MC in the embodiment is a MONOS type memory cell in which an insulating layer is used for a charge storage layer. The memory cell transistor MC may be a floating gate type in which a conductive layer is used as a charge storage layer. Each of the selection transistors ST1 and ST2 is used to select the string unit SU in the write operation, the read operation, and the like. Furthermore, each of the selection transistors ST1 and ST2 can also be used to bring a channel of the NAND string NS included in the unselected block BLK into a floating state.

In each NAND string NS, current paths of the selection transistor ST1, the memory cell transistors MC3 to MC0, and the selection transistor ST2 are connected in series in this order. Specifically, a drain of the selection transistor ST1 is connected to an associated bit line BL. A source of the selection transistor ST1 is connected to a drain of the memory cell transistor MC3 among the memory cell transistors MC3 to MC0 connected in series. A source of the memory cell transistor MC0 among the memory cell transistors MC3 to MC0 connected in series is connected to a drain of the selection transistor ST2.

The control gates of the plurality of memory cell transistors MC0 included in the same block BLK are connected to the word line WL0. The control gates of the plurality of memory cell transistors MC1 included in the same block BLK are connected to the word line WL1. The control gates of the plurality of memory cell transistors MC2 included in the same block BLK are connected to the word line WL2. The control gates of the plurality of memory cell transistors MC3 included in the same block BLK are connected to the word line WL3.

The gates of the plurality of selection transistors ST1 included in the plurality of string units SU0 in the same block BLK are connected to a select gate line SGD0. The gates of the plurality of selection transistors ST1 included in the plurality of string units SU1 in the same block BLK are connected to a select gate line SGD1. Gates of the plurality of selection transistors ST2 included in the same block BLK are connected to a select gate line SGS. Sources of the plurality of selection transistors ST2 included in the same block BLK are connected to the source line SL. Note that the gates of the plurality of selection transistors ST2 included in the same block BLK may be connected to different select gate lines SGS for each string unit SU, similarly to the select gate line SGD.

Hereinafter, a set of the memory cell transistors MC included in the string units SU connected to the common select gate line SGD and connected to the common word line WL is referred to as a “cell unit CU”. For example, one cell unit CU includes a memory cell transistor MC3 of each of the NAND strings NS0 to NS5 included in the string unit SU0 of the memory unit MU0 and a memory cell transistor MC3 of each of the NAND strings NS0 to NS5 included in the string unit SU0 of the memory unit MU1. For example, a storage capacity of the cell unit CU including the memory cell transistors MC each storing 1-bit data is defined as “1-page data”. The cell unit CU may have a storage capacity of two page data or more according to the number of bits of data stored in the memory cell transistor MC. Each of the write operation and the read operation is collectively executed for the plurality of memory cell transistors MC included in one cell unit CU.

The circuit configuration of the memory cell array 18 may be another circuit configuration. For example, the number of blocks BLK included in the memory cell array 18 may be another number. The number of memory units MU included in each block BLK may be another number. The number of string units SU included in each memory unit MU may be another number. The number of NAND strings NS included in each string unit SU can be appropriately changed according to the number of stacked semiconductor layers 33 to be described later. The number of memory cell transistors MC included in each NAND string NS may be another number. The number of each of the selection transistors ST1 and ST2 included in each NAND string NS may be another number.

### 1.3.2 Structure of Memory Cell Array 18

Next, an example of a structure of the memory cell array 18 included in the memory device 100 of the memory system 1 according to the embodiment will be described. An X direction, a Y direction, and a Z direction used in the following description are directions crossing each other. The X direction is substantially parallel to a surface of the semiconductor substrate 30 used for forming the memory device 100 and corresponds to a direction in which the word lines WL extend. The Y direction is substantially parallel to the surface of the semiconductor substrate 30 and corresponds to the direction in which the bit lines BL extend. The Z direction corresponds to a vertical direction to the surface of the semiconductor substrate 30. In the drawings referred to below, illustration of the configuration of the insulating layer and the like is omitted as appropriate for easy viewing of the drawings.

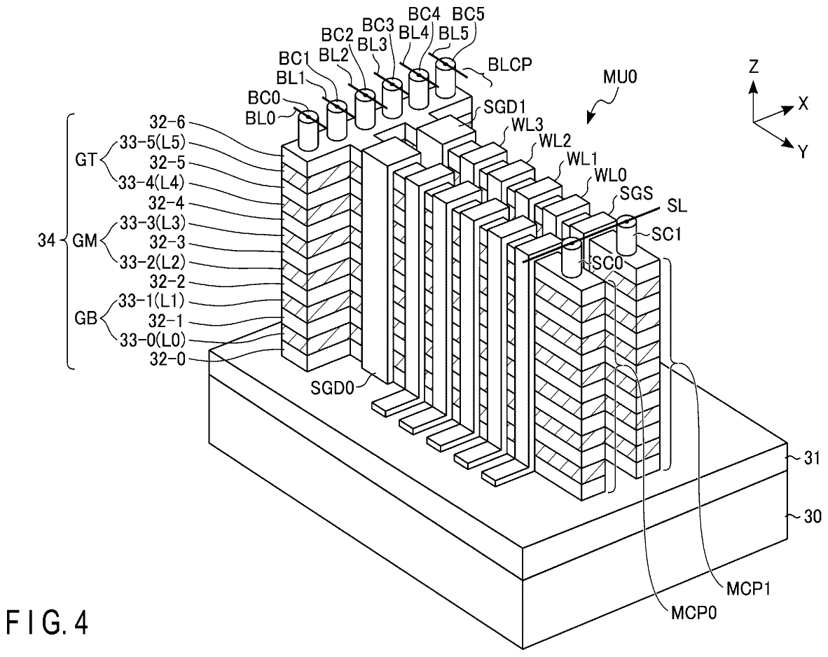

FIG. 4 is a perspective view illustrating an example of a structure of the memory cell array 18 included in the memory device 100 of the memory system 1 according to the embodiment. FIG. 4 illustrates a region including a structure corresponding to one memory unit MU0. As illustrated in FIG. 4, the memory device 100 includes, for example, a semiconductor substrate 30, an insulating layer 31, a plurality of insulating layers 32, a plurality of semiconductor layers 33, contact plugs BC0 to BC5, and contact plugs SC0 and SC1.

The insulating layer 31 is provided on the semiconductor substrate 30. The insulating layer 31 includes, for example, silicon oxide (SiO₂). A structure corresponding to the memory unit MU0 is provided on the insulating layer 31. Specifically, the insulating layers 32 and the semiconductor layers 33 are alternately stacked on the insulating layer 31. The insulating layer 32 includes, for example, silicon oxide (SiO₂). The semiconductor layer 33 is, for example, silicon doped with impurities. Hereinafter, the alternately stacked insulating layers 32 and semiconductor layers 33 are referred to as a “stack 34”.

In the present example, the stack 34 includes seven insulating layers 32 and six semiconductor layers 33. Hereinafter, the seven insulating layers 32 are referred to as insulating layers 32-0 to 32-6 in order from the semiconductor substrate 30 side. The six semiconductor layers 33 are referred to as semiconductor layers 33-0 to 33-5 in order from the semiconductor substrate 30 side.

The wiring layer including the semiconductor layer 33-0 is referred to as a “layer L0”. Similarly, the wiring layer including the semiconductor layer 33-1 is referred to as a “layer L1”. The wiring layer including the semiconductor layer 33-2 is referred to as a “layer L2”. The wiring layer including the semiconductor layer 33-3 is referred to as a “layer L3”. The wiring layer including the semiconductor layer 33-4 is referred to as a “layer L4”. The wiring layer including the semiconductor layer 33-5 is referred to as a “layer L5”. Further, a group including the layers L0 and L1 is referred to as a lower layer group GB, a group including the layers L2 and L3 is referred to as a middle layer group GM, and a group including the layers L4 and L5 is referred to as an upper layer group GT.

One stack 34 corresponds to one memory unit MU. The stack 34 includes a bit line connection portion BLCP and memory cell units MCP0 and MCP1. The bit line connection portion BLCP has a portion extending in the X direction. Each of the memory cell units MCP0 and MCP1 has a portion extending in the Y direction. One end of each of the plurality of memory cell units MCP0 and MCP1 is connected to the bit line connection portion BLCP. In other words, the insulating layers 32 and the semiconductor layers 33 stacked in each memory cell unit MCP are continuously connected to the insulating layer 32 and the semiconductor layer 33 stacked in the bit line connection portion BLCP, respectively.

One memory cell unit MCP corresponds to one string unit SU. Specifically, the memory cell units MCP0 and MCP1 correspond to the string units SU0 and SU1, respectively. The semiconductor layers 33-0 to 33-5 of each memory cell unit MCP are provided corresponding to the NAND strings NS0 to NS5, respectively. That is, the number of NAND strings NS included in one string unit SU corresponds to the number of stacked semiconductor layers 33. In addition, the semiconductor layer 33 included in the memory cell unit MCP functions as an active area including channel layers of the memory cell transistor MC and the selection transistors ST1 and ST2. That is, the channel layer of each NAND string NS is provided to extend in a direction parallel to the surface of the semiconductor substrate 30.

The bit lines BL are provided above the stack 34. Then, the bit lines and the NAND strings NS are connected via the semiconductor layers 33 of the bit line connection portions BLCP and the contact plugs BC. Specifically, bottom portions of the contact plugs BC0 to BC5 are electrically connected to the semiconductor layers 33-0 to 33-5, respectively. The bit lines BL0 to BL5 are electrically connected via upper surfaces of the contact plugs BC0 to BC5, respectively. Each contact plug BC is electrically insulated from the semiconductor layer 33 other than the semiconductor layer 33 electrically connected at the bottom.

A source line SL is provided above stack 34. The source line SL has, for example, a portion extending in the X direction. Then, the source line SL and the NAND string NS are connected to each other via the semiconductor layer 33 of the memory cell unit MCP and the contact plug SC. Specifically, a side surface or a bottom surface of the contact plug SC0 is electrically connected to each of the semiconductor layers 33-0 to 33-5 at the other end portion of the memory cell unit MCP0. A side surface or a bottom surface of the contact plug SC1 is electrically connected to each of the semiconductor layers 33-0 to 33-5 at the other end portion of the memory cell unit MCP1. The source line SL is electrically connected via the upper surfaces of the contact plugs SC0 and SC1.

A tunnel insulating film, a charge storage layer, and a block insulating film (hereinafter, also referred to as a stacked film) not illustrated are stacked on the side surface and the upper surface of the stack 34. In addition, the select gate line SGS, the word lines WL0 to WL3, and the select gate line SGD are arranged in this order toward the bit line connection portion BLCP between the portion of the memory cell unit MCP to which the contact plug SC is connected and the bit line connection portion BLCP. Each of the select gate line SGS and the word lines WL0 to WL3 has a portion provided to extend in the X direction so as to cover (cross) the side surface and the upper surface of the stacked film provided in the memory cell unit MCP of the stack 34. The select gate line SGD0 has a portion provided so as to cover the side surface and the upper surface of the stacked film provided in the memory cell unit MCP0 of the stack 34. The select gate line SGD1 has a portion provided so as to cover the side surface and the upper surface of the stacked film provided in the memory cell unit MCP1 of the stack 34.

### (Planar Layout of Memory Cell Array 18)

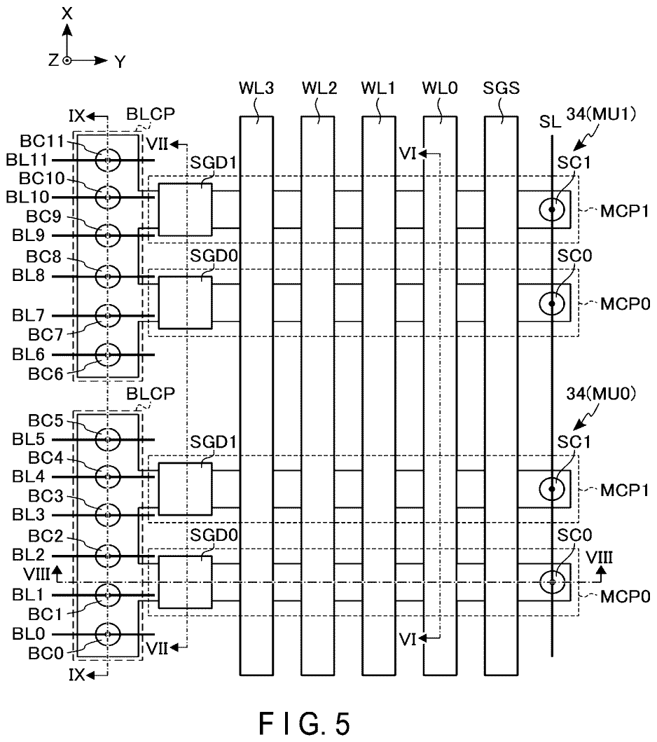

FIG. 5 is a plan view illustrating an example of a planar layout of the memory cell array 18 included in the memory device 100 of the memory system 1 according to the embodiment. FIG. 5 illustrates an area including two adjacent memory units MU0 and MU1. As illustrated in FIG. 5, the plurality of stacks 34 is arranged apart from each other and side by side in the X direction.

Contact plugs BC0 to BC5 respectively connected to the bit lines BL0 to BL5 are provided in the bit line connection portion BLCP of the stack 34 corresponding to the memory unit MU0. Contact plugs BC6 to BC11 respectively connected to the bit lines BL6 to BL11 are provided in the bit line connection portion BLCP of the stack 34 corresponding to the memory unit MU1. As described above, in the present example, the six contact plugs BC connected to the six bit lines BL are provided in the bit line connection portion BLCP of the stack 34 of one memory unit MU.

The stack 34 corresponding to the memory unit MU0 is provided with contact plugs SC0 and SC1 connected to the memory cell units MCP0 and MCP1, respectively. The stack 34 corresponding to the memory unit MU1 is provided with contact plugs SC0 and SC1 connected to the memory cell units MCP0 and MCP1, respectively. In this manner, at least one contact plug SC connected to the source line SL is provided in each memory cell unit MCP of the stack 34 of one memory unit MU.

Select gate line SGS and word lines WL0 to WL3 are provided in a region where a plurality of stack 34 corresponding to one block BLK is formed. Each of the select gate line SGS and the word lines WL0 to WL3 has a portion extending in the X direction and is disposed so as to overlap the plurality of stacks 34. As a result, each of the select gate line SGS and the word lines WL0 to WL3 is shared among the plurality of memory units MU in the same block BLK.

Select gate lines SGD0 and SGD1 are provided in the memory cell units MCP0 and MCP1 of the stack 34 corresponding to the memory unit MU0, respectively. The select gate lines SGD0 and SGD1 are provided in the memory cell units MCP0 and MCP1 of the stack 34 corresponding to the memory unit MU1, respectively. As described above, the select gate lines SGD0 and SGD1 are provided in the memory cell units MCP0 and MCP1 of the stack 34 corresponding to one memory unit MU, respectively. In the same block BLK, the plurality of select gate lines SGD0 and the plurality of select gate lines SGD1 are electrically connected via contacts and wirings (not illustrated).

### (Cross-Sectional Structure of Memory Cell Array 18)

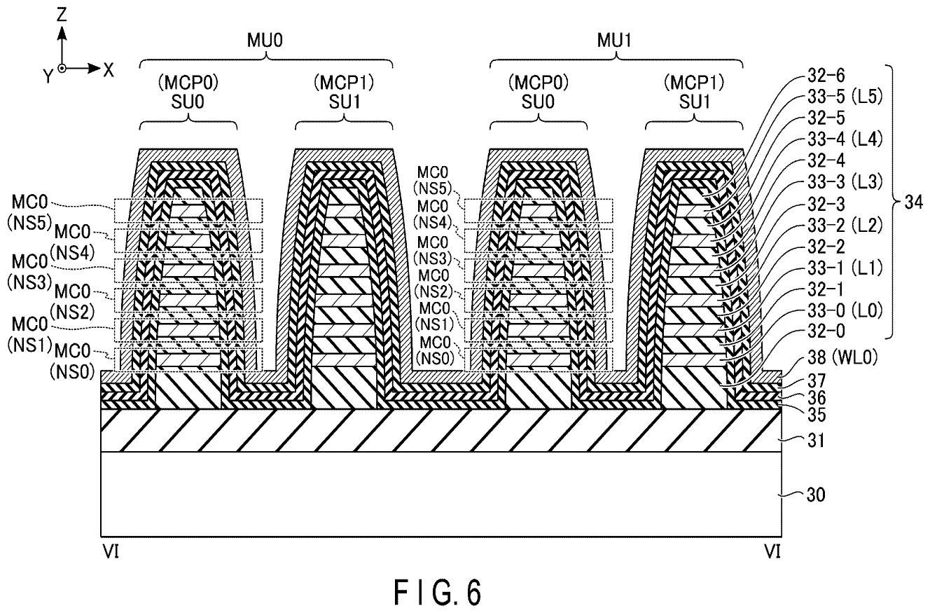

Hereinafter, a cross-sectional structure of the memory cell array 18 included in the memory device 100 of the memory system 1 according to the embodiment will be described with reference to FIGS. 6 to 9. FIGS. 6 to 9 are cross-sectional views illustrating an example of a cross-sectional structure of the memory cell array 18 included in the memory device 100. FIG. 6 is a cross-sectional view taken along line VI-VI in FIG. 5, and illustrates a cross section of the two memory units MU0 and MU1 including the word line WL0 and taken along the X direction.

As shown in FIG. 6, the memory device 100 further includes a tunnel insulating film 35, a charge storage layer 36, a block insulating film 37, and a conductive layer 38.

The tunnel insulating film 35 is continuously provided so as to cover the upper surface and the side surface of the stack 34 of each memory unit MU. In other words, the tunnel insulating film 35 is provided above the insulating layer 31 so as to cross the stack 34 of each memory unit MU. The charge storage layer 36, the block insulating film 37, and the conductive layer 38 are stacked in this order above the tunnel insulating film 35.

Each of the tunnel insulating film 35 and the block insulating film 37 contains, for example, silicon oxide (SiO₂). The charge storage layer 36 includes, for example, silicon nitride (SiN). The conductive layer 38 contains, for example, tungsten (W). The conductive layer 38 included in the cross section shown in FIG. 6 is used as the word line WL0.

In each memory unit MU, a portion where the semiconductor layer 33-0 in the memory cell unit MCP0 and the word line WL0 are close to each other functions as the memory cell transistor MC0 of the NAND string NS0 included in the string unit SU0. In each memory unit MU, a portion where the semiconductor layer 33-0 in the memory cell unit MCP1 and the word line WL0 are close to each other functions as the memory cell transistor MC0 of the NAND string NS0 included in the string unit SU1. That is, the plurality of memory cell transistors MC0 allocated to the NAND string NS0 is included in the layer L0.

In each memory unit MU, a portion where the semiconductor layer 33-1 in the memory cell unit MCP0 and the word line WL0 are close to each other functions as the memory cell transistor MC0 of the NAND string NS1 included in the string unit SU0. In each memory unit MU, a portion where the semiconductor layer 33-1 in the memory cell unit MCP1 and the word line WL0 are close to each other functions as the memory cell transistor MC0 of the NAND string NS1 included in the string unit SU1. That is, the plurality of memory cell transistors MC0 allocated to the NAND string NS1 is included in the layer L1.

In each memory unit MU, a portion where the semiconductor layer 33-2 in the memory cell unit MCP0 and the word line WL0 are close to each other functions as the memory cell transistor MC0 of the NAND string NS2 included in the string unit SU0. In each memory unit MU, a portion where the semiconductor layer 33-2 in the memory cell unit MCP1 and the word line WL0 are close to each other functions as the memory cell transistor MC0 of the NAND string NS2 included in the string unit SU1. That is, the plurality of memory cell transistors MC0 allocated to the NAND string NS2 is included in the layer L2.

In each memory unit MU, a portion where the semiconductor layer 33-3 in the memory cell unit MCP0 and the word line WL0 are close to each other functions as the memory cell transistor MC0 of the NAND string NS3 included in the string unit SU0. In each memory unit MU, a portion where the semiconductor layer 33-3 in the memory cell unit MCP1 and the word line WL0 are close to each other functions as the memory cell transistor MC0 of the NAND string NS3 included in the string unit SU1. That is, the plurality of memory cell transistors MC0 allocated to the NAND string NS3 is included in the layer L3.

In each memory unit MU, a portion where the semiconductor layer 33-4 in the memory cell unit MCP0 and the word line WL0 are close to each other functions as the memory cell transistor MC0 of the NAND string NS4 included in the string unit SU0. In each memory unit MU, a portion where the semiconductor layer 33-4 in the memory cell unit MCP1 and the word line WL0 are close to each other functions as the memory cell transistor MC0 of the NAND string NS4 included in the string unit SU1. That is, the plurality of memory cell transistors MC0 allocated to the NAND string NS4 is included in the layer L4.

In each memory unit MU, a portion where the semiconductor layer 33-5 in the memory cell unit MCP0 and the word line WL0 are close to each other functions as the memory cell transistor MC0 of the NAND string NS5 included in the string unit SU0. In each memory unit MU, a portion where the semiconductor layer 33-5 in the memory cell unit MCP1 and the word line WL0 are close to each other functions as the memory cell transistor MC0 of the NAND string NS5 included in the string unit SU1. That is, the plurality of memory cell transistors MC0 allocated to the NAND string NS5 is included in the layer L5.

Note that the cross-sectional structure along the X direction is similar between the cross-sectional structure including the word line WL0 and the cross-sectional structure including the other word lines WL. In addition, the cross-sectional structure along the X direction is similar between the cross-sectional structure including the word line WL0 and the cross-sectional structure including the select gate line SGS. That is, the plurality of memory cell transistors MC1 to MC3 and the plurality of selection transistors ST2 allocated to the NAND string NS0 are included in the layer L0. The plurality of memory cell transistors MC1 to MC3 and the plurality of selection transistors ST2 allocated to the NAND string NS1 are included in the layer L1. The plurality of memory cell transistors MC1 to MC3 and the plurality of selection transistors ST2 allocated to the NAND string NS2 are included in the layer L2. The plurality of memory cell transistors MC1 to MC3 and the plurality of selection transistors ST2 allocated to the NAND string NS3 are included in the layer L3. The plurality of memory cell transistors MC1 to MC3 and the plurality of selection transistors ST2 allocated to the NAND string NS4 are included in the layer L4. The plurality of memory cell transistors MC1 to MC3 and the plurality of selection transistors ST2 allocated to the NAND string NS5 are included in the layer L5.

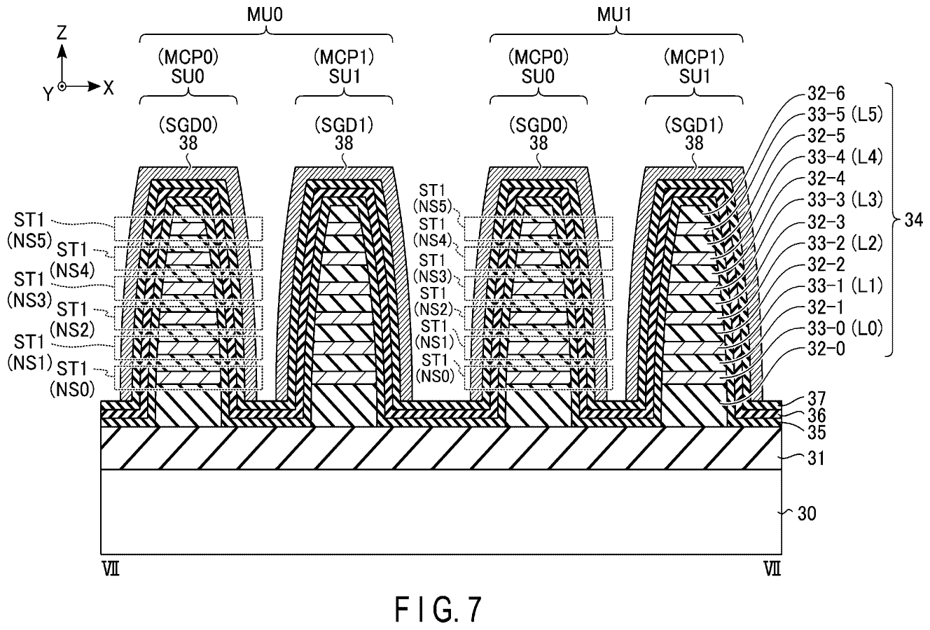

FIG. 7 is a cross-sectional view taken along line VII-VII in FIG. 5, and illustrates a cross section of the two memory units MU0 and MU1 including the select gate lines SGD0 and SGD1 and taken along the X direction. As shown in FIG. 7, the cross-sectional structure including select gate lines SGD0 and SGD1 and along the X direction includes conductive layers 38 of different shapes relative to the cross-sectional structure including word line WL0 and along the X direction.

Specifically, the conductive layer 38 is separated for each memory cell unit MCP in the cross section including the select gate lines SGD0 and SGD1 and along the X direction. In other words, the conductive layer 38 is provided independently for each string unit SU in the cross section including the plurality of select gate lines SGD and along the X direction.

Other structures of the cross section including the select gate lines SGD0 and SGD1 and along the X direction are similar to the structures of the cross section including the word line WL0 and along the X direction. That is, the plurality of selection transistors ST1 allocated to the NAND string NS0 is included in the layer L0. The plurality of selection transistors ST1 allocated to the NAND string NS1 is included in the layer L1. The plurality of selection transistors ST1 allocated to the NAND string NS2 is included in the layer L2. The plurality of selection transistors ST1 allocated to the NAND string NS3 is included in the layer L3. The plurality of selection transistors ST1 allocated to the NAND string NS4 is included in the layer L4. The plurality of selection transistors ST1 allocated to the NAND string NS5 is included in the layer L5.

In addition, as illustrated in FIGS. 6 and 7, the cross-sectional shape of the stack 34 along the X direction has a tapered shape. As described above, in the memory device 100, the cross-sectional shape of the stack 34 along the X direction can change based on processing characteristics of dry etching or the like in a process of forming the stack 34. For this reason, the cross-sectional shape of the stack 34 along the X direction may be a reverse tapered shape, a bowing shape, or the like.

In this example, a width in the X direction of each of the semiconductor layers 33-0 to 33-5 included in the stack 34 and a length along the Z direction of the side surface of each of the semiconductor layers 33-0 to 33-5 included in the stack 34 are different for each layer. As a result, gate widths of the memory cell transistors MC included in the NAND strings NS0 to NS5 are different for each layer.

Specifically, the gate width of the memory cell transistor MC provided in the layer L0, that is, the length of the word line WL adjacent to the memory cell transistor MC and in the Z direction is shorter than the gate width of the memory cell transistor MC provided in the layer L1. The gate width of the memory cell transistor MC provided in the layer L1 is shorter than the gate width of the memory cell transistor MC provided in the layer L2. The gate width of the memory cell transistor MC provided in the layer L2 is shorter than the gate width of the memory cell transistor MC provided in the layer L3. The gate width of the memory cell transistor MC provided in the layer L3 is shorter than the gate width of the memory cell transistor MC provided in the layer L4. Further, the gate width of the memory cell transistor MC provided in the layer L4 is shorter than the gate width of the memory cell transistor MC provided in the layer L5. That is, in the present example, the gate width of the memory cell transistor MC becomes longer as the distance from the semiconductor substrate 30 increases.

In addition, the length (width) in the X direction of the semiconductor layer 33-0 provided in the layer L0 is longer than the length in the X direction of the semiconductor layer 33-1 provided in the layer L1. The length in the X direction of the semiconductor layer 33-1 provided in the layer L1 is longer than the length in the X direction of the semiconductor layer 33-2 provided in the layer L2. The length in the X direction of the semiconductor layer 33-2 provided in the layer L2 is longer than the length in the X direction of the semiconductor layer 33-3 provided in the layer L3. The length in the X direction of the semiconductor layer 33-3 provided in the layer L3 is longer than the length in the X direction of the semiconductor layer 33-4 provided in the layer L4. Further, the length in the X direction of the semiconductor layer 33-4 provided in the layer L4 is longer than the length in the X direction of the semiconductor layer 33-5 provided in the layer L5. That is, in the present example, the length in the X direction of the semiconductor layer 33 used as a part of the memory cell transistor MC becomes shorter as the distance from the semiconductor substrate 30 increases.

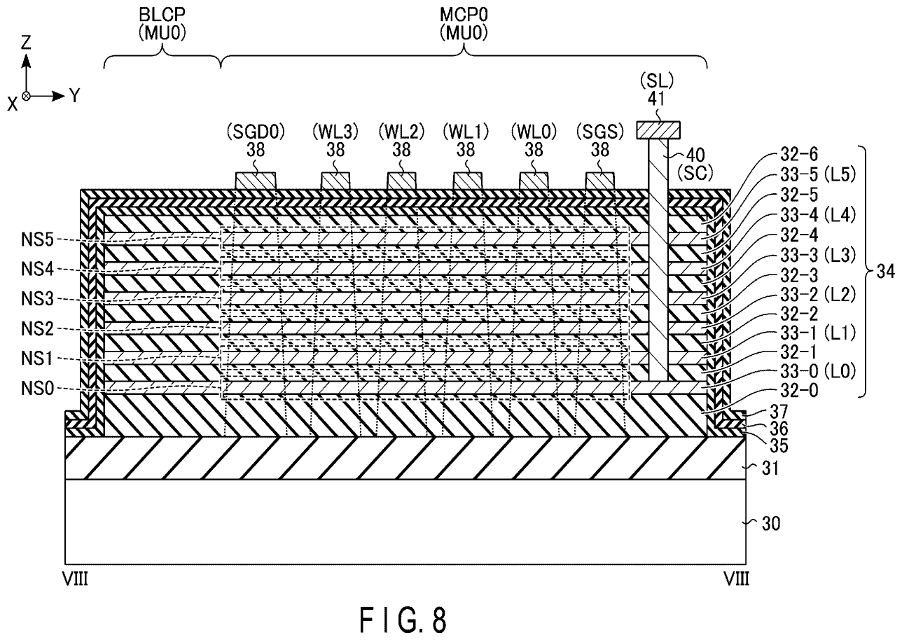

FIG. 8 is a cross-sectional view taken along line VIII-VIII in FIG. 5, and illustrates a cross section including each channel of the NAND strings NS0 to NS5 included in one memory unit MU and taken along the Y direction. As shown in FIG. 8, the memory device 100 further includes a conductive member 40 and a conductive layer 41.

The conductive member 40 is provided in a columnar shape extending along the Z direction, for example, and is used as a contact plug SC. The conductive member 40 penetrates the block insulating film 37, the charge storage layer 36, the tunnel insulating film 35, the insulating layers 32-6 to 32-1, and the semiconductor layers 33-5 and 33-1 in the vicinity of an end of the memory cell unit MCP on the side away from the bit line connection portion BLCP. The bottom portion of the conductive member 40 reaches the semiconductor layer 33-0. Thus, the conductive member 40 is electrically connected to the semiconductor layers 33-0 to 33-5. The conductive member 40 contains, for example, tungsten (W).

The conductive layer 41 is provided on the conductive member 40. The conductive layer 41 has, for example, a portion extending along the X direction, and is used as the source line SL. That is, the conductive layer 41 is electrically connected to each of the semiconductor layers 33-0 to 33-5 via the conductive member 40 (contact plug SC). The conductive layer 41 contains, for example, copper (Cu).

As illustrated in FIG. 8, the length in the Y direction of the conductive layer 38 separated for each wiring varies according to the height. As described above, in the memory device 100, the length in the Y direction of the conductive layer 38 separated for each wiring can be changed based on processing characteristics of dry etching or the like in a process of separating the conductive layer 38 for each wiring. In this example, the length in the Y direction of the conductive layer 38 separated for each wiring becomes shorter as the distance from the semiconductor substrate 30 increases. In such a case, the gate length of the memory cell transistor MC is different for each NAND string NS.

Specifically, the gate length of the memory cell transistor MC provided in the layer L0 is longer than the gate length of the memory cell transistor MC provided in the layer L1. The gate length of the memory cell transistor MC provided in the layer L1 is longer than the gate length of the memory cell transistor MC provided in the layer L2. The gate length of the memory cell transistor MC provided in the layer L2 is longer than the gate length of the memory cell transistor MC provided in the layer L3. The gate length of the memory cell transistor MC provided in the layer L3 is longer than the gate length of the memory cell transistor MC provided in the layer L4. Further, the gate length of the memory cell transistor MC provided in the layer L4 is longer than the gate length of the memory cell transistor MC provided in the layer L5. That is, in the present example, the gate length of the memory cell transistor MC becomes shorter as the distance from the semiconductor substrate 30 increases.

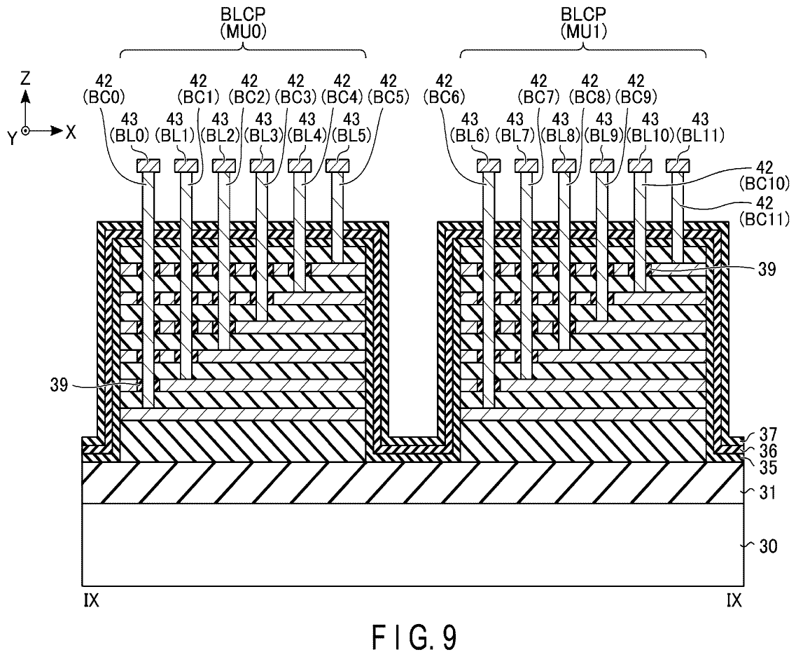

FIG. 9 is a cross-sectional view taken along line IX-IX in FIG. 5, and illustrates a cross section of the two memory units MU0 and MU1 including the bit line connection portion BLCP and taken along the X direction. As shown in FIG. 9, the memory device 100 further includes a plurality of conductive members 42, a plurality of conductive layers 43, and a plurality of insulating layers 39.

Each conductive member 42 is provided in a columnar shape extending in the Z direction, for example, and is used as a contact plug BC. Specifically, in the bit line connection portion BLCP of the memory unit MU0, six conductive members 42 (contact plugs BC0 to BC5) are provided on each of the semiconductor layers 33-0 to 33-5. In the bit line connection portion BLCP of the memory unit MU1, six conductive members 42 (contact plugs BC6 to BC11) are provided on each of the semiconductor layers 33-0 to 33-5. In addition, each conductive member 42 penetrates the block insulating film 37, the charge storage layer 36, and the tunnel insulating film 35.

The conductive member 42 connected to the semiconductor layer 33-0 included in the layer L0 further penetrates the semiconductor layers 33-1 to 33-5 included in the layers L1 to L5. The conductive member 42 connected to the semiconductor layer 33-0 and each of the semiconductor layers 33-1 to 33-5 are separated and insulated by the insulating layer 39.

The conductive member 42 connected to the semiconductor layer 33-1 included in the layer L1 further penetrates the semiconductor layers 33-2 to 33-5 included in the layers L2 to L5. The conductive member 42 connected to the semiconductor layer 33-1 and each of the semiconductor layers 33-2 to 33-5 are separated and insulated by the insulating layer 39.

The conductive member 42 connected to the semiconductor layer 33-2 included in the layer L2 further penetrates the semiconductor layers 33-3 to 33-5 included in the layers L3 to L5. The conductive member 42 connected to the semiconductor layer 33-2 and each of the semiconductor layers 33-3 to 33-5 are separated and insulated by the insulating layer 39.

The conductive member 42 connected to the semiconductor layer 33-3 included in the layer L3 further penetrates the semiconductor layers 33-4 and 33-5 included in the layers L4 and L5. The conductive member 42 connected to the semiconductor layer 33-3 and each of the semiconductor layers 33-4 and 33-5 are separated and insulated by the insulating layer 39.

The conductive member 42 connected to the semiconductor layer 33-4 included in the layer L4 further penetrates the semiconductor layer 33-5 included in the layer L5. The conductive member 42 connected to the semiconductor layer 33-4 and the semiconductor layer 33-5 are separated and insulated by the insulating layer 39. The insulating layer 39 includes, for example, silicon oxide (SiO2).

A plurality of conductive layers 43 is provided on each of the plurality of conductive members 42. The conductive layer 43 has, for example, a portion extending in the Y direction, and is used as the bit line BL. Specifically, the conductive layer 43 provided on the conductive member 42 corresponding to the contact plug BC0 is used as the bit line BL0. The conductive layer 43 provided on the conductive member 42 corresponding to the contact plug BC1 is used as the bit line BL1. The conductive layer 43 provided on the conductive member 42 corresponding to the contact plug BC2 is used as the bit line BL2. Similarly, each conductive layer 43 is used as the bit line BL associated with the semiconductor layer 33 connected via the contact plug BC. The conductive layer 43 contains, for example, copper (Cu).

### 1.4 Configuration of Sense Amplifier Module 21 and Data Register 22

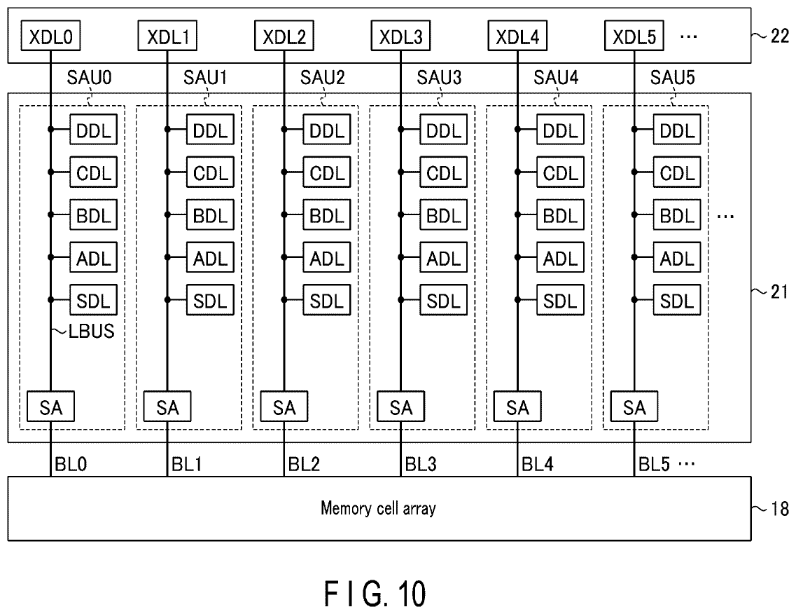

Next, configurations of the sense amplifier module 21 and the data register 22 included in the memory device 100 according to the embodiment will be described with reference to FIG. 10. FIG. 10 is a block diagram illustrating an example of a configuration of the sense amplifier module 21 and the data register 22 included in the memory device 100.

As illustrated in FIG. 10, the sense amplifier module 21 includes, for example, a plurality of sense amplifier units SAU (SAU0, SAU1, SAU2, SAU3, SAU4, SAU5, . . . ) respectively associated with a plurality of bit lines BL. The data register 22 includes, for example, a plurality of latch circuits XDL (XDL0, XDL1, XDL2, XDL3, XDL4, XDL5, . . . ) respectively associated with a plurality of sense amplifier units SAU.

Each sense amplifier unit SAU includes, for example, a sense circuit SA, latch circuits SDL, ADL, BDL, CDL, and DDL, and a bus LBUS. The sense circuit SA, the latch circuits SDL, ADL, BDL, CDL, and DDL, and the associated latch circuit XDL are connected to a common bus LBUS. As a result, the sense circuit SA and the latch circuits SDL, ADL, BDL, CDL, DDL, and XDL can transmit and receive data to and from each other via the bus LBUS.

The sense circuit SA is connected to the bit line BL associated with the sense amplifier unit SAU. For example, at the time of the read operation, the sense circuit SA senses the data read to the associated bit line BL and determines the data stored in the selected memory cell transistor MC. Specifically, in a case where the control signal STB is asserted during the read operation, the sense circuit SA determines whether the read data of the selected memory cell transistor MC is “0” or “1” based on the voltage of the associated bit line BL or the current flowing through the associated bit line BL. In addition, the sense circuit SA applies a voltage to the bit line BL based on write data stored in at least one latch circuit included in the sense amplifier unit SAU during the write operation.

Each of the latch circuits SDL, ADL, BDL, CDL, DDL, and XDL temporarily stores read data and write data. At the time of the read operation, the read data determined by the sense circuit SA is transferred to the latch circuit XDL via any of the latch circuits SDL, ADL, BDL, CDL, and DDL, for example. The data read to the latch circuit XDL is output to the memory controller 200 via the input/output circuit 10. At the time of the write operation, the write data transferred to the latch circuit XDL is transferred to, for example, any one of the latch circuits SDL, ADL, BDL, CDL, and DDL, and writing is executed. As described above, the latch circuit XDL is used to input and output data between the sense amplifier unit SAU and the input/output circuit 10. The latch circuit XDL can also be used as a cache memory of the memory device 100. The memory device 100 is in a ready state if data can be input and output between the latch circuit XDL and the input/output circuit 10.

### 1.4.1 Circuit Configuration of Sense Amplifier Unit SAU

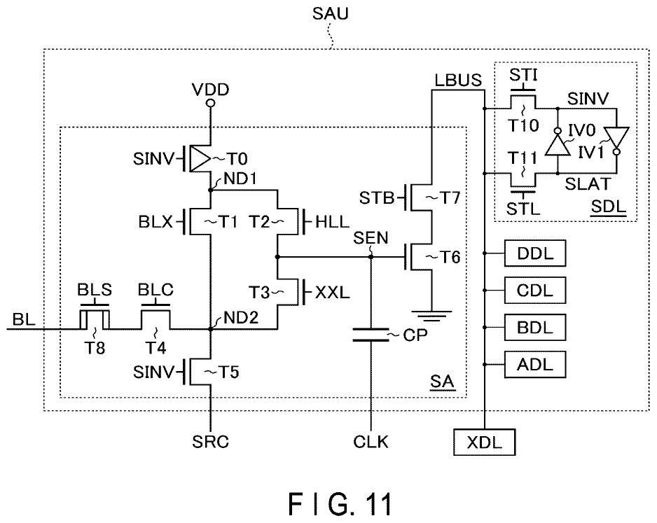

Next, a circuit configuration of the sense amplifier unit SAU included in the sense amplifier module 21 of the memory device 100 according to the embodiment will be described with reference to FIG. 11. FIG. 11 is a diagram illustrating an example of a circuit configuration of a sense amplifier unit SAU included in the sense amplifier module 21.

As illustrated in FIG. 11, the sense circuit SA of the sense amplifier unit SAU includes transistors T0 to T8 and a capacitor CP. The latch circuit SDL of the sense amplifier unit SAU includes inverters IV0 and IV1 and transistors T10 and T11. The transistor T0 is a P-type MOS transistor. Each of the transistors T1 to T7, T10, and T11 is an N-type MOS transistor. The transistor T8 is an N-type MOS transistor having a higher withstand voltage than each of the transistors T0 to T7.

The source of the transistor T0 is connected to a power supply line. The drain of the transistor T0 is connected to a node ND1. The gate of the transistor TO is connected to a node SINV in the latch circuit SDL. The drain of the transistor T1 is connected to the node ND1. The source of the transistor T1 is connected to a node ND2. A control signal BLX is input to the gate of the transistor T1. The drain of a transistor T2 is connected to the node ND1. The source of the transistor T2 is connected to a node SEN. A control signal HLL is input to the gate of the transistor T2.

The drain of the transistor T3 is connected to the node SEN. The source of the transistor T3 is connected to the node ND2. A control signal XXL is input to the gate of the transistor T3. The drain of the transistor T4 is connected to the node ND2. A control signal BLC is input to the gate of the transistor T4. The drain of the transistor T5 is connected to the node ND2. The source of the transistor T5 is connected to a node SRC. The gate of the transistor T5 is connected to, for example, a node SINV in the latch circuit SDL.

The source of the transistor T6 is grounded. The gate of the transistor T6 is connected to the node SEN. The drain of the transistor T7 is connected to the bus LBUS. The source of the transistor T7 is connected to the drain of the transistor T6. A control signal STB is input to the gate of the transistor T7. One electrode of the capacitor CP is connected to the node SEN. A clock signal CLK is input to the other electrode of the capacitor CP. The drain of the transistor T8 is connected to the source of the transistor T4. The source of the transistor T8 is connected to the associated bit line BL. A control signal BLS is input to the gate of the transistor T8.

An input node of the inverter IV0 is connected to a node SLAT. An output node of the inverter IV0 is connected to the node SINV. An input node of the inverter IV1 is connected to the node SINV. An output node of the inverter IV1 is connected to the node SLAT. One end of the transistor T10 is connected to the node SINV. The other end of the transistor T10 is connected to the bus LBUS. A control signal STI is input to the gate of the transistor T10. One end of the transistor T11 is connected to the node SLAT. The other end of the transistor T11 is connected to the bus LBUS. A control signal STL is input to the gate of the transistor T11. For example, the data held in the node SLAT corresponds to the data stored in the latch circuit SDL. On the other hand, the data held in the node SINV corresponds to inverted data of the data held in the node SLAT.

The circuit configurations of the latch circuits ADL, BDL, CDL, DDL, and XDL are similar to, for example, the latch circuit SDL. For example, the latch circuit ADL holds data at a node ALAT and holds inverted data thereof at a node AINV. Then, a control signal ATI is input to the gate of the transistor T10 of the latch circuit ADL, and a control signal ATL is input to the gate of the transistor T11 of the latch circuit ADL. The latch circuit BDL holds data at a node BLAT and holds inverted data thereof at a node BINV. Then, a control signal BTI is input to the gate of the transistor T10 of the latch circuit BDL, and a control signal BTL is input to the gate of the transistor T11 of the latch circuit BDL. The same applies to the latch circuits CDL, DDL, and XDL, and thus description thereof is omitted.

In the circuit configuration of the sense amplifier unit SAU described above, for example, a power supply voltage VDD is applied to the power supply line connected to the source of the transistor TO. For example, a ground voltage VSS is applied to the node SRC. Each of the control signals BLX, HLL, XXL, BLC, STB, BLS, STI, and STL and the clock signal CLK is generated by, for example, the sequencer 15. The node SEN may be referred to as a sense node of the sense circuit SA.

The circuit configuration of the sense amplifier unit SAU may be another circuit configuration. For example, the number of latch circuits included in each sense amplifier unit SAU can be appropriately changed based on the number of pages stored in one cell unit CU. The sense amplifier unit SAU may include an arithmetic circuit capable of executing a simple logical operation. In the memory device 100 in the embodiment, asserting the control signal corresponds to temporarily changing the voltage of the “L” level to the voltage of the “H” level. In a case where the transistor whose gate is connected to the sense node is a P-type transistor, asserting the control signal STB corresponds to temporarily changing the “H” level to the “L” level.

### 1.4.2 Connection Relationship Between Data Register 22 and Input/Output Circuit 10

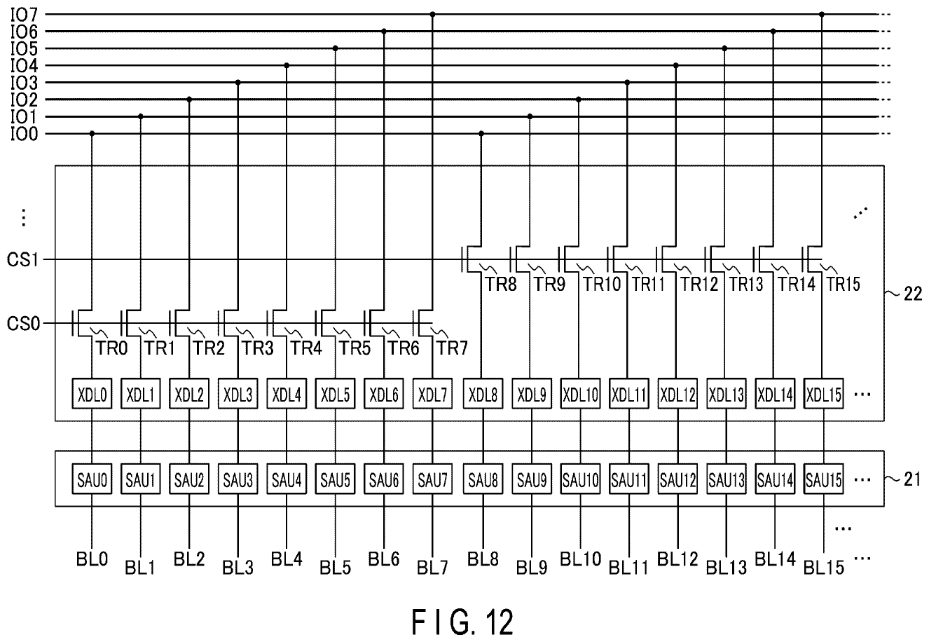

Next, a connection relationship between the data register 22 and the input/output circuit 10 of the memory device 100 according to the embodiment will be described with reference to FIG. 12. FIG. 12 is a circuit diagram illustrating an example of a connection relationship between the data register 22 and the input/output circuit 10 included in the memory device 100. In addition, FIG. 12 illustrates eight input/output buses (alternatively, the data bus) IO0 to IO7 connected to the input/output circuit 10.

As shown in FIG. 12, the data register 22 further includes a plurality of transistors TR (TR0, TR1, TR2, TR3, TR4, TR5, TR6, TR7, TR8, TR9, TR10, TR11, TR12, TR13, TR14, TR15, . . . ).

The source and the drain of the transistor TR(k×8) (k is an integer of 0 or more) are connected between the latch circuit XDL(k×8) and the input/output bus IO0. The source and the drain of the transistor TR(1+k×8) are connected between the latch circuit XDL(1+k×8) and the input/output bus IO1. The source and the drain of the transistor TR(2+k×8) are connected between the latch circuit XDL(2+k×8) and the input/output bus IO2. The source and the drain of the transistor TR(3+k×8) are connected between the latch circuit XDL(3+k×8) and the input/output bus IO3. The source and the drain of the transistor TR(4+k×8) are connected between the latch circuit XDL(4+k×8) and the input/output bus IO4. The source and the drain of the transistor TR(5+k×8) are connected between the latch circuit XDL(5+k×8) and the input/output bus IO5. The source and the drain of the transistor TR(6+k×8) are connected between the latch circuit XDL(6+k×8) and the input/output bus IO6. The source and the drain of the transistor TR(7+k×8) are connected between the latch circuit XDL(7+k×8) and the input/output bus IO7.

The sequencer 15 generates and controls a plurality of control signals CS. A control signal CSk is input to the gates of the transistors TR(k×8), TR(1+k×8), TR(2+k×8), TR(3+k×8), TR(4+k×8), TR(5+k×8), TR(6+k×8), and TR(7+k×8). Specifically, a control signal CS0 is input to the gates of the transistors TR0 to TR7, and a control signal CS1 is input to the gates of the transistors TR8 to TR15. That is, the transistors TR to which the same control signal CS is input are connected to different input/output buses 10. For example, the sequencer 15 sequentially controls the plurality of control signals CS to the “H” level to turn on the transistors TR eight by eight, so that data can be transmitted and received eight bits by eight bits between the plurality of latch circuits XDL in the data register 22 and the input/output circuit 10.

### 1.5 Data Storage Method

The memory system 1 according to the embodiment can use a plurality of types of storage methods according to the number of bits of data to be stored in one memory cell transistor MC. For example, the memory system 1 according to the embodiment can use any storage scheme of a single-level cell (SLC) method, a multi-level cell (MLC) method, a triple-level cell (TLC) method, and a quadruple-level cell (QLC) method.

The SLC method, the MLC method, the TLC method, and the QLC method are storage methods for storing 1-bit data, 2-bit data, 3-bit data, and 4-bit data in one memory cell transistor MC, respectively.

In the present embodiment, a case where the memory system 1 uses the TLC method as a data storage method will be described. The operations described below can also be applied in the case of using other writing modes.

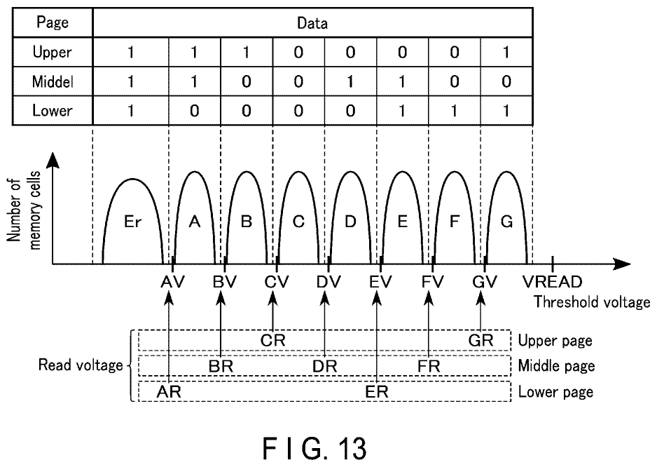

FIG. 13 is a schematic diagram illustrating an example of data allocation by the TLC method used in the memory system 1 according to the embodiment.

The 3-bit data that can be stored in the memory cell transistor MC is defined by a lower bit, a middle bit, and an upper bit. In a case where the memory cell transistor MC stores three bits, the memory cell transistor MC can take any one of eight states according to a plurality of threshold voltages. The eight states are referred to as an “Er” state, an “A” state, a “B” state, a “C” state, a “D” state, an “E” state, an “F” state, and a “G” state in order from the lowest. The plurality of memory cell transistors MC belonging to each of these “Er” to “G” states form a threshold voltage distribution as illustrated in FIG. 13.

For example, data “111”, “110”, “100”, “000”, “010”, “011”, “001”, and “101” are allocated to Er, A, B, C, D, E, F, and G states, respectively. The arrangement of bits is “Z, Y, X” where a lower bit “X”, a middle bit “Y”, and an upper bit “Z” are set. The allocation of the threshold voltage distribution and the data can be arbitrarily set.

In order to read data stored in the memory cell transistor MC to be read, a state to which the threshold voltage of the memory cell transistor MC belongs is determined. Hereinafter, the memory cell transistor MC to be read is referred to as a target memory cell transistor or a target memory cell. In order to determine the state, read voltages AR, BR, CR, DR, ER, FR, and GR are used. Hereinafter, the read voltages AR, BR, CR, DR, ER, FR, and GR are referred to as default voltages. In addition, the voltage applied to the target memory cell transistor MC for determining the level including the read voltages AR, BR, CR, DR, ER, FR, and GR may be referred to as a read voltage VCGRV.

The Er state corresponds to, for example, a state in which data is erased (erased state). The threshold voltage of the memory cell transistor MC belonging to the Er state is lower than the voltage AR and has, for example, a negative value.

The A to G states correspond to a state in which charges are injected into the charge storage layer and data is written in the memory cell transistor MC, and the threshold voltages of the memory cell transistors MC belonging to the A to G states have positive values, for example. The threshold voltage of the memory cell transistor MC belonging to the A state is higher than the read voltage AR and equal to or lower than the read voltage BR. The threshold voltage of the memory cell transistor MC belonging to the B state is higher than the read voltage BR and equal to or lower than the read voltage CR. The threshold voltage of the memory cell transistor MC belonging to the C state is higher than the read voltage CR and equal to or lower than the read voltage DR. The threshold voltage of the memory cell transistor MC belonging to the D state is higher than the read voltage DR and equal to or lower than the read voltage ER. The threshold voltage of the memory cell transistor MC belonging to the E state is higher than the read voltage ER and equal to or lower than the read voltage FR. The threshold voltage of the memory cell transistor MC belonging to the F state is higher than a read voltage FR and equal to or lower than the read voltage GR. The threshold voltage of the memory cell transistor MC belonging to the G state is higher than the read voltage GR and lower than a voltage VREAD.

The voltage VREAD is a voltage applied to the word line WL connected to the memory cell transistor MC of the cell unit CU to be not read, and is higher than the threshold voltage of the memory cell transistor MC having any state. Therefore, the memory cell transistor MC to which the voltage VREAD is applied to the control gate is turned on regardless of the stored data.

In addition, a verify voltage used in the write operation is set between adjacent threshold distributions. Specifically, verify voltages AV, BV, CV, DV, EV, FV, and GV are set corresponding to the states A, B, C, D, E, F, and G, respectively. For example, the verify voltages AV, BV, CV, DV, EV, FV, and GV are set slightly higher than the read voltages AR, BR, CR, DR, ER, FR, and GR, respectively.

As described above, each memory cell transistor MC is set to one of the eight states, and can store 3-bit data. Further, writing and reading are performed in units of pages in one cell unit CU. In a case where the memory cell transistor MC stores 3-bit data, a lower bit, a middle bit, and an upper bit are allocated to each of three pages in one cell unit CU. A page to be written in one write operation for the lower bit, the middle bit, and the upper bit, or a page to be read in one read operation, that is, a set of lower bits, a set of middle bits, and a set of upper bits held by the cell unit CU are referred to as a lower page, a middle page, and an upper page, respectively.

In a case where the data allocation is applied, the lower page is determined by the read operation using the read voltages AR and ER. The middle page is determined by the read operation using the read voltages BR, DR, and FR. The upper page is determined by the read operation using the read voltages CR and GR.

### 1.5.1 Layer Dependency of Threshold Voltage Distribution of Memory Cell Transistor MC

As described with reference to FIGS. 6 to 8, the memory cell transistor MC has a different size for each layer. Therefore, the memory cell transistor MC can have different characteristics for each layer, such as data holding characteristics. Therefore, even in a case where the same writing condition is applied to the memory cell transistors MC of different layers and the write operation is executed, the threshold voltage distribution of the memory cell transistors MC can be shifted according to the layer with the lapse of time after the write operation.

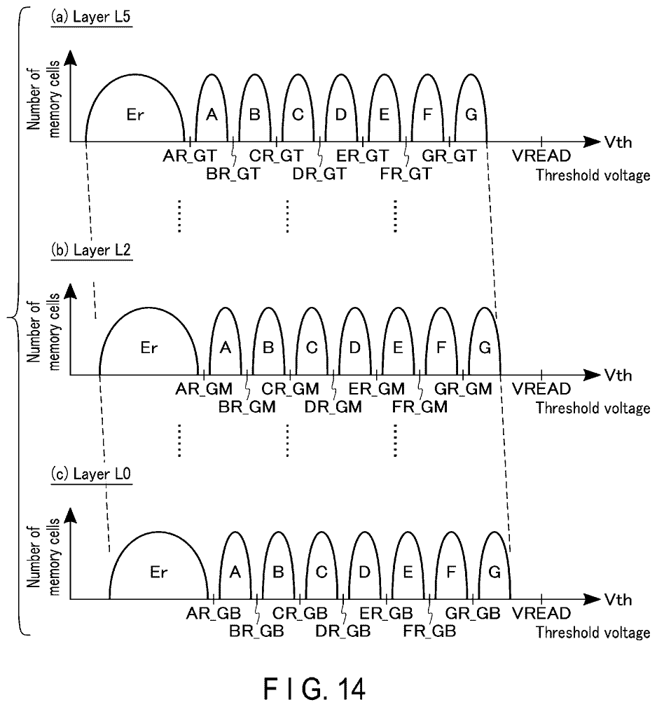

FIG. 14 is a schematic diagram illustrating an example of threshold voltage distribution of the memory cell transistor MC for each layer in the memory system 1 according to the embodiment. In FIG. 14, (a) to (c) illustrate threshold voltage distributions of the memory cell transistors MC corresponding to the layers L5 to L0. As illustrated in FIG. 14, the threshold voltage distribution of the memory cell transistor MC has layer dependency.

In this example, the threshold voltage distribution of the memory cell transistor MC arranged in the layer L1 is shifted lower than the threshold voltage distribution of the memory cell transistor MC arranged in the layer L0. The threshold voltage distribution of the memory cell transistor MC arranged in the layer L5 is shifted lower than the threshold voltage distribution of the memory cell transistor MC arranged in the layer L4 (not illustrated). That is, in this example, the threshold voltage distribution of the memory cell transistor MC is shifted higher in the layer closer to the semiconductor substrate 30.

Note that the layer dependency of the threshold voltage distribution of the memory cell transistor MC can change according to the size of the memory cell transistor MC based on the shape of the stack 34 and the shape of the word line WL. For example, the threshold voltage distribution of the memory cell transistors MC arranged in the uppermost layer (for example, layer L5) among the plurality of layers may be located on the higher voltage side than the threshold voltage distribution of the memory cell transistors MC arranged in the other layers. For example, the threshold voltage distribution of the memory cell transistors MC arranged in a middle layer (for example, layer L2) among the plurality of layers L may be located on the higher voltage side than the threshold voltage distribution of the memory cell transistors MC arranged in the other layers.

The memory system 1 according to the embodiment can set different read voltages for each group (alternatively, for each layer) of the lower layer group GB, the middle layer group GM, and the upper layer group GT in which the memory cell transistors MC are arranged.

For example, in the reading using the read voltage AR, the read voltages AR_GB, AR_GM, and AR_GT are set corresponding to the lower layer group GB, the middle layer group GM, and the upper layer group GT, respectively. In the reading using the read voltage BR, the read voltages BR_GB, BR_GM, and BR_GT are set corresponding to the groups GB, GM, and GT, respectively. In the reading using the read voltage CR, the read voltages CR_GB, CR_GM, and CR_GT are set corresponding to the groups GB, GM, and GT, respectively. In the reading using the read voltage DR, the read voltages DR_GB, DR_GM, and DR_GT are set corresponding to the groups GB, GM, and GT, respectively. In the reading using the read voltage ER, the read voltages ER_GB, ER_GM, and ER_GT are set corresponding to the groups GB, GM, and GT, respectively. In the reading using the read voltage FR, the read voltages FR_GB, FR_GM, and FR_GT are set corresponding to the groups GB, GM, and GT, respectively. Further, in the reading using the read voltage GR, the read voltages GR_GB, GR_GM, and GR_GT are set corresponding to the groups GB, GM, and GT, respectively.

In this example, the read voltages AR_GB, AR_GM, and AR_GT have a relationship of “AR_GB>AR_GM>AR_GT”. The read voltages BR_GB, BR_GM, and BR_GT have a relationship of “BR_GB>BR_GM>BR_GT”. The read voltages CR_GB, CR_GM, and CR_GT have a relationship of “CR_GB>CR_GM>CR_GT”. The read voltages DR_GB, DR_GM, and DR_GT have a relationship of “DR_GB>DR_GM>DR_GT”. The read voltages ER_GB, ER_GM, and ER_GT have a relationship of “ER_GB>ER_GM>ER_GT”. The read voltages FR_GB, FR_GM, and FR_GT have a relationship of “FR_GB>FR_GM>FR_GT”. Further, the read voltages GR_GB, GR_GM, and GR_GT have a relationship of “GR_GB>GR_GM>GR_GT”.

Note that the relationship of the read voltages set for each group can change according to the layer dependency of the threshold voltage distribution of the memory cell transistor MC. In addition, the read voltage set for each group is set based on, for example, the read voltages AR to GR illustrated in FIG. 13 as a criterion. Hereinafter, the read voltages AR to GR used as the criterion are also referred to as “default voltages”. For example, the shift amount of the read voltage set for each group from the default voltage is managed by a digital analog converter (DAC) value. In this case, the shift amount of the read voltage corresponds to a value obtained by multiplying the DAC value by a predetermined voltage value.

### 2. Operation

Next, an operation of the memory system 1 according to the embodiment will be described. First, an operation at the time of power on in the memory system 1 will be described.

2.1 Operation in a Case where Power on

In a case where power on, the memory system 1 according to the embodiment acquires various types of information and tables necessary for operation from the memory device 100. Here, information used at the time of the read operation according to the embodiment will be focused and described. For example, at the time of power on, the physical location conversion table 222 in which the read bit location in the read data and the physical location of the memory cell transistor MC are associated with each other is generated.

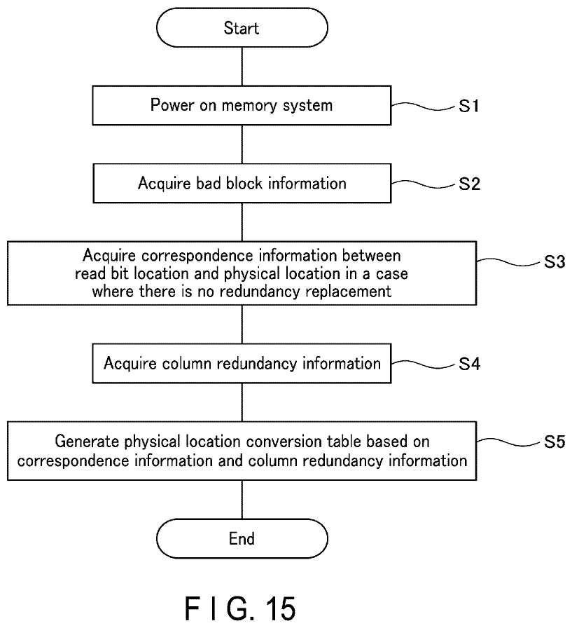

FIG. 15 is a flowchart illustrating an example of operation processing at the time of power on in the memory system 1 according to the embodiment. This processing is executed by the CPU 230 of the memory controller 200.

In a case where power on to the memory system 1 (S1), the CPU 230 of the memory controller 200 acquires bad block information from the memory cell array 18 of the memory device 100 (S2). The bad block information is information on a defective block that cannot be used for the write operation and the read operation. Among the plurality of blocks in the memory cell array 18, there is a defective block that cannot be used due to a defect occurring at the time of manufacturing, exhaustion caused by erasing and writing, or the like. For example, the memory cell array 18 includes a ROM block that stores various types of information and tables necessary for operation. The bad block information is stored in the ROM block of the memory cell array 18. The CPU 230 acquires the bad block information from the ROM block. Then, the CPU 230 excludes the bad block from the blocks used for the write operation and the read operation based on the bad block information.

Next, the CPU 230 acquires, from the memory cell array 18 of the memory device 100, the correspondence information between the read bit location and the physical location in a case where the defective column (alternatively, a defective memory cell) is not replaced with the redundancy column (alternatively, the redundancy memory cell) (S3). In each block in the memory cell array 18, there is a defective column that cannot be used for the write operation and the read operation due to a defect generated at the time of manufacturing, such as an open or short circuit of the bit line BL. The defective column is replaced with the redundancy column by the memory device 100, but here, correspondence information indicating a correspondence relationship between the read bit location of the read data and the physical location of the memory cell transistor MC in a case where there is no replacement of the defective column with the redundancy column is acquired. This correspondence information is stored, for example, in the ROM block of the memory cell array 18. The read bit location corresponds to column addresses COL0 to COL2 and input/output buses IO0 to IO7 corresponding to the read data. The physical location corresponds to the memory units MU0 to MU3 and the layers L0 to L5 in which the memory cell transistors MC are arranged.

Next, the CPU 230 acquires column redundancy information from the memory cell array 18 of the memory device 100 (S4). The column redundancy information is information indicating that the defective column is replaced with the redundancy column in a case where there is replacement of the defective column with the redundancy column. The defective column is replaced by a column of redundancy by the memory device 100. The column redundancy information is stored in, for example, the ROM block of the memory cell array 18. The CPU 230 acquires the column redundancy information from the ROM block. A method of replacing the defective column with the redundancy column will be described later.

Next, the CPU 230 generates the physical location conversion table 222 indicating the correspondence relationship between the read bit location and the physical location based on the correspondence information and the column redundancy information (S5). Thus, the operation processing at the time of power on is ended.

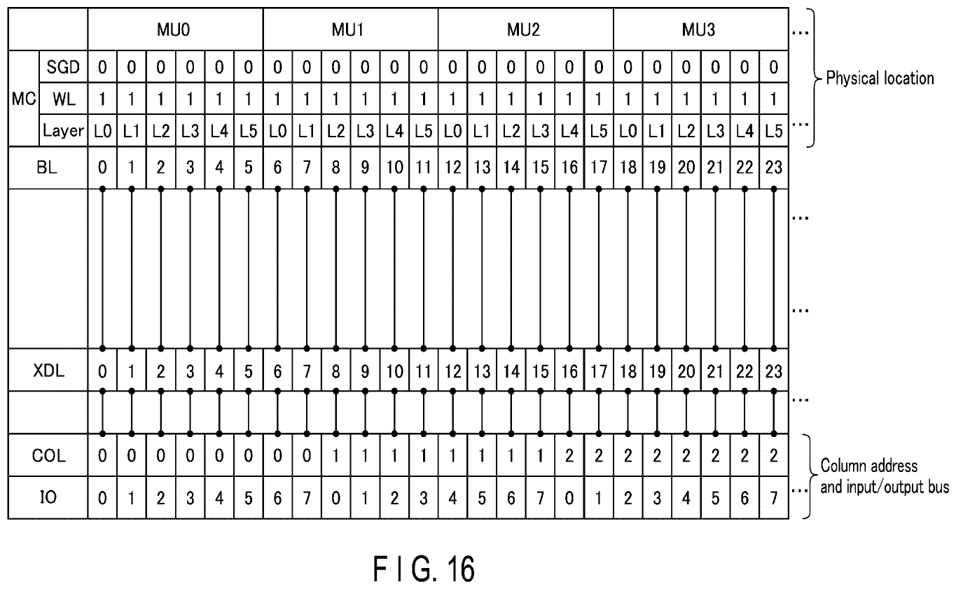

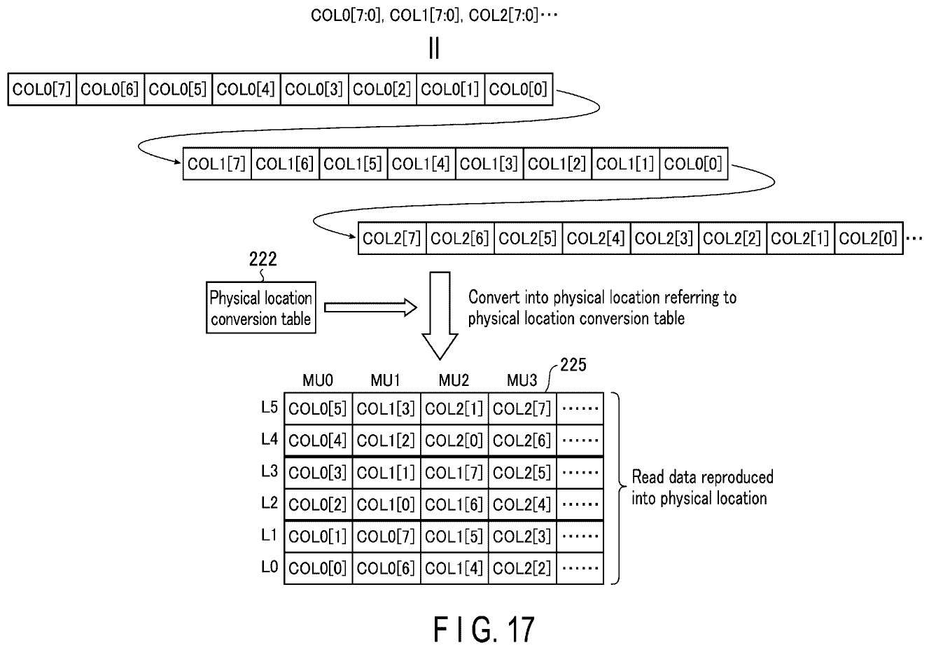

Hereinafter, the correspondence relationship between the read bit location of the read data and the physical location of the memory cell transistor MC in the memory system 1 will be described with reference to FIGS. 16 and 17.

FIG. 16 is a diagram illustrating an example of a connection relationship between the physical location of the memory cell transistor MC of the memory device 100, the column address, and the input/output bus. FIG. 17 is a diagram illustrating, in an upper portion of FIG. 17, the read bit location of read data in the case of satisfying the connection relationship shown in FIG. 16, and in a lower portion thereof, read data 225 in which the physical location is reproduced based on the physical location conversion table 222. Hereinafter, the read data 225 in which the physical location is reproduced is also referred to as the read data 225 reproduced into physical location. Here, in order to simplify the description, the memory units MU0 to MU3 of the pages (alternatively, the cell unit CU) in the block to be read are illustrated. Hereinafter, the page in the block to be read is simply referred to as a target page.

As illustrated in FIG. 16, for example, the memory cell transistors MC corresponding to the memory units MU0 to MU3, the select gate line (alternatively, a selection gate transistor) SGD0, the word line WL1, and the layers L0 to L5 in the target page of the memory cell array 18 are connected to the bit lines BL0 to BL23, respectively. Further, each of the bit lines BL0 to BL23 is connected to the latch circuits XDL0 to XDL23 of the data register 22. Then, the data input/output from the latch circuits XDL0 to XDL23 correspond to the column addresses COL0 to COL2 and the input/output buses IO0 to IO7, respectively.

For example, in a case where the read operation is executed, the data corresponding to the column address COL0 and the input/output bus IO2 is read from the memory cell transistors MC arranged in the memory unit MU0, the select gate line SGD0, the word line WL1, and the layer L2 as physical location. In addition, the data corresponding to the column address COL1 and the input/output bus IO3 is read from the memory cell transistors MC arranged in the memory unit MU1, the select gate line SGD0, the word line WL1, and the layer L5 as physical location.

Hereinafter, for example, the column address COL0 and the input/output bus IO0 are referred to as a column address COL0 [0]. The column address COL1 and the input/output bus IO7 are referred to as a column address COL1 [7]. The same applies to other column addresses and input/output buses.

Based on the physical location conversion table 222 having the connection information illustrated in FIG. 16, as illustrated in FIG. 17, the read bit location of the read data is converted into the read data 225 reproduced into physical location.

In the read data 225 reproduced into physical location, the column addresses COL0 to COL2 and the input/output buses IO0 to IO7 are associated with each memory unit of the memory units MU0 to MU3 and each layer of the layers L0 to L5. That is, column addresses COL0 [0], COL0 [1], . . . , COL0 [7], COL1 [0], COL1 [1], . . . , COL1 [7], COL2 [0], COL2 [1], . . . , and COL2 [7] are associated with each of the memory units MU0 to MU3 and each of the layers L0 to L5. For example, the column address COL0 [2] corresponds to the layer L2 of the memory unit MU0. The column address COL1 [3] corresponds to the layer L5 of the memory unit MU1.

The CPU 230 can identify that the data corresponding to the column address COL0 [2] is written in the memory cell transistor MC arranged in the layer L2 of the memory unit MU0 by referring to the read data 225 reproduced into physical location illustrated in FIG. 17. In addition, it can be identified that the data corresponding to the column address COL1 [3] is written in the memory cell transistor MC arranged in the layer L5 of the memory unit MU1.

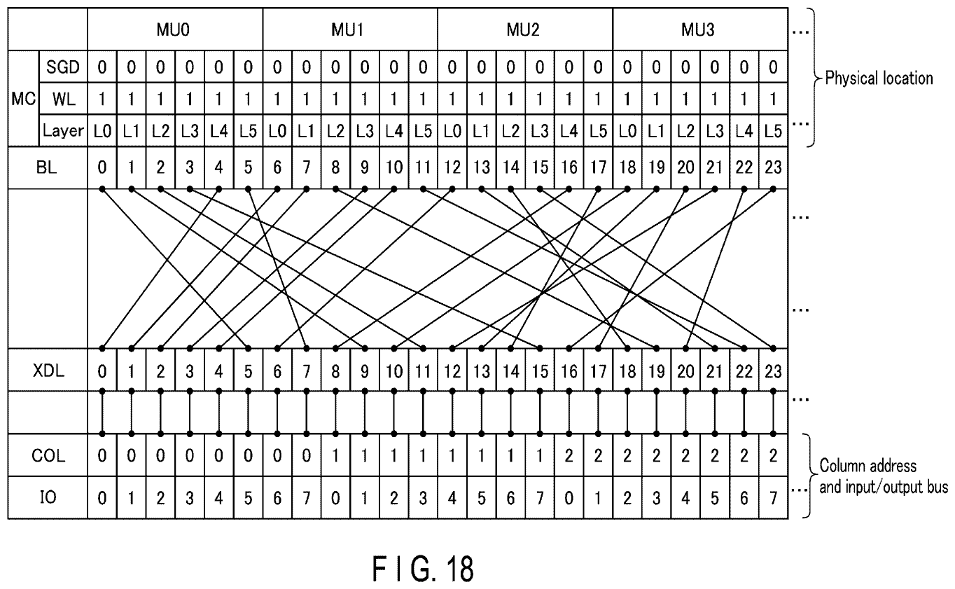

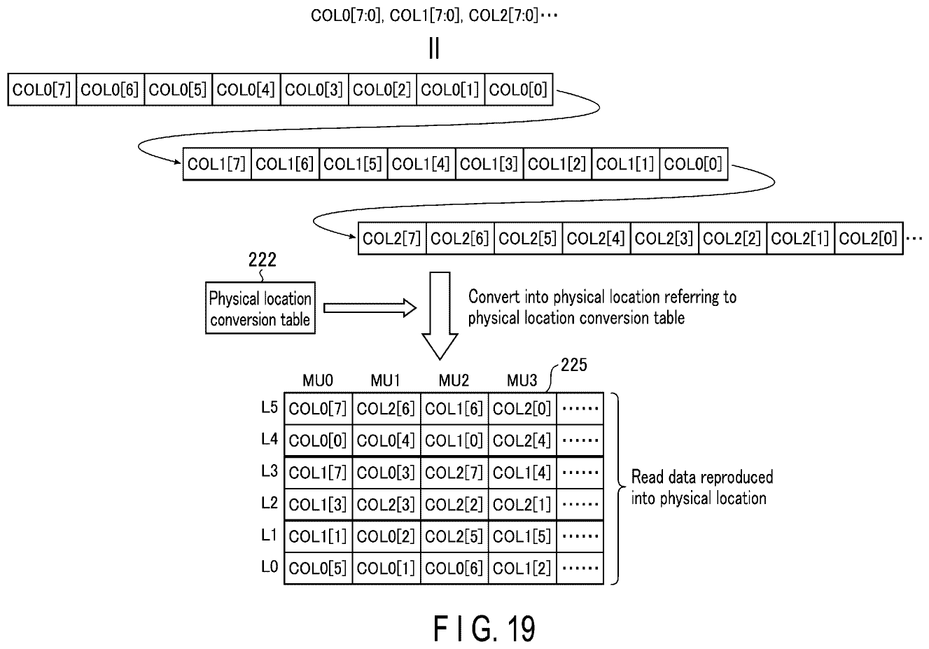

Hereinafter, another example of the correspondence relationship between the read bit location of the read data and the physical location of the memory cell transistor MC in the memory system 1 will be described with reference to FIGS. 18 and 19.

FIG. 18 is a diagram illustrating another example of the connection relationship between the physical location of the memory cell transistor MC of the memory device 100, and the column address and the input/output bus. FIG. 19 is a diagram illustrating, in an upper portion of FIG. 19, the read bit location of read data in the case of satisfying the connection relationship shown in FIG. 18, and in a lower portion thereof, read data 225 in which the physical location is reproduced based on the physical location conversion table.

Although FIG. 16 described above illustrates the case where the bit lines BL0 to BL23 and the latch circuits XDL0 to XDL23 are connected in the order of arrangement, the bit lines BL0 to BL23 and the latch circuits XDL0 to XDL23 are not connected in the order of arrangement in many cases as illustrated in FIG. 18 due to layout constraints in the design stage.

For example, in a case where the memory device 100 is designed (alternatively, at the time of a test of manufacturing processing), the bit line BL0 may be connected to the latch circuit XDL5, or the bit line BL1 may be connected to the latch circuit XDL9. The configuration illustrated in FIG. 18 other than the connection between the bit line BL and the latch circuit XDL is similar to the configuration illustrated in FIG. 16.

Based on the physical location conversion table 222 having the connection relationship illustrated in FIG. 18, as illustrated in FIG. 19, the read bit location of the read data is converted into the read data 225 reproduced into physical location.

In the read data 225 reproduced into physical location, the column addresses COL0 to COL2 and the input/output buses IO0 to IO7 are associated with each memory unit of the memory units MU0 to MU3 and each layer of the layers L0 to L5. For example, the column address COL0 [5] corresponds to the layer L0 of the memory unit MU0. In addition, the column address COL1 [1] corresponds to the layer L1 of the memory unit MU0.

The CPU 230 can identify that the data corresponding to the column address COL0 [5] is written in the memory cell transistor MC in which the layer L0 of the memory unit MU0 is arranged and that the data corresponding to the column address COL1 [1] is written in the memory cell transistor MC arranged in the layer L1 of the memory unit MU0 by referring to the read data 225 reproduced into physical location illustrated in FIG. 19.

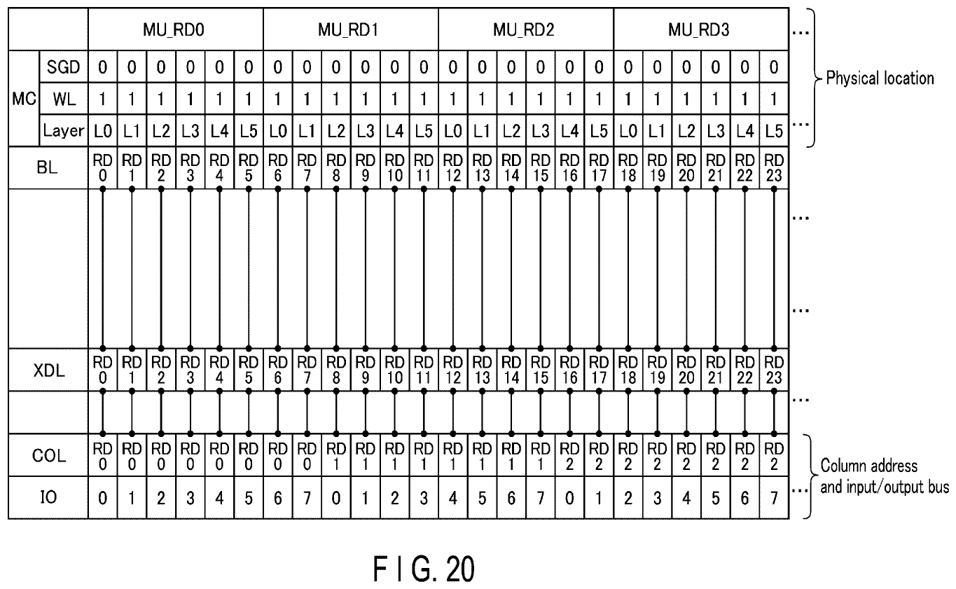

Next, a method of replacing the defective column in the target page (target cell unit CU) with the redundancy column will be described with reference to FIGS. 20, 21, and 22.

FIG. 20 is a diagram illustrating an example of a connection relationship between the physical location of the memory cell transistor MC, and the column address and the input/output bus, in the memory unit of the redundancy provided in the target page. Here, memory units MU_RD0 to MU_RD3 of the redundancy are illustrated as the redundancy column provided in the target page.

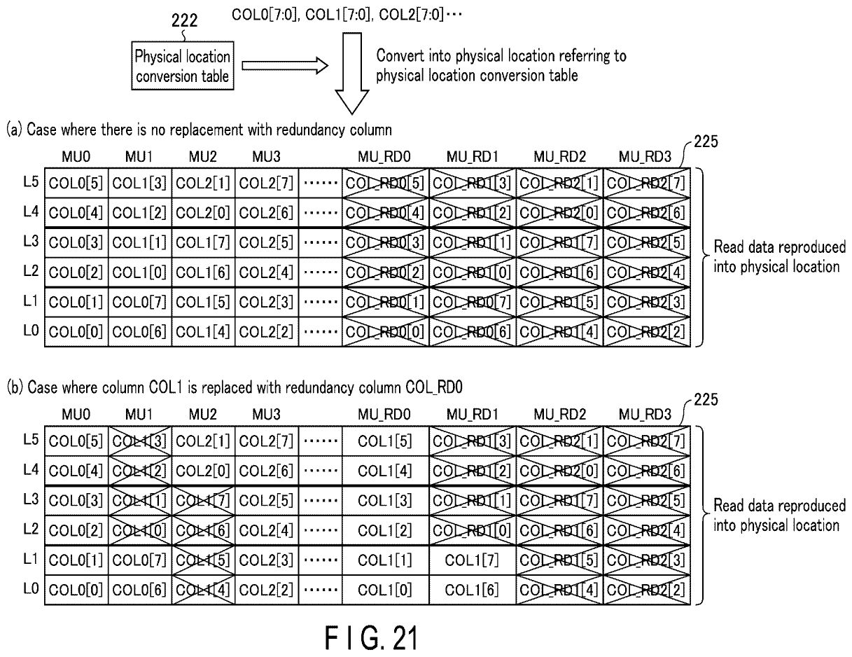

In FIG. 21, (a) is a diagram illustrating the read data 225 reproduced into physical location in a case where there is no replacement of the main column with the redundancy column. In a case where there is no replacement with the redundancy column, data is not output from the “column of the redundancy region” as indicated by x in the figure. Therefore, in a case where the physical location is reproduced, the reading result from the memory cell transistor MC corresponding to columns COL_RD0, COL_RD1, and COL_RD2 in the redundancy region is not output.

In FIG. 21, (b) is a diagram illustrating the read data 225 reproduced into physical location in a case where the main column is replaced with the redundancy column. That is, in FIG. 21, (b) shows the read data reproduced into physical location in a case where the main column COL1 is replaced with the redundancy column COL_RD0. Since the main column COL1 is replaced with COL_RD0, the reading result from the memory cell transistor MC corresponding to the main column COL1 is not output, and the reading result from the memory cell transistor MC corresponding to the redundancy column COL_RD0 is output, as indicated by x in the drawing. In addition, here, since the redundancy columns COL_RD1 and COL_RD2 are not to be replaced, similarly, the reading result from the memory cell transistor MC corresponding thereto is not output.

As illustrated in FIG. 20, for example, the memory cell transistors MC corresponding to the memory units MU_RD0 to MU_RD3, the select gate line SGD0, the word line WL1, and the layers L0 to L5 of the redundancy in the target page of the memory cell array 18 are connected to the bit lines BL_RD0 to BL_RD23 of the redundancy, respectively. Further, the bit lines BL_RD0 to BL_RD23 are respectively connected to latch circuits XDL_RD0 to XDL_RD23 of redundancy provided in the data register 22. The data input/output from the latch circuits XDL_RD0 to XDL_RD23 correspond to the column addresses COL_RD0 to COL_RD2 and the input/output buses IO0 to IO7 of the redundancy.

For example, at the time of the read operation, data corresponding to the column address COL_RD0 and the input/output bus IO2 is read from the memory cell transistor MC arranged in the memory unit MU_RD0, the select gate line SGD0, the word line WL1, and the layer L2 as physical locations. In addition, data corresponding to the column address COL_RD1 and the input/output bus IO3 is read from the memory cell transistors MC arranged in the memory unit MU_RD1, the select gate line SGD0, the word line WL1, and the layer L5 as physical locations.

In the physical location conversion table 222 illustrated in (b) in FIG. 21, the column addresses COL_RD0 to COL_RD2 and the input/output buses IO0 to IO7 are respectively associated with each memory unit of the memory units MU_RD0 to MU_RD3 and each layer of the layers L0 to L5. That is, column addresses COL0 [0], COL0 [1], . . . , COL0 [7], COL2 [0], COL2 [1], . . . , COL2 [7], and COL1 [0], COL1 [1], . . . , COL1 [7] are respectively associated with each of the memory units MU_RD0 to MU_RD3 and each of the layers L0 to L5. For example, the column address COL0 [2] corresponds to the layer L2 of the memory unit MU0. In addition, the column address COL1 [3] corresponds to the layer L3 of the memory unit MU_RD0.

The CPU 230 can identify that the data corresponding to the column address COL0 [2] is written in the memory cell transistor MC arranged in the layer L2 of the memory unit MU0 by referring to the physical location conversion table 222 created in the operation processing at the time of power input illustrated in FIG. 15. In addition, it can be identified that the column address COL1 [3] is written in the memory cell transistor MC arranged in the layer L3 of the memory unit MU_RD0.

As described above, even in a case where the memory cell transistor MC of the column address COL1 [7:0] is replaced with the memory cell transistor MC of the column address COL_RD0 [7:0] of the redundancy, the CPU 230 can identify in which layer L the data corresponding to the column address COL and the input/output bus IO is written to the memory cell transistor MC by referring to the physical location conversion table 222 between the read bit location and the physical location illustrated in (b) in FIG. 21.

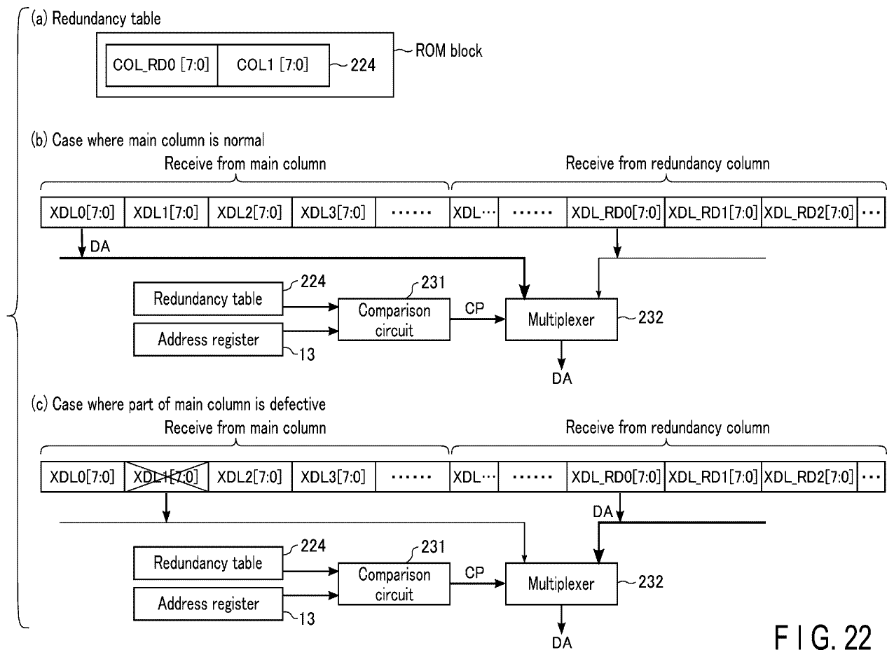

FIG. 22 is a diagram illustrating a circuit configuration for replacing a defective column in a target page in the memory system 1 with a column of redundancy. In FIG. 22, (a) illustrates an example of a redundancy table 224 held in the ROM block of the memory cell array 18. In FIG. 22, (b) and (c) illustrate a comparison circuit 231 and a multiplexer 232 for replacing the defective column with the column of redundancy. The comparison circuit 231 and the multiplexer 232 are provided in, for example, the column decoder 23 and the data register 22.

The redundancy table 224 is held in a ROM block in the memory cell array 18 of the memory device 100. The redundancy table 224 is a table indicating a correspondence relationship between a main column of a replacement source and a redundancy column of a replacement destination in a case where a normally used main column is replaced with a redundancy column. For example, as illustrated in (a) in FIG. 22, in the redundancy table 224, a column address COL_RD0 [7:0] of the redundancy column is associated with a column address COL1 [7:0] of the main column.

The column address of the main column held in the redundancy table 224 and the column address held in the address register 13 are transmitted to the comparison circuit 231. The comparison circuit 231 compares the two received column addresses and outputs a signal CP indicating whether the two column addresses match to the multiplexer 232.

For example, in a case where the comparison circuit 231 compares a column address COL0 [7:0] held in the address register 13 with a column address COL1 [7:0] of the main column held in the redundancy table 224 and indicates that the signals CP do not match each other, the multiplexer 232 receives the data from the main column and outputs the data DA held in the latch circuit, for example, XDL0 [7:0] as illustrated in (b) in FIG. 22. The CPU 230 acquires the data DA from XDL0 [7:0] output from the multiplexer 232.

In addition, in a case where the comparison circuit 231 compares a column address COL1 [7:0] held in the address register 13 with a column address COL1 [7:0] of the main column held in the redundancy table 224 and the signals CP indicate matching, the multiplexer 232 receives the data from the redundancy column and outputs the data DA held in the latch circuit, for example, XDL_RD0 [7:0] as illustrated in (c) in FIG. 22. The CPU 230 acquires the data DA from XDL_RD0 [7:0] output from the multiplexer 232.

With such a circuit, the data of the latch circuit XDL1 [7:0] corresponding to the defective column can be replaced with the data of the latch circuit XDL_RD0 [7:0] of the redundancy corresponding to the redundancy column.

### 2.2 Read Operation

Next, a read operation in the memory system 1 according to the embodiment will be described. The memory system 1 executes a read operation based on a read request from the host device 2. The read operation is an operation of read data written or stored in the memory cell array 18 of the memory device 100 to the memory controller 200 and transferring the read data read to the host device 2.

The RAM 220 of the memory controller 200 stores a shift value history table 221. The shift value history table 221 holds a shift value of the read voltage used in the read operation. The shift value includes a value related to a voltage value to be shifted from the default voltage of the read voltage or a voltage value to be shifted from the default voltage. The storage location of the shift value history table 221 is not limited to the RAM 220, and may be stored at least in an area that can be referred to by the CPU 230.

In the read operation, the CPU 230 refers to the shift value held in the shift value history table 221 and sets the read voltage to which the shift value is applied. The CPU 230 causes the memory device 100 to execute reading using the read voltage to which the shift value is applied. Hereinafter, the read voltage to which the shift value is applied is also referred to as a correction value.

In the following description, a reading result using a read voltage based on the shift value history table 221 is referred to as hard bit data. In addition, in a case where error correction cannot be performed with hard bit data, the error correction capability can be improved by also using a reading result using a voltage obtained by changing the read voltage based on the shift value history table 221 by, for example, voltage ±Δ. At that time, a reading result using a plurality of read voltages changed by the voltage ±Δ is referred to as soft bit data. Error correction processing using hard bit data is referred to as hard bit decoding processing, and error correction processing using hard bit data and soft bit data is referred to as soft bit decoding processing.

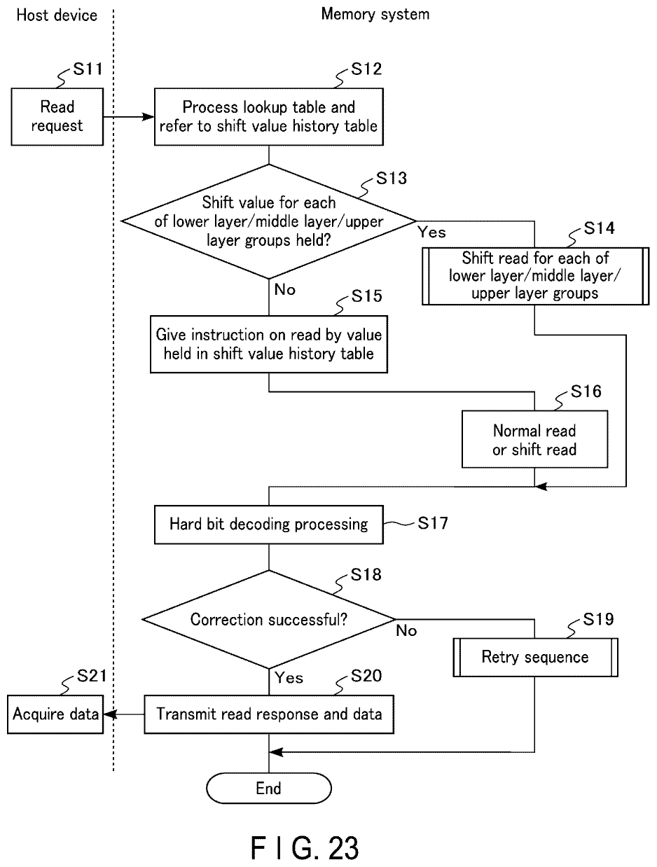

FIG. 23 is a flowchart illustrating an example of a read operation in the memory system 1 according to the embodiment. The processing illustrated in the flowchart is executed by the CPU 230 of the memory controller 200 or the sequencer 15 of the memory device 100.

First, the memory controller 200 receives a read request from the host device 2 (S11). Upon receiving the read request, the CPU 230 of the memory controller 200 refers to the processing of a lookup table and the shift value history table 221 based on the read request to acquire information necessary for the read operation (S12).

The lookup table is a table in which a logical address transmitted from the host device 2 is associated with a physical address including a row address and a column address used in the memory system 1. The CPU 230 refers to the lookup table and acquires the row address and the column address associated with the logical address from the logical address received from the host device 2. Further, the CPU 230 refers to the shift value history table 221 to acquire the default voltage or the shift value.

Next, the CPU 230 determines whether or not a shift value is held for each group of the lower layer group GB, the middle layer group GM, and the upper layer group GT in the shift value history table 221 (S13).

In a case where the shift value is held for each group in the shift value history table 221 (Yes in S13), the CPU 230 causes the memory device 100 to execute shift read for each group on the target page identified by the row address and the column address (S14). For example, in reading the memory cell transistors MC arranged in the layers L0 and L1 included in the lower layer group GB, reading using a read voltage to which a shift value corresponding to the lower layer group GB is applied is executed. In reading the memory cell transistors MC arranged in the layers L2 and L3 included in the middle layer group GM, reading using a read voltage to which a shift value corresponding to the middle layer group GM is applied is executed. In the reading the memory cell transistors MC arranged in the layers L4 and L5 included in the upper layer group GT, reading using a read voltage to which a shift value corresponding to the upper layer group GT is applied is executed. Details of the shift read for each group will be described later.

On the other hand, in a case where the shift value is not held for each group in the shift value history table 221 (No in S13), the CPU 230 causes the memory device 100 to execute reading using the default voltage held in the shift value history table 221 or the read voltage to which the shift value (not for each group) is applied on the target page (S15). As a result, the sequencer 15 of the memory device 100 executes normal read using the read voltage as the default voltage or shift read using the read voltage to which the shift value is applied (S16). The normal read is reading in a case where the default voltage is held in the shift value history table 221. The shift read is reading in a case where a shift value is held in the shift value history table 221. Thereafter, the sequencer 15 transmits the read data read in the normal read or the shift read to the memory controller 200.

Next, the CPU 230 executes hard bit decoding processing on the read data read in the normal read or the shift read. That is, the CPU 230 causes the error checking and correcting circuit 260 to execute error correction processing using the hard bit data (S17).

Next, the CPU 230 determines whether or not error correction has succeeded by hard bit decoding processing (S18).

In a case where the error correction fails in step S18 (No in S18), the CPU 230 executes a retry sequence (S19). In the retry sequence, a plurality of reads is sequentially executed while changing the reading condition. Details of the retry sequence will be described later.

On the other hand, in a case where the error correction succeeds in step S18 (Yes in S18), the CPU 230 transmits the read data after the error correction to the host device 2 together with a reading response (S20). The host device 2 acquires read data (S21). Thus, the read operation ends.

### 2.2.1 Retry Sequence

Hereinafter, the retry sequence in step S19 will be described. As described above, in a case where the error correction by the hard bit decoding processing fails in the read operation, the CPU 230 executes the retry sequence. In the retry sequence, for example, reading using tracking for searching for an optimum read voltage by reading a plurality of times, reading using adjacency correction for correcting the read voltage in consideration of an influence between adjacent memory cells, and (or) soft bit read are executed.

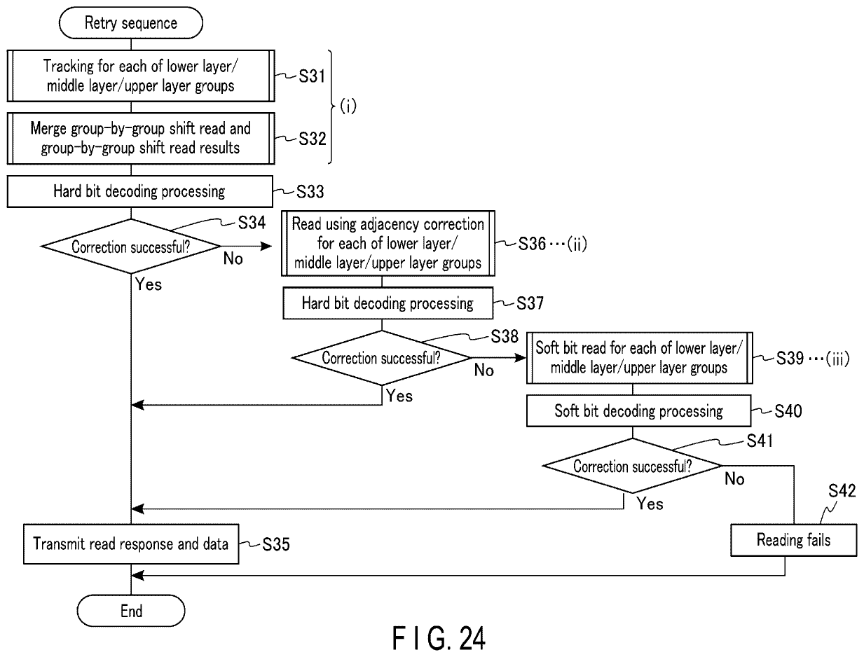

FIG. 24 is a flowchart illustrating an example of a retry sequence in the read operation according to the embodiment. The processing illustrated in the flowchart is executed by the CPU 230 of the memory controller 200 or the sequencer 15 of the memory device 100.

First, the CPU 230 of the memory controller 200 causes the memory device 100 to execute (i) tracking of each group of the lower layer group GB, the middle layer group GM, and the upper layer group GT on the target page (S31). In the tracking for each group, for example, tracking is executed for the memory cell transistors MC arranged in the layers L0 and L1 included in the lower layer group GB. Tracking is similarly executed for the memory cell transistors MC arranged in the layers L2 and L3 included in the middle layer group GM and the memory cell transistors MC arranged in the layers L4 and L5 included in the upper layer group GT. Details of tracking for each group will be described later.

Subsequently, the group-by-group shift read and the group-by-group shift read result are merged (S32). In the shift read for each group, shift read using the read voltage calculated in tracking is executed for each group of the lower layer group GB, the middle layer group GM, and the lower layer group GT. The merge of the shift read results for each group is performed such that the results of the shift read corresponding to each group are fetched. Details of the group-by-group shift read and the merge of the group-by-group shift read results will be described later.

Next, the CPU 230 executes hard bit decoding processing on the read data read by the reading using tracking (S33).

Next, the CPU 230 determines whether or not error correction has succeeded by hard bit decoding processing (S34).

In a case where the error correction succeeds in step S34 (Yes in S34), the CPU 230 transmits the read data after the error correction to the host device 2 together with the reading response (S35). Thereafter, the retry sequence is ended, and the read operation is ended.

On the other hand, in a case where the error correction fails in step S34 (No in S34), the CPU 230 causes the memory device 100 to execute (ii) reading using the adjacency correction on the target page (S36).

In the reading using the adjacency correction, for example, reading using the adjacency correction is executed on the memory cell transistors MC arranged in the layers L0 and L1 included in the lower layer group GB. The reading using the adjacency correction is similarly executed on the memory cell transistors MC arranged in the layers L2 and L3 included in the middle layer group GM and the memory cell transistors MC arranged in the layers L4 and L5 included in the upper layer group GT. (ii) Details of the reading using the adjacency correction will be described later.

Next, the CPU 230 executes hard bit decoding processing on the read data read by the reading using the adjacency correction (S37).

Next, the CPU 230 determines whether or not error correction has succeeded by hard bit decoding processing (S38).

In a case where the error correction succeeds in step S38 (Yes in S38), the CPU 230 transmits the read data after the error correction to the host device 2 together with the reading response (S35). Then, the retry sequence is ended, and the read operation is ended.

On the other hand, in a case where the error correction fails in step S38 (No in S38), the CPU 230 causes the memory device 100 to execute (iii) the soft bit read on the target page (S39). In the soft bit read, for example, the soft bit read is executed on the memory cell transistors MC arranged in the layers L0 and L1 included in the lower layer group GB. The soft bit read is similarly executed on the memory cell transistors MC arranged in the layers L2 and L3 included in the middle layer group GM and the memory cell transistors MC arranged in the layers L4 and L5 included in the upper layer group GT. (iii) Details of the soft bit read will be described later.

Next, the CPU 230 executes soft bit decoding processing on the read data read by the soft bit read. That is, the CPU 230 causes the error checking and correcting circuit 260 to execute error correction processing using the soft bit data (S40). Details of the soft bit decoding processing will be described later.

Next, the CPU 230 determines whether or not error correction has succeeded by soft bit decoding processing (S41).

In a case where the error correction succeeds in step S41 (Yes in S41), the CPU 230 transmits the read data after the error correction to the host device 2 together with the reading response (S35). Thereafter, the retry sequence is ended, and the read operation is ended.

On the other hand, in a case where the error correction has failed in step S41 (No in S41), the CPU 230 determines that the read operation has failed (S42), ends the retry sequence, and ends the read operation.

### 2.2.1.1 Reading Using Tracking

Hereinafter, (i) reading using tracking will be described. As described above, the CPU 230 causes the memory device 100 to execute tracking for each group of the lower layer group GB, the middle layer group GM, and the upper layer group GT (S31). Subsequently, shift read is executed for each group using the read voltage obtained by tracking (S32).

Hereinafter, tracking and shift read will be described in this order.

### (Tracking)

The tracking is an operation of detecting a valley portion between adjacent states in the threshold voltage distribution of the memory cell transistor MC and calculating an optimum read voltage.

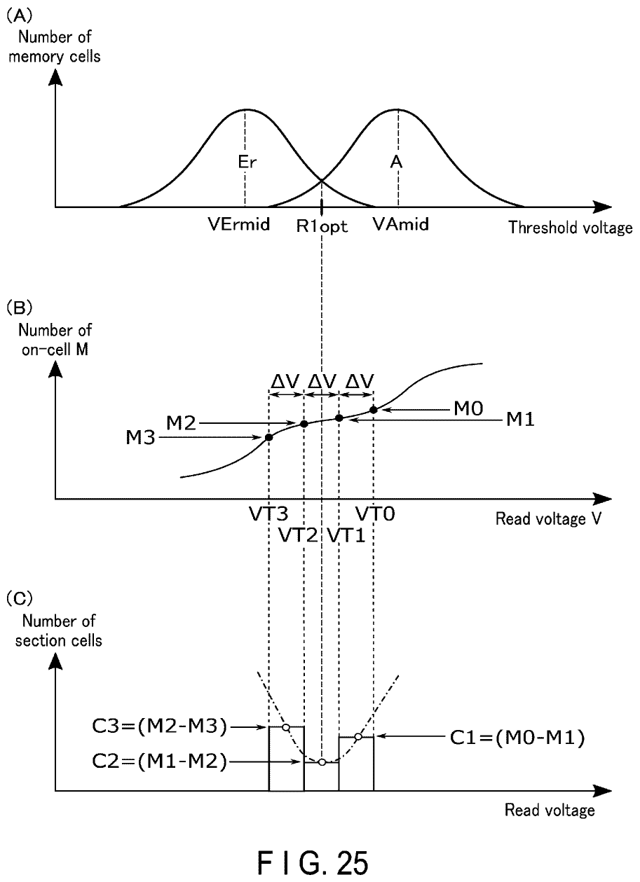

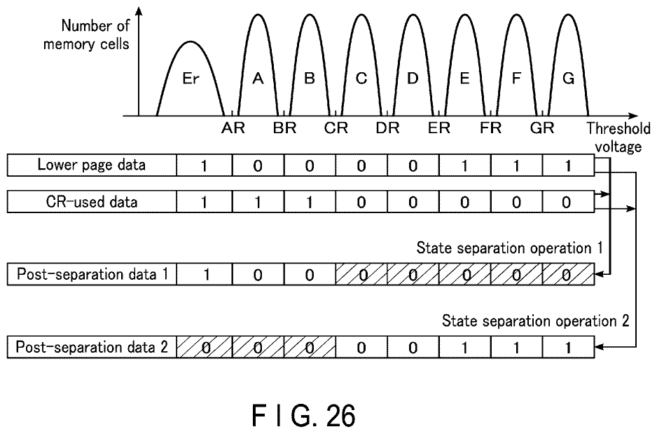

FIGS. 25 and 26 are diagrams illustrating a concept of tracking in the retry sequence according to the embodiment. As an example, in FIG. 25, (A) illustrates threshold voltage distributions of an Er state and an A state among threshold voltage distributions in a certain cell unit CU. The two threshold voltage distributions of the Er state and the A state partially overlap each other due to a change in the threshold voltage immediately after data is written, and a minimum point is formed between the two threshold voltage distributions. In FIG. 25, (B) illustrates a relationship between the read voltage V and the number (hereinafter, the number of on-cells) M of the memory cell transistors MC that are turned on with respect to the read voltage. In FIG. 25, (C) illustrates a change amount (hereinafter, also referred to as the number of section cells) of the number of on-cells between the two read voltages.

As illustrated in (B) in FIG. 25, as the read voltage V is lowered, the number of on-cells M rapidly decreases at a voltage slightly lower than a voltage VAmid, and |dM/dV| becomes maximum. As the read voltage V is further lowered, a decrease rate of the number of on-cells M becomes small, and the decrease rate of the number of on-cells M becomes minimum at a read voltage of a certain value. The minimum value of the decrease rate of the number of on-cells M is zero in a case where the threshold voltage distribution of the Er state and the threshold voltage distribution of the A state do not overlap. However, in a case where these threshold voltage distributions overlap, the minimum value of the decrease rate of the number of on-cells M becomes a positive value that is not zero. As the read voltage V is further lowered, the decrease rate of the number of on-cells M increases again, and |dM/dV| becomes maximum again at a voltage slightly higher than the voltage VErmid.

By estimating the minimum point of the threshold voltage based on such a change in the number of on-cells M, it is possible to detect the read voltage at which the overlapping of the threshold voltage distributions of the Er state and the A state becomes the smallest. Specifically, first, the reading processing is performed using the voltage VT0 as the read voltage. The resulting number of on-cells is M0. Next, the reading processing is performed using a voltage VT1 lower than the voltage VT0 by ΔV as the read voltage. The resulting number of on-cells is defined as M1. Then, the number of the memory cell transistors MC newly turned off while the read voltage decreases from the voltage VT0 to the voltage VT1 is C1=M0−M1 as illustrated in (C) in FIG. 25. That is, the number of memory cells having a threshold voltage between the voltage VT0 and the voltage VT1 is C1. In other words, the number of section cells between the voltage VT0 and the voltage VT1 is C1.

Subsequently, the reading processing is performed using a voltage VT2 lower than the voltage VT1 by ΔV as the read voltage. The number of on-cells as a result is defined as M2. Then, the number of the memory cell transistors MC newly turned off while the read voltage decreases from the voltage VT1 to the voltage VT2 is C2=M1−M2. That is, the number of memory cells (that is, the number of section cells) having a threshold voltage between the voltage VT2 and the voltage VT1 is C2. C1 is greater than C2. Therefore, it is considered that the voltage at which |dM/dV| is minimized is at least lower than the voltage VT1.

Subsequently, the reading processing is performed using a voltage VT3 lower than the voltage VT2 by ΔV as the read voltage. The number of on-cells obtained as a result is defined as M3. Then, the number of the memory cell transistors MC newly turned off while the read voltage decreases from the voltage VT2 to the voltage VT3 is C3=M2−M3. That is, the number of memory cells (the number of section cells) having a threshold voltage between the voltage VT3 and the voltage VT2 is C3. C3 is greater than C2.

As a result, the threshold voltage distribution as indicated by the one-dot chain line can be expressed in (C) in FIG. 25 by the number of section cells (alternatively, the change amount of the number of on-cells). From this threshold voltage distribution, it is estimated that there is a minimum point between the voltage VT1 and the voltage VT2, which is a section where the number of section cells is minimum. The estimated minimum point is a point (hereinafter, also referred to as a valley location) at which the overlapping of the threshold voltage distributions of the Er state and the A state is estimated to be the smallest. Then, the voltage corresponding to the minimum point is the optimum read voltage AR calculated in this tracking. In addition, a difference between the voltage corresponding to the local minimum point and the read voltage AR which is the default voltage is the estimated shift value.

As illustrated in FIG. 13, values in the page data may be distributed to states that are not adjacent to each other. That is, the “1” data in the lower page data is associated with a voltage range equal to or lower than the read voltage AR and a voltage range equal to or higher than the read voltage ER. Therefore, it is difficult to correctly calculate the number of on-cells only with the plurality of pieces of lower page data by the plurality of lower page read executed while shifting the read voltage.

Therefore, as illustrated in FIG. 26, state separation is performed. FIG. 26 illustrates data obtained by the operation by the memory system of the embodiment.

For state separation, the memory controller 200 causes the memory device 100 to perform at least one single-state read. In the single-state read for the state separation purpose, a read voltage located between a plurality of discontinuous voltage ranges to which the same value is allocated, which is determined based on a page to be read, is used. In one example, the read voltage CR is used in the single-state read for reading the lower page.

Data obtained by the single-state read is referred to as separation data. Since the read voltage CR is used in the single-state read of the lower page read here, the data is referred to as CR-used data. Then, an AND operation of the lower page data and the separation data or the inverted data of the separation data is performed.

Specifically, post-separation data 1 having “1” data in the bit of the memory cell transistor MC having the threshold voltage less than the read voltage AR and “0” data in the bit of the memory cell transistor MC having the threshold voltage equal to or higher than the read voltage AR is obtained by the logical product bit operation (state separation operation 1) of the lower page data and the CR-used data.

Similarly, post-separation data 2 having “0” data in the bit of the memory cell transistor MC having the threshold voltage less than the read voltage ER and “1” data in the bit of the memory cell transistor MC having the threshold voltage equal to or higher than the read voltage ER is obtained by the logical product bit operation (state separation operation 2) of the lower page data and the inverted data of the CR-used data.

Similarly, for the middle page data, state separation may be performed using data obtained by single-state read using the read voltage CR and data obtained by single-state read using the read voltage ER. For the upper page data, state separation may be performed by using data obtained by single-state read using the read voltage ER.

The number of on-cells can be correctly calculated by the above-described state separation.

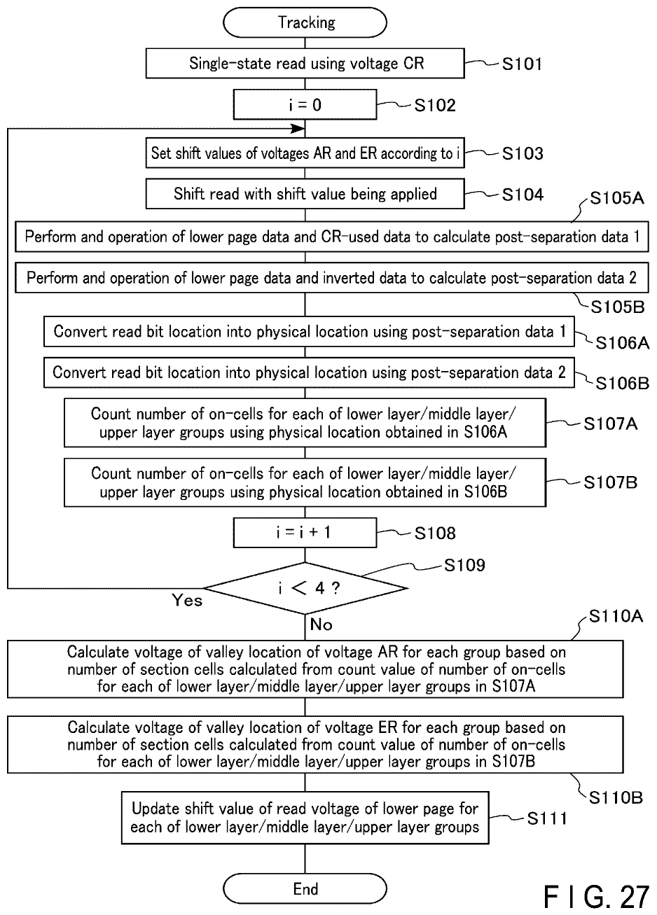

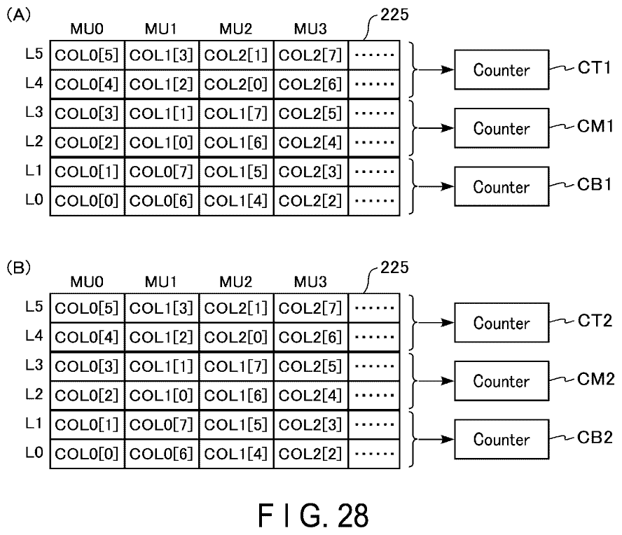

Next, an example of tracking in the retry sequence according to the embodiment will be described. FIG. 27 is a flowchart illustrating an example of tracking in the retry sequence according to the embodiment. The processing illustrated in the flowchart is executed by the CPU 230 of the memory controller 200 or the sequencer 15 of the memory device 100. FIG. 28 illustrates counters for counting the number of on-cells for each group of the lower layer group GB, the middle layer group GM, and the upper layer group GT used in tracking. Here, tracking of the lower page of the target page will be described as an example.

In execution of the tracking read, a variable i, counters CB1, CM1, and CT1, and counters CB2, CM2, and CT2 are prepared. The variable i indicates the number of executions of shift read performed in tracking. The counters CB1, CM1, and CT1 are used to calculate the reading level of the read voltage AR. The counters CB2, CM2, and CT2 are used to calculate the reading level of the read voltage ER. The counters CB1 and CB2 are counters that count the number of on-cells of the memory cell transistors MC of the layers L0 and L1 included in the lower layer group GB. The counters CM1 and CM2 are counters that count the number of on-cells of the memory cell transistors of the layers L2 and L3 included in the middle layer group GM. The counters CT1 and CT2 are counters that count the number of on-cells of the memory cells of the layers L4 and L5 included in the upper layer group GT.

First, the CPU 230 of the memory controller 200 causes the memory device 100 to execute single-state read for state separation using the read voltage CR for the target page (S101). The single-state read is reading processing of acquiring read data indicating the magnitude of a threshold voltage with respect to a read voltage of one state.

Next, the CPU 230 sets the variable i to 0 (S102). The variable i indicates the number of executions of shift read.

Next, the CPU 230 sets shift values of the read voltages AR and ER according to the variable i (S103). Subsequently, the CPU 230 causes the memory device 100 to execute shift read using the read voltage to which the set shift value is applied for the target page (S104).

Next, the CPU 230 acquires the reading result (hereinafter, CR-used data) by the single-state read of the read voltage CR and the reading result (hereinafter, lower page data) by the shift read of the read voltages AR and ER.

Next, as illustrated in FIG. 26, the CPU 230 performs an AND bit operation of the lower page data and the CR-used data to calculate post-separation data 1 (S105A).

Subsequently, the CPU 230 performs an AND bit operation between the lower page data and the inverted data of the CR-used data to calculate post-separation data 2 (S105B).

Next, the CPU 230 converts the read bit location into the physical location of the memory cell transistor MC by referring to the physical location conversion table 222 using the post-separation data 1 (S106A).

Subsequently, the CPU 230 converts the read bit location into the physical location of the memory cell transistor MC with reference to the physical location conversion table 222 using the post-separation data 2 (S106B).

Next, the CPU 230 counts the number of on-cells for each group of the lower layer group GB, the middle layer group GM, and the upper layer group GT using the physical location of the memory cell transistor MC obtained in S106A (S107A). Specifically, the CPU 230 counts the number of on-cells of the memory cell transistors MC of the layers L0 and L1 included in the lower layer group GB. That is, the CPU 230 causes the counter CB1 to count the number of on-cells of the memory cell transistor MC included in the lower layer group GB. Similarly, the CPU 230 counts the number of on-cells of the memory cell transistors MC of the layers L2 and L3 included in the middle layer group GM and the number of on-cells of the memory cell transistors MC of the layers L4 and L5 included in the upper layer group GT. That is, the CPU 230 causes the counters CM1 and CT1 to count the number of on-cells of the memory cell transistor MC included in the middle layer group GM and the number of on-cells of the memory cell transistor MC included in the upper layer group GT, respectively.

Next, the CPU 230 counts the number of on-cells for each group of the lower layer group GB, the middle layer group GM, and the upper layer group GT using the physical location of the memory cell transistor MC obtained in S106B (S107B). Specifically, the CPU 230 counts the number of on-cells of the memory cell transistors MC of the layers L0 and L1 included in the lower layer group GB. That is, the CPU 230 causes the counter CB2 to count the number of on-cells of the memory cell transistor MC included in the lower layer group GB. Similarly, the CPU 230 counts the number of on-cells of the memory cell transistors MC of the layers L2 and L3 included in the middle layer group GM and the number of on-cells of the memory cell transistors MC of the layers L4 and L5 included in the upper layer group GT. That is, the CPU 230 causes the counters CM2 and CT2 to count the number of on-cells of the memory cell transistor MC included in the middle layer group GM and the number of on-cells of the memory cell transistor MC included in the upper layer group GT, respectively.

Next, the CPU 230 increments the variable i (S108). Subsequently, the CPU 230 determines whether the variable i is smaller than 4 (S109). In this embodiment, reading (shift read) performed in tracking is set to four times. The CPU 230 determines whether the number of times of reading has reached 4 by determining whether the variable i is smaller than 4. Note that the number of times of reading performed in tracking can be arbitrarily set.

In a case where the variable i is smaller than 4 in step S108 (Yes in S109), the CPU 230 returns to step S103 and repeats the processing in and after step S103.

On the other hand, in a case where the variable i is not smaller than 4 in step S109 (No in S109), the CPU 230 proceeds to step S110A. In step S110A, the CPU 230 calculates the voltage corresponding to the valley location with respect to the read voltage AR for each group of the lower layer group GB, the middle layer group GM, and the upper layer group GT based on the section cell number calculated from the count value of the number of on-cells for each group of the lower layer group GB, the middle layer group GM, and the upper layer group GT in step S107A.

That is, the CPU 230 calculates the section cell number from the count value of the number of on-cells of the memory cell transistor MC included in the lower layer group GB obtained while the shift read is executed four times. Then, the CPU 230 calculates the voltage corresponding to the valley location of the threshold voltage distribution with respect to the lower layer group GB of the read voltage AR based on the calculated number of section cells.

Similarly, the CPU 230 calculates the section cell number from the count value of the number of on-cells of the memory cell transistor MC included in the middle layer group GM obtained while the shift read is executed four times. Then, the CPU 230 calculates the voltage corresponding to the valley location of the threshold voltage distribution with respect to the middle layer group GM of the read voltage AR based on the calculated number of section cells.

The CPU 230 calculates the section cell number from the count value of the number of on-cells of the memory cell transistor MC included in the upper layer group GT obtained while the shift read is executed four times. Then, the CPU 230 calculates the voltage corresponding to the valley location of the threshold voltage distribution with respect to the upper layer group GT of the read voltage AR based on the calculated number of section cells.

Next, the CPU 230 calculates the voltage corresponding to the valley location with respect to the read voltage ER for each group of the lower layer group GB, the middle layer group GM, and the upper layer group GT based on the section cell number calculated from the count value of the number of on-cells for each group of the lower layer group GB, the middle layer group GM, and the upper layer group GT in step S107B (S110B).

That is, the CPU 230 calculates the section cell number from the count value of the number of on-cells of the memory cell transistor MC included in the lower layer group GB obtained while the shift read is executed four times. Then, the CPU 230 calculates the voltage corresponding to the valley location of the threshold voltage distribution with respect to the lower layer group GB of the read voltage ER based on the calculated number of section cells.

Similarly, the CPU 230 calculates the section cell number from the count value of the number of on-cells of the memory cell transistor MC included in the middle layer group GM obtained while the shift read is executed four times. Then, the CPU 230 calculates the voltage corresponding to the valley location of the threshold voltage distribution with respect to the middle layer group GM of the read voltage ER based on the calculated number of section cells.

The CPU 230 calculates the section cell number from the count value of the number of on-cells of the memory cell transistor MC included in the upper layer group GT obtained while the shift read is executed four times. Then, the CPU 230 calculates the voltage corresponding to the valley location of the threshold voltage distribution with respect to the upper layer group GT of the read voltage ER based on the calculated number of section cells.

Next, the CPU 230 updates the shift values of the read voltages AR and ER with respect to the lower page for each group of the lower layer group GB, the middle layer group GM, and the upper layer group GT held in the shift value history table 221 according to the voltages calculated in steps S110A and S110B (S111). That is, the CPU 230 calculates the difference between the voltage calculated for each group of the lower layer group GB, the middle layer group GM, and the upper layer group GT and the read voltages AR and ER which are the default voltages as the shift values. Subsequently, the CPU 230 updates the shift values held in the shift value history table 221 to the calculated shift values. Thus, the tracking is ended, and the processing returns to step S32.

Tracking of the middle page and the upper page of the target page is also executed by a similar method, and the shift value of the read voltage for the middle page and the upper page is updated.

### (Shift Read)

Next, shift read will be described. The shift read for each group of the lower layer group GB, the middle layer group GM, and the upper layer group GT is executed in a case where the shift value history table 221 holds the shift value for each group (Yes in S13) and in a case where the shift value for each group is acquired by tracking (S31).

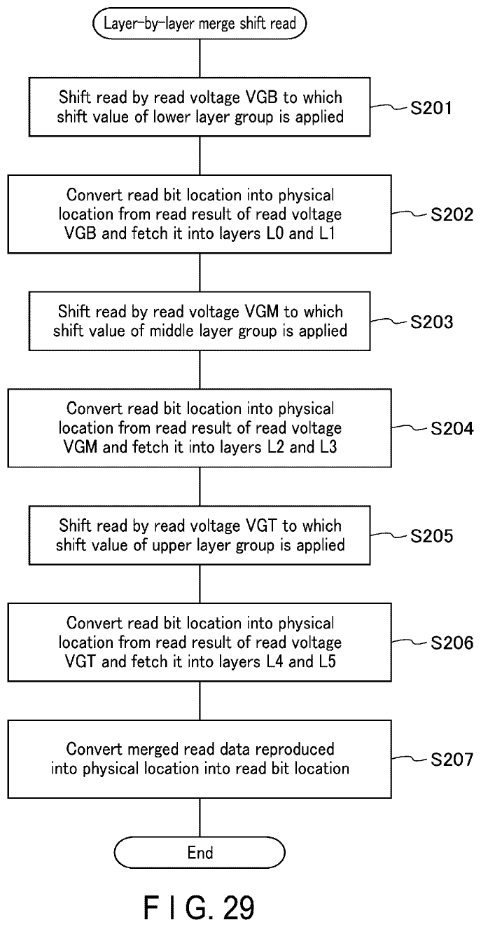

FIG. 29 is a flowchart illustrating processing of merging the group-by-group shift read and the group-by-group shift read results in the read operation according to the embodiment. The processing illustrated in the flowchart is executed by the CPU 230 of the memory controller 200 or the sequencer 15 of the memory device 100.

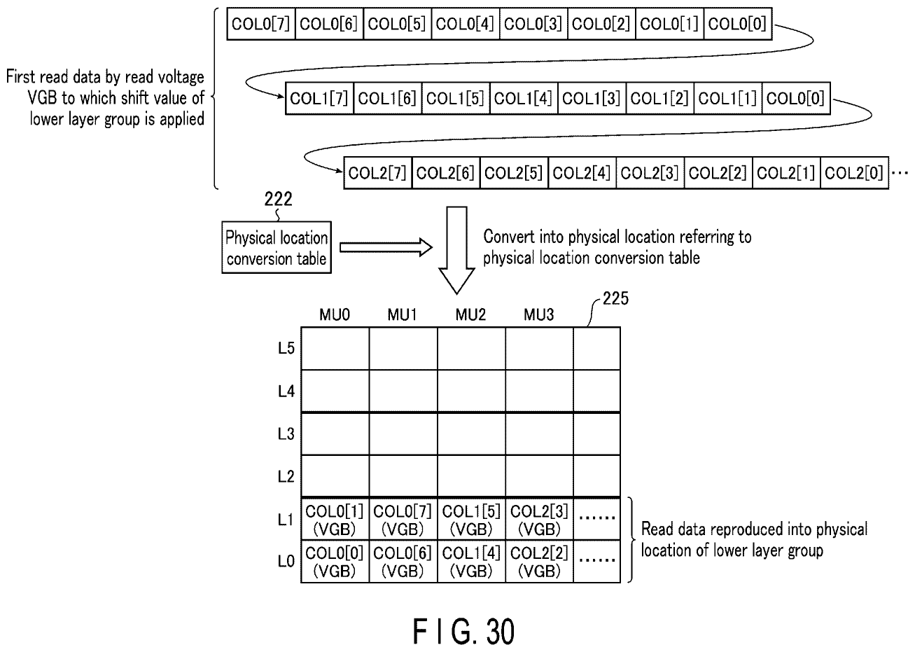

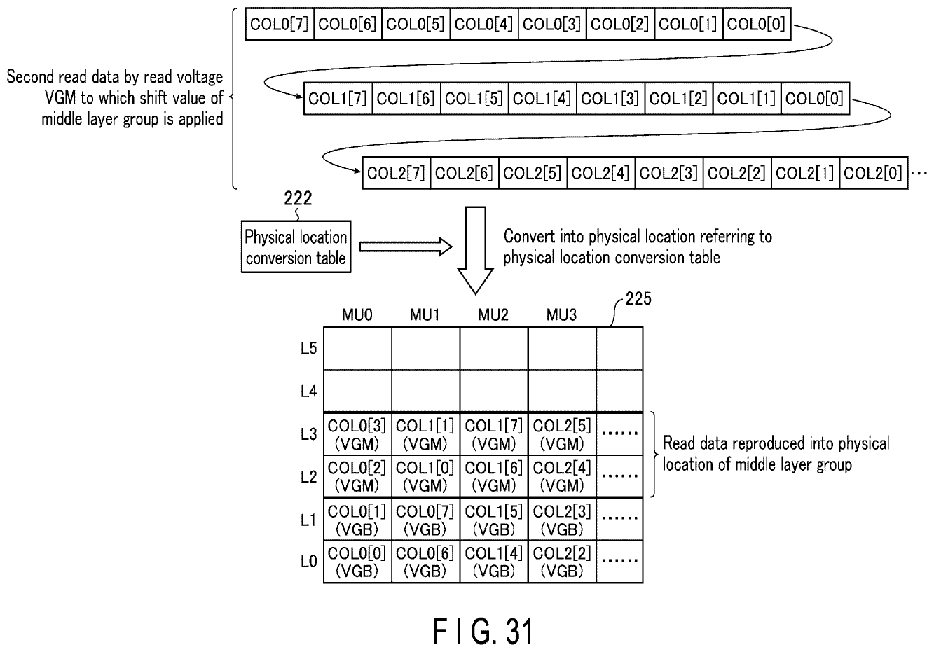

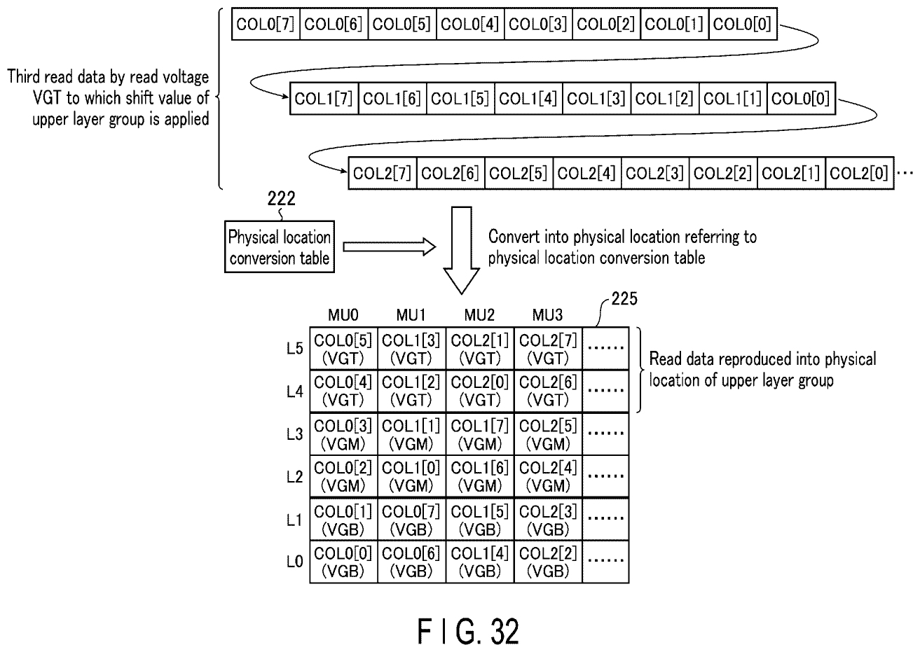

FIGS. 30, 31, and 32 are diagrams illustrating a method of merging the group-by-group shift read and the group-by-group shift read results. FIG. 30 illustrates a method of merging the read data read using the read voltage VGB to which the shift value corresponding to the lower layer group GB is applied and the shift read result for each group. FIG. 31 illustrates a method of merging the read data read using a read voltage VGM to which the shift value of the middle layer group GM is applied and the shift read result for each group. FIG. 32 illustrates a method of merging the read data read using a read voltage VGT to which the shift value of the upper layer group GT is applied and the shift read result for each group. Each of the read voltages VGB, VGM, and VGT is a read voltage to which the optimum shift value calculated by tracking in step S31 is applied.

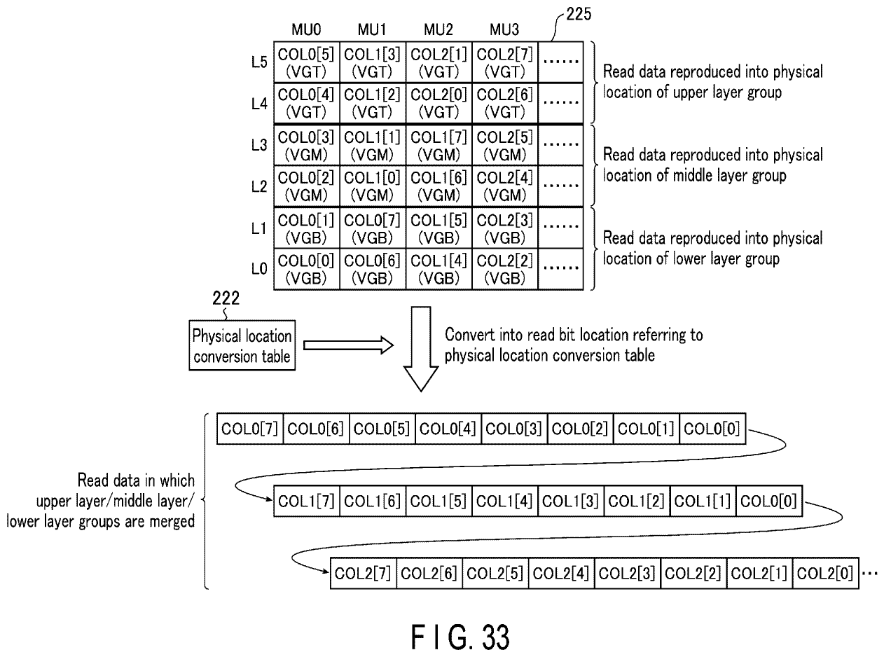

FIG. 33 is a diagram illustrating conversion of the read data 225 reproduced into physical location obtained by merging the read data by the group-by-group shift read into the read bit location.

As illustrated in FIG. 29, first, the CPU 230 of the memory controller 200 causes the memory device 100 to execute shift read to which a shift value corresponding to the lower layer group GB is applied (S201). As a result, the sequencer 15 of the memory device 100 executes reading on the target page using the read voltage (correction value) VGB to which the shift value corresponding to the lower layer group GB is applied. As illustrated in FIG. 30, the CPU 230 receives the first read data read by the reading from the memory controller 200.

Next, the CPU 230 refers to the physical location conversion table 222 to convert the read bit location of the first read data into the physical location of the memory cell transistor MC, and fetches the data corresponding to the lower layer group GB in the first read data into the layers L0 and L1 in the read data in which the physical location is reproduced as illustrated in FIG. 30 (S202).

Next, the CPU 230 causes the memory device 100 to execute shift read to which a shift value corresponding to the middle layer group GM is applied (S203). As a result, the sequencer 15 of the memory device 100 executes reading from the target page using the read voltage (correction value) VGM to which the shift value corresponding to the middle layer group GM is applied. As illustrated in FIG. 31, the CPU 230 receives the second read data read by the reading from the memory controller 200.

Next, the CPU 230 refers to the physical location conversion table 222 to convert the read bit location of the second read data into the physical location of the memory cell transistor MC, and as shown in FIG. 31, fetches data corresponding to the middle layer group GM in the second read data into the layers L2 and L3 in the read data in which the physical location is reproduced (S204).

Next, the CPU 230 causes the memory device 100 to execute shift read to which a shift value corresponding to the upper layer group GT is applied (S205). As a result, the sequencer 15 of the memory device 100 executes reading on the target page using the read voltage (correction value) VGT to which the shift value corresponding to the upper layer group GT is applied. As illustrated in FIG. 32, the CPU 230 receives the third read data read by the reading from the memory controller 200.

Next, the CPU 230 refers to the physical location conversion table 222 to convert the read bit location of the third read data into the physical location of the memory cell transistor MC, and fetches data corresponding to the upper layer group GT in the third read data into the layers L4 and L5 in the read data in which the physical location is reproduced as illustrated in FIG. 32 (S206).

As described above, the read data 225 in which the physical location is reproduced using the optimum read voltage for each is obtained.

Next, the CPU 230 refers to the physical location conversion table 222 to convert the merged read data reproduced into physical location into a read bit location. (S207).

As described above, the CPU 230 ends the merge of the group-by-group shift read and the group-by-group shift read result, returns to step S17 or step S33, and executes the processing of step S17 or step S33 and subsequent steps. Hereinafter, the group-by-group shift read and the merge of the group-by-group shift read results are referred to as a layer-by-layer merge shift read.

### 2.2.1.2 Reading Using Adjacency Correction

First, the adjacency influence degree table 223 used in reading using the adjacency correction will be described. The RAM 220 of the memory controller 200 stores an adjacency influence degree table 223. The adjacency influence degree table 223 holds the adjacency influence degree (hereinafter, also referred to as a rank or a parameter) referred to in the reading using the adjacency correction. The adjacency influence degree is set based on the state of the target memory cell transistor and the state of the memory cell transistor (hereinafter, referred to as an adjacent memory cell transistor or an adjacent reading bit) adjacent to the target memory cell transistor. Here, the adjacent memory cell transistor refers to a memory cell transistor located in an upper layer or a lower layer in the memory unit MU to be read. The adjacency influence degree is set for each state included in the target memory cell transistor. The storage location of the adjacency influence degree table 223 is not limited to the RAM 220, and may be stored at least in an area that can be referred to by the CPU 230.

In reading using the adjacency correction, the CPU 230 refers to the adjacency influence degree held in the adjacency influence degree table 223 and sets the read voltage according to the adjacency influence degree. The CPU 230 causes the memory device 100 to execute reading using the read voltage set according to the adjacency influence degree.

Hereinafter, the adjacency influence degree (rank) set for each state of the target memory cell transistor will be described.

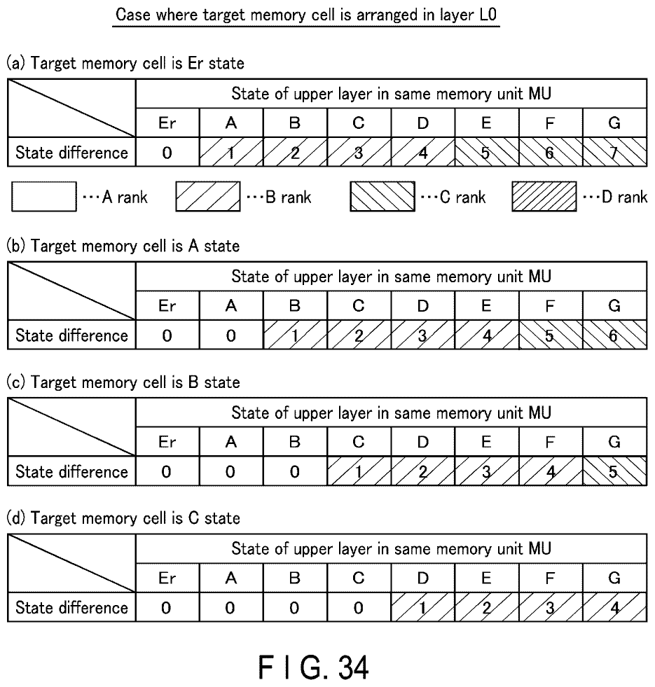

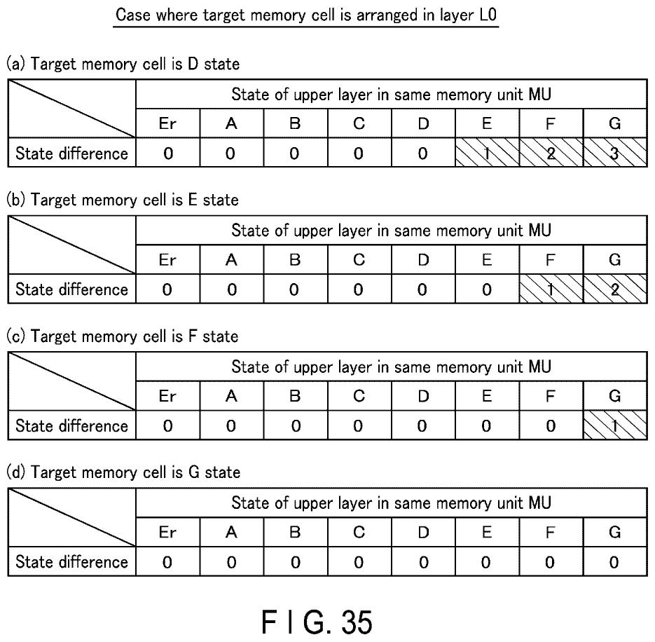

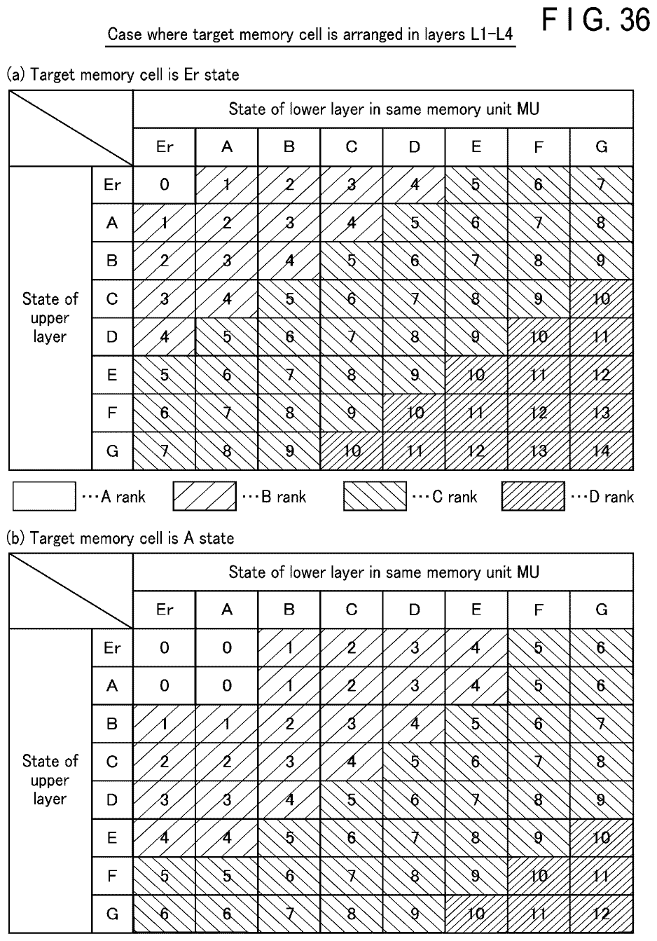

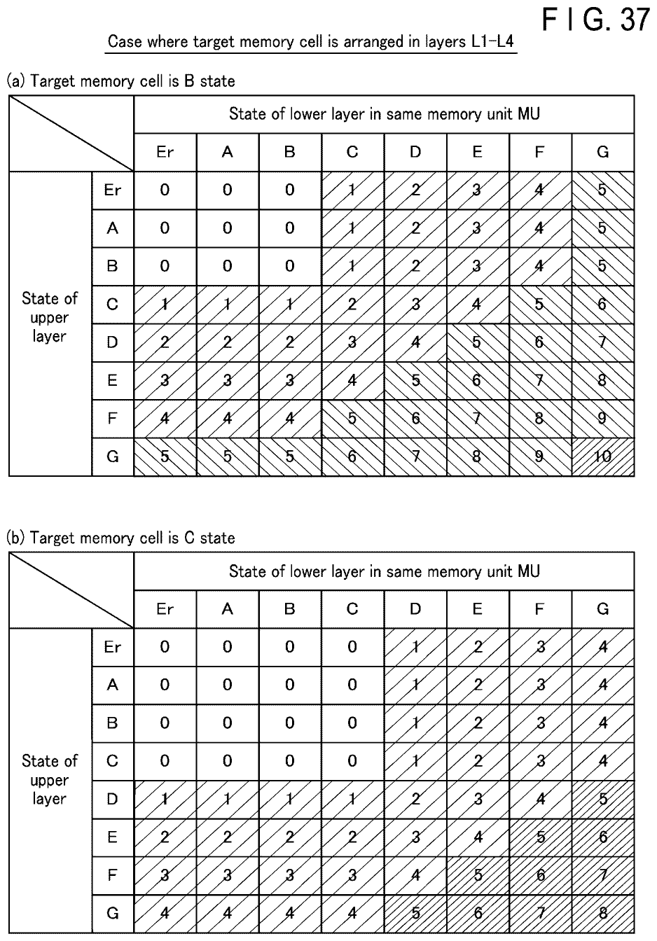

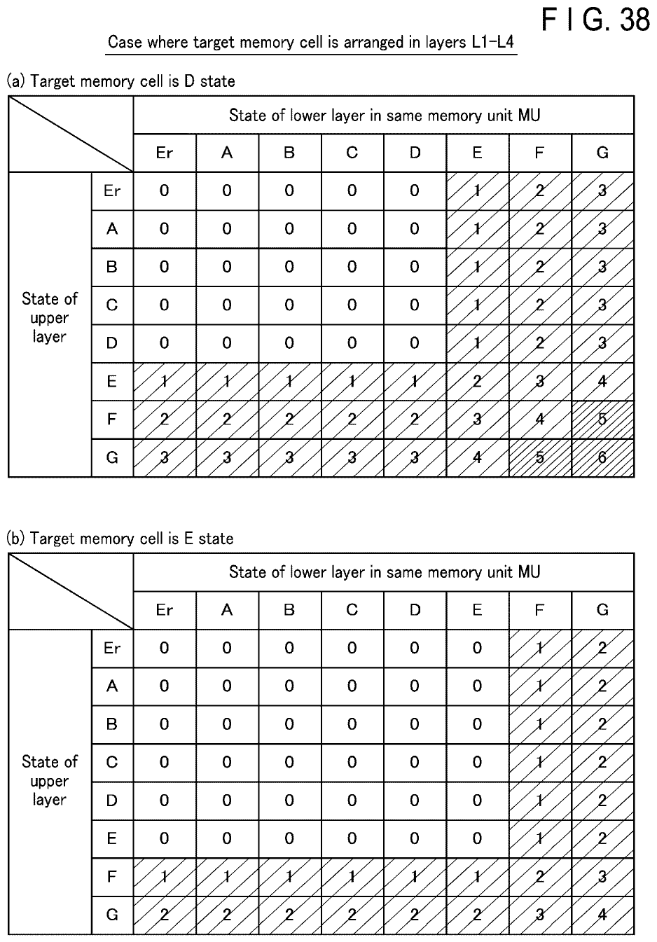

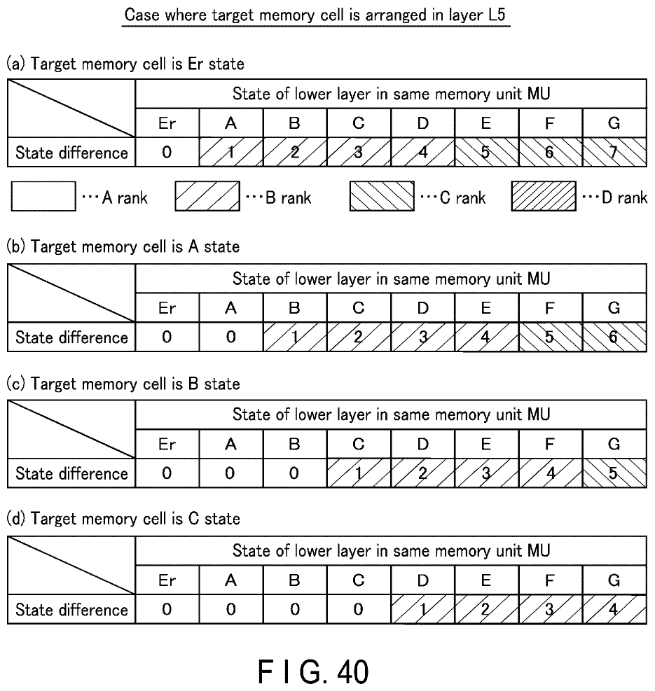

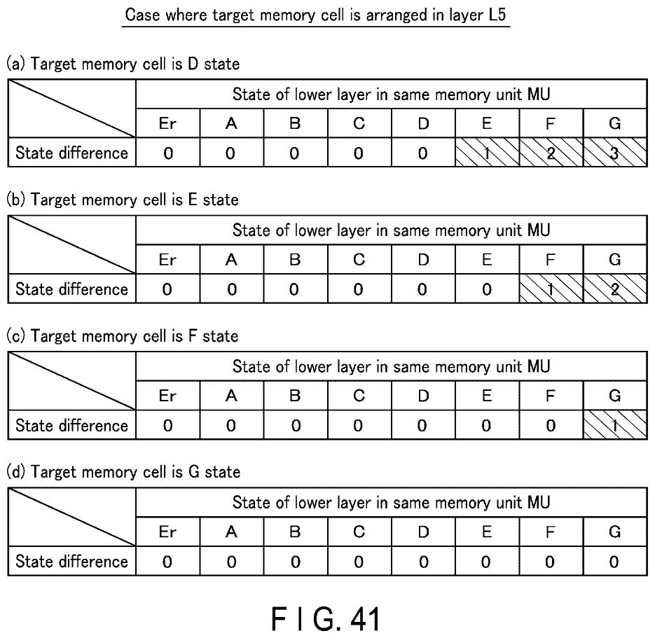

FIGS. 34 to 41 are diagrams illustrating the adjacency influence degree set based on the state of the target memory cell transistor and the state of the adjacent memory cell transistor. FIGS. 34 and 35 are applied to a case where the target memory cell transistor is arranged in the layer L0. FIGS. 36 to 39 are applied in a case where the target memory cell transistors are arranged in the layers L1 to L4. FIGS. 40 and 41 are applied to a case where the target memory cell transistor is arranged in the layer L5.

In a case where the target memory cell transistor is arranged in the lowermost layer L0, the adjacency influence degree is set for the target memory cell transistor according to the state of the target memory cell transistor and the state of the adjacent memory cell transistor arranged in the layer L1 one layer above in the same memory unit MU as the state of the target memory cell transistor.

The adjacency influence degree affects a case where the state of the adjacent memory cell transistor is higher than the state of the target memory cell transistor. For example, as shown in (a) to (d) in FIG. 34 to (a) to (d) in FIG. 35, in a case where the target memory cell transistor is arranged in the layer L0 and has the Er state, the state difference 0 to 7 are obtained between the target memory cell transistor and the adjacent memory cell transistor according to the states Er to G of the adjacent memory cell transistor arranged in the layer L1. Then, a rank A is set in a case where the state difference is 0, a rank B is set in a case where the state difference is 1 to 4, a rank C is set in a case where the state difference is 5 to 9, and a rank D is set in a case where the state difference is 10 to 14. Here, the state difference is defined as 0 in a case where the target memory cell transistor is the C state and the states of the adjacent memory cell transistors are Er to C, 1 in a case where the state is D, 2 in a case where the state is E, 3 in a case where the state is F, and 4 in a case where the state is G.

In a case where the target memory cell transistor is arranged in the layers L1 to L4 of the middle layer, the adjacency influence degree is set according to the state of the target memory cell transistor and the states of the two adjacent memory cell transistors arranged in the layer one layer below and the layer one layer above.

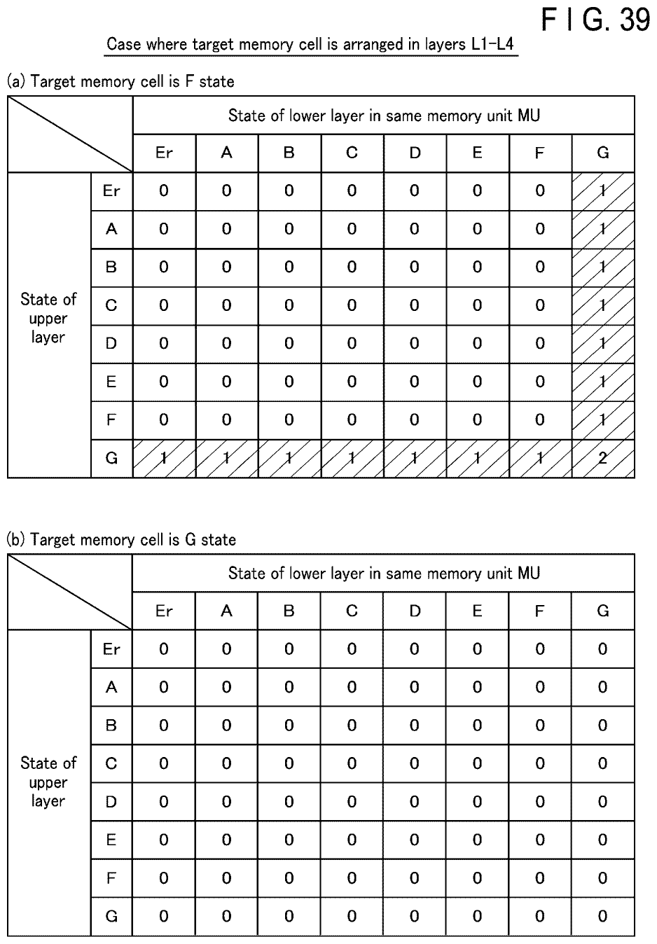

For example, as shown in (a), (b) in FIG. 36 to (a), (b) in FIG. 39, in a case where the target memory cell transistor is arranged in the layer L1 and has the Er state, the state difference 0 to 14 is obtained between the target memory cell transistor and the adjacent memory cell transistor according to the states Er to G of the two adjacent memory cell transistors respectively arranged in the lower layer and the upper layer. As described above, the A to D ranks are set according to the state difference between the target memory cell transistor and the adjacent memory cell transistor.

In addition, in a case where the target memory cell transistor is arranged in the uppermost layer L5, the adjacency influence degree is set for the target memory cell transistor according to the state of the target memory cell transistor and the state of the adjacent memory cell transistor arranged in the layer L4 one layer below.

For example, as shown in (a) to (d) in FIG. 40 and (a) to (d) in FIG. 41, in a case where the target memory cell transistor is arranged in the layer L5 and has the Er state, the state difference 0 to 7 is obtained between the target memory cell transistor and the adjacent memory cell transistor according to the states Er to G of the adjacent memory cell transistor arranged in the layer L4. Similarly, A to C ranks are set according to the state difference between the target memory cell transistor and the adjacent memory cell transistor.

Hereinafter, (ii) reading using the adjacency correction will be described.

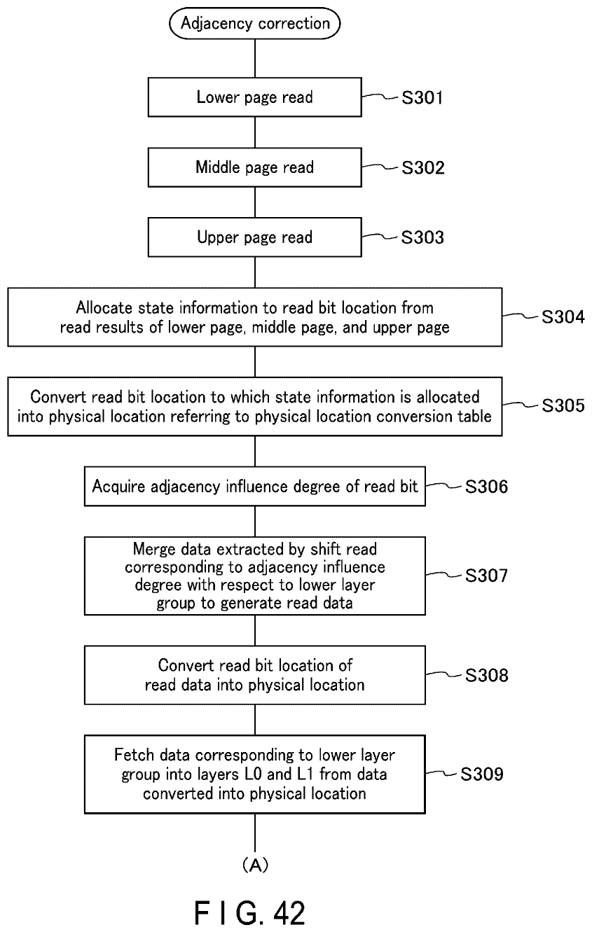

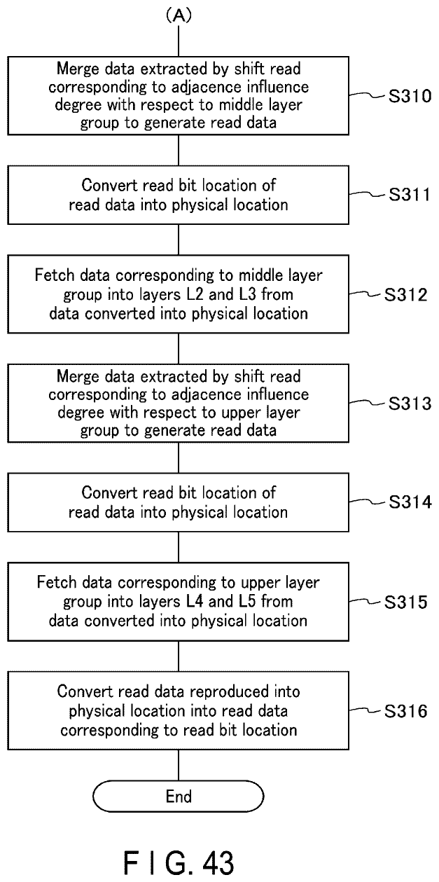

FIGS. 42 and 43 are flowcharts illustrating an example of reading using the adjacency correction in the retry sequence according to the embodiment. The processing illustrated in the flowchart is executed by the CPU 230 of the memory controller 200 or the sequencer 15 of the memory device 100.

First, the CPU 230 of the memory controller 200 causes the memory device 100 to execute the lower page read on the target page (S301). That is, the CPU 230 acquires the shift value corresponding to the lower page from the shift value history table 221. The CPU 230 causes the memory device 100 to execute reading using the read voltage to which the acquired shift value is applied, on the target page. Subsequently, the CPU 230 receives the reading result reading by the sequencer 15 of the memory device 100, that is, the lower page data from the memory device 100.

Next, the CPU 230 causes the memory device 100 to execute the middle page read on the target page (S302). That is, the CPU 230 acquires the shift value corresponding to the middle page from the shift value history table 221. The CPU 230 causes the memory device 100 to execute reading using the read voltage to which the acquired shift value is applied, on the target page. Subsequently, the CPU 230 receives the reading result reading by the sequencer 15 of the memory device 100, that is, the middle page data from the memory device 100.

Next, the CPU 230 causes the memory device 100 to execute the upper page read on the target page (S303). That is, the CPU 230 acquires the shift value corresponding to the upper page from the shift value history table 221. The CPU 230 causes the memory device 100 to execute reading using the read voltage to which the acquired shift value is applied, on the target page. Subsequently, the CPU 230 receives the reading result reading by the sequencer 15 of the memory device 100, that is, the upper page data from the memory device 100.

Next, the CPU 230 allocates state information to each read bit location (alternatively, each memory cell transistor) in the target page from the reading results of the lower page read, the middle page read, and the upper page read, that is, the lower page data, the middle page data, and the upper page data (S304).

Specifically, as illustrated in FIG. 13, in a case where (lower page data, middle page data, and upper page data) is (1,1,1), it can be determined as the Er state. In addition, in a case where (Lower page data, middle page data, and upper page data) is (0, 1, 1), it can be determined as the A state.

Next, the CPU 230 refers to the physical location conversion table 222 and converts the read bit location to which the state information is allocated into the physical location of the memory cell transistor MC (S305).

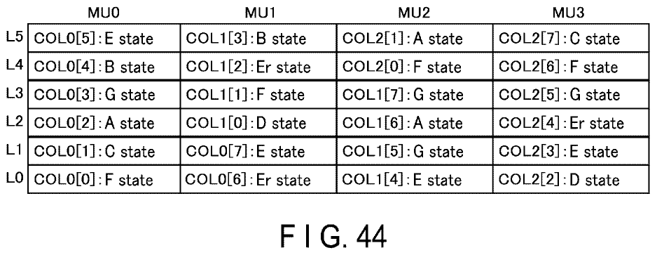

FIG. 44 is a diagram illustrating an example in which the read bit location to which the state information calculated from the reading result of the target page is allocated is converted into the physical location of the memory cell transistor with reference to the physical location conversion table 222. For example, the reading bit of the column address COL0 [0] has the F state, and the physical location of the reading bit is the layer L0 of the memory unit MU0. In addition, the reading bit of the column address COL1 [2] has the Er state, and the physical location of the reading bit is the layer L4 of the memory unit MU1.

Next, the CPU 230 acquires the adjacency influence degree (rank) corresponding to the reading bit based on the adjacency influence degree table 223 from the states of the reading bits and their physical locations (S306).

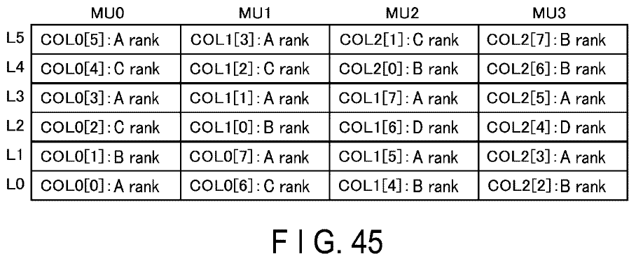

FIG. 45 is a diagram illustrating the adjacency influence degree of the reading bit acquired based on the adjacency influence degree table 223. For example, the reading bit of the column address COL0 [0] has the F state and is arranged in the lowermost layer L0. The reading bit of the column address COL0 [0] arranged in the layer L0 is affected by the adjacent reading bit, that is, the reading bit of the column address COL0 [1] arranged in the layer L1 one layer above. Therefore, the adjacency influence degree of the reading bit of the column address COL0 [0] is set based on the state of the reading bit of the column address COL0 [1] and the state of the reading bit of its own column address COL0 [0].

The reading bit of the column address COL0 [0] has the F state, and the reading bit of the column address COL0 [1] has the C state. Therefore, based on the adjacency influence degree table 223 illustrated in FIG. 35, the CPU 230 acquires the A rank for the reading bit of the column address COL0 [0].

In addition, for example, the reading bit of the column address COL0 [2] has the A state and is arranged in the layer L2 of the middle layer. The reading bits of the column address COL0 [2] arranged in the layer L2 are affected by adjacent reading bits, that is, two reading bits of the column address COL0 [1] and the column address COL0 [3] arranged in the layer L1 of one lower layer and the layer L3 of one upper layer, respectively. Therefore, the adjacency influence degree of the reading bit of the column address COL0 [2] is set based on the state of the reading bit of the column address COL0 [1] and the column address COL0 [3] and the state of the reading bit of its own column address COL0 [2].

The reading bits of the column address COL0 [2] have the A state, and the reading bits of the column addresses COL0 [1] and COL0 [3] have the C and G states, respectively. Therefore, based on the adjacency influence degree table 223 illustrated in FIG. 36, the CPU 230 acquires the C rank for the reading bit of the column address COL0 [2].

In addition, for example, the reading bit of the column address COL1 [3] has the B state and is arranged in the uppermost layer L5. The reading bit of the column address COL1 [3] arranged in the layer L5 is affected by the adjacent reading bit, that is, the reading bit of the column address COL1 [2] arranged in the layer L4 which is one layer lower. Therefore, the adjacency influence degree of the reading bit of the column address COL1 [3] is set based on the state of the reading bit of the column address COL1 [2] and the state of the reading bit of its own column address COL1 [3].

The reading bit of the column address COL1 [3] has the B state, and the reading bit of the column address COL1 [2] has the Er state. Therefore, based on the adjacency influence degree table 223 illustrated in FIG. 40, the CPU 230 acquires the A rank for the reading bit of the column address COL1 [3].

Next, the CPU 230 causes the memory device 100 to execute shift read corresponding to each adjacency influence degree with respect to the reading bits (alternatively, the memory cell transistor) of the layers L0 and L1 included in the lower layer group GB (S307).

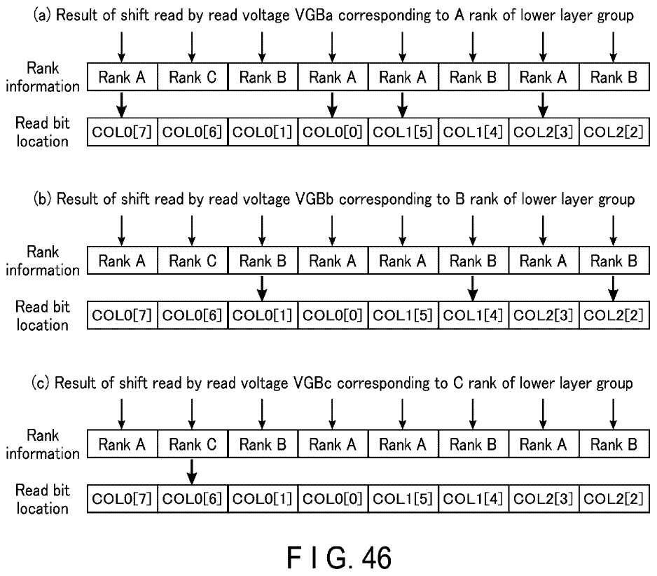

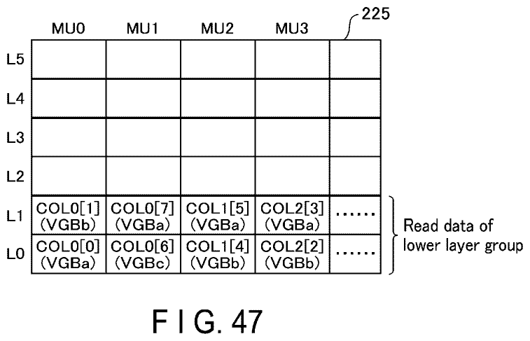

FIG. 46 is a diagram illustrating a state of shift read according to each adjacency influence degree with respect to the lower layer group GB. FIG. 47 is a diagram illustrating the shift read according to each adjacency influence degree with respect to the lower layer group GB and the read data obtained in the subsequent processing. First, the CPU 230 causes the memory device 100 to execute shift read according to the A rank on the lower layer group GB. Specifically, the CPU 230 causes the memory device 100 to execute reading using a read voltage VGBa to which the A rank is applied to the target page. Then, as illustrated in (a) in FIG. 46, the CPU 230 extracts only the data of the reading bits of the column addresses COL0 [7], COL0 [0], COL1 [5], and COL2 [3] set to the A rank from the read data of the target page received from the memory device 100. A read voltage VGBa is a read voltage used to read data from the memory cell transistor MC to which the A rank of the lower layer group GB is set.

Subsequently, the CPU 230 causes the memory device 100 to execute shift read according to the B on the lower layer group GB. Specifically, the CPU 230 causes the memory device 100 to execute reading using the read voltage VGBb obtained by applying the B rank to the target page. Then, as illustrated in (b) in FIG. 46, the CPU 230 extracts only the data of the reading bits of the column addresses COL0 [1], COL1 [4], and COL2 [2] set to the B rank from the read data of the target page received from the memory device 100. A read voltage VGBb is a read voltage used to read data from the memory cell transistor MC to which the B rank of the lower layer group GB is set.

Subsequently, the CPU 230 causes the memory device 100 to execute shift read according to the C rank on the lower layer group GB. Specifically, the CPU 230 causes the memory device 100 to execute reading using the read voltage VGBc obtained by applying the C rank to the target page. Then, as illustrated in (c) in FIG. 46, the CPU 230 extracts only the data of the reading bit of the column address COL0 [6] set to the C rank from the read data of the target page received from the memory device 100. Further, the CPU 230 merges the data extracted in the shift read according to the A rank, the B rank, and the C rank, and generates the read data of the lower layer group GB. A read voltage VGBc is a read voltage used to read data from the memory cell transistor MC to which the C rank of the lower layer group GB is set.

Next, the CPU 230 converts the read bit location in the read data of the lower layer group GB generated in step S307 to the physical location of the memory cell transistor MC (S308). Specifically, the CPU 230 converts the read bit location of the read data obtained by the shift read according to the A rank, the B rank, and the C rank for the lower layer group GB into the physical location of the memory cell transistor MC.

Next, the CPU 230 fetches the data corresponding to the lower layer group GB from the data converted into the physical location in step S308 into the layers L0 and L1 in the read data in which the physical location is reproduced as illustrated in FIG. 47 (S309).

Next, the CPU 230 causes the memory device 100 to execute shift read corresponding to each adjacency influence degree for the reading bits (alternatively, the memory cell transistor) of the layers L2 and L3 included in the middle layer group GM (S310).

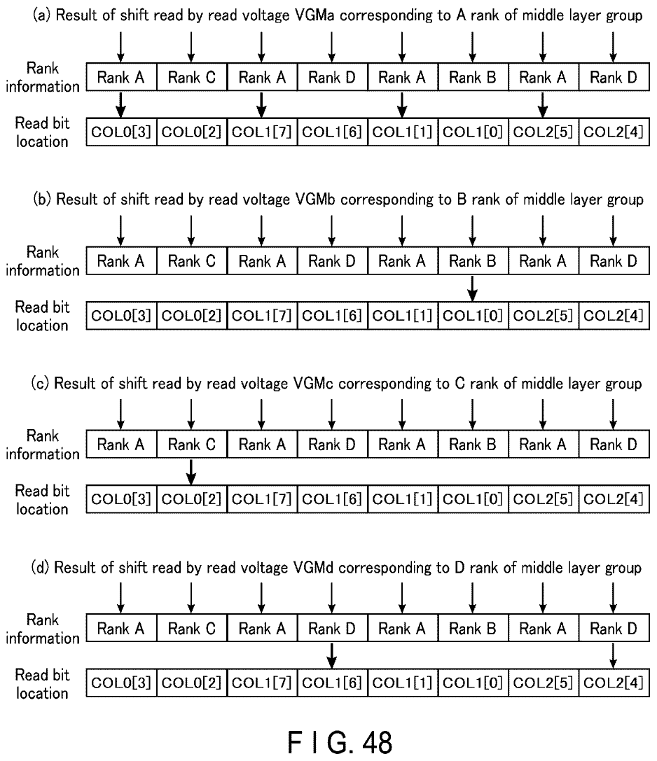

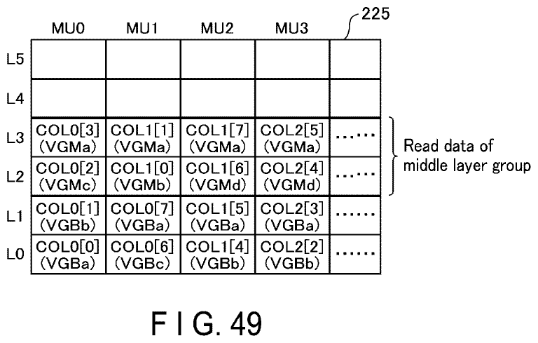

FIG. 48 is a diagram illustrating a state of shift read according to each adjacency influence degree with respect to the middle layer group GM. FIG. 49 is a diagram illustrating the shift read according to each adjacency influence degree on the middle layer group GM and the read data obtained by the subsequent processing. First, the CPU 230 causes the memory device 100 to execute shift read according to the A rank on the middle layer group GM. Specifically, the CPU 230 causes the memory device 100 to execute reading using a read voltage VGMa obtained by applying the A rank to the target page. Then, as illustrated in (a) in FIG. 48, the CPU 230 extracts only the data of the reading bits of the column addresses COL0 [3], COL1 [7], COL1 [1], and COL2 [5] set to the A rank from the read data of the target page received from the memory device 100. The read voltage VGMa is a read voltage used to read data from the memory cell transistor MC to which the A rank of the middle layer group GM is set.

Subsequently, the CPU 230 causes the memory device 100 to execute shift read according to the B rank on the middle layer group GM. Specifically, the CPU 230 causes the memory device 100 to execute reading using a read voltage VGMb to which the B rank is applied to the target page. Then, as illustrated in (b) in FIG. 48, the CPU 230 extracts only the data of the reading bit of the column address COL1 [0] set to the B rank from the read data of the target page received from the memory device 100. The read voltage VGMb is a read voltage used to read data from the memory cell transistor MC to which the B rank of the middle layer group GM is set.

Subsequently, the CPU 230 causes the memory device 100 to execute shift read according to the C rank on the middle layer group GM. Specifically, the CPU 230 causes the memory device 100 to execute reading using a read voltage VGMc obtained by applying the C rank to the target page. Then, as illustrated in (c) in FIG. 48, the CPU 230 extracts only the data of the reading bit of the column address COL0 [2] set to the C rank from the read data of the target page received from the memory device 100. The read voltage VGMc is a read voltage used to read data from the memory cell transistor MC to which the C rank of the middle layer group GM is set.

Subsequently, the CPU 230 causes the memory device 100 to execute shift read according to the D rank on the middle layer group GM. Specifically, the CPU 230 causes the memory device 100 to execute reading using the read voltage VGMd obtained by applying the D rank to the target page. Then, as illustrated in (d) in FIG. 48, the CPU 230 extracts only the data of the reading bits of the column addresses COL1 [6] and COL2 [4] set to the D rank from the read data of the target page received from the memory device 100. Further, the CPU 230 merges the data extracted in the shift read according to the A rank, the B rank, the C rank, and the D rank, and generates the read data of the middle layer group GM. A read voltage VGMd is a read voltage used to read data from the memory cell transistor MC to which the D rank of the middle layer group GM is set.

Next, the CPU 230 converts the read bit location in the read data of the middle layer group GM generated in step S310 into the physical location of the memory cell transistor MC (S311). Specifically, the CPU 230 converts the read bit location of the read data obtained by the shift read according to the A rank, the B rank, the C rank, and the D rank with respect to the middle layer group GM into the physical location of the memory cell transistor MC.

Next, the CPU 230 fetches the data corresponding to the middle layer group GM from the data converted into the physical location in step S311 into the layers L2 and L3 in the read data in which the physical location is reproduced as illustrated in FIG. 49 (S312).

Next, the CPU 230 causes the memory device 100 to execute shift read corresponding to each adjacency influence degree on the reading bits (alternatively, the memory cell transistor) of the layers L4 and L5 included in the upper layer group GT (S313).

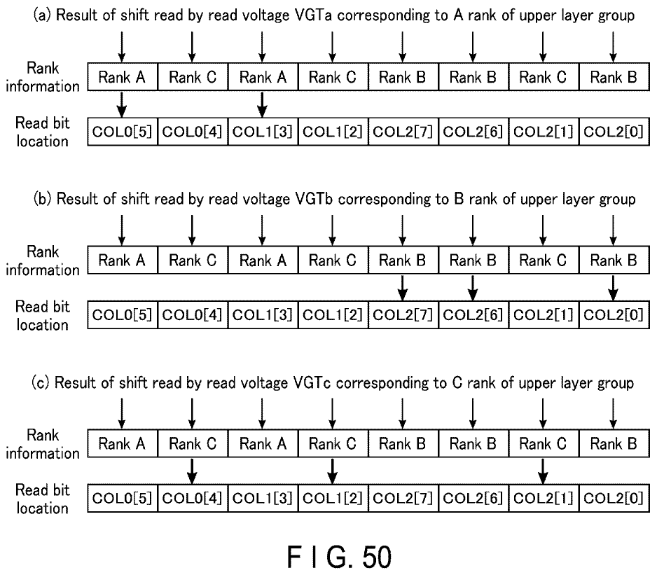

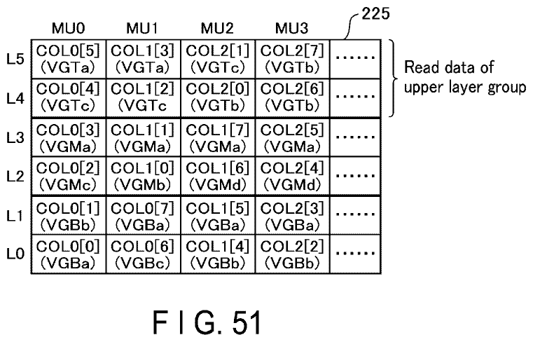

FIG. 50 is a diagram illustrating a state of shift read according to each adjacency influence degree with respect to the upper layer group GT. FIG. 51 is a diagram illustrating shift read according to each adjacency influence degree on the upper layer group GT and read data obtained in subsequent processing. First, the CPU 230 causes the memory device 100 to execute shift read according to the A rank on the upper layer group GT. Specifically, the CPU 230 causes the memory device 100 to execute reading using a read voltage VGTa to which the A rank is applied to the target page. Then, as illustrated in (a) in FIG. 50, the CPU 230 extracts only the data of the reading bits of the column addresses COL0 [5] and COL1 [3] set to the A rank from the read data of the target page received from the memory device 100. The read voltage VGTa is a read voltage used to read data from the memory cell transistor MC to which the A rank of the upper layer group GT is set.

Subsequently, the CPU 230 causes the memory device 100 to execute shift read according to the B rank with respect to the upper layer group GT. Specifically, the CPU 230 causes the memory device 100 to execute reading using a read voltage VGTb obtained by applying the B rank to the target page. Then, as illustrated in (b) in FIG. 50, the CPU 230 extracts only the data of the reading bits of the column addresses COL2 [7], COL2 [6], and COL2 [0] set to the B rank from the read data of the target page received from the memory device 100. A read voltage VGTb is a read voltage used to read data from the memory cell transistor MC to which the B rank of the upper layer group GT is set.

Subsequently, the CPU 230 causes the memory device 100 to execute shift read according to the C rank with respect to the upper layer group GT. Specifically, the CPU 230 causes the memory device 100 to execute reading using the read voltage VGTc obtained by applying the C rank to the target page. Then, as illustrated in (c) in FIG. 50, the CPU 230 extracts only the data of the reading bits of the column addresses COL0 [4], COL1 [2], and COL2 [1] set to the C rank from the read data of the target page received from the memory device 100. Further, the CPU 230 merges the data extracted in the shift read according to the A rank, the B rank, and the C rank, and generates the read data of the upper layer group GT. A read voltage VGTc is a read voltage used to read data from the memory cell transistor MC to which the C rank of the upper layer group GT is set.

Next, the CPU 230 converts the read bit location in the read data of the upper layer group GT generated in step S313 into the physical location of the memory cell transistor MC (S314). Specifically, the CPU 230 converts the read bit location of the read data obtained by the shift read according to the A rank, the B rank, and the C rank with respect to the upper layer group GT into the physical location of the memory cell transistor MC.

Next, the CPU 230 fetches the data corresponding to the upper layer group GT from the data converted into the physical location in step S314 into the layers L4 and L5 in the read data in which the physical location is reproduced as illustrated in FIG. 51 (S315).

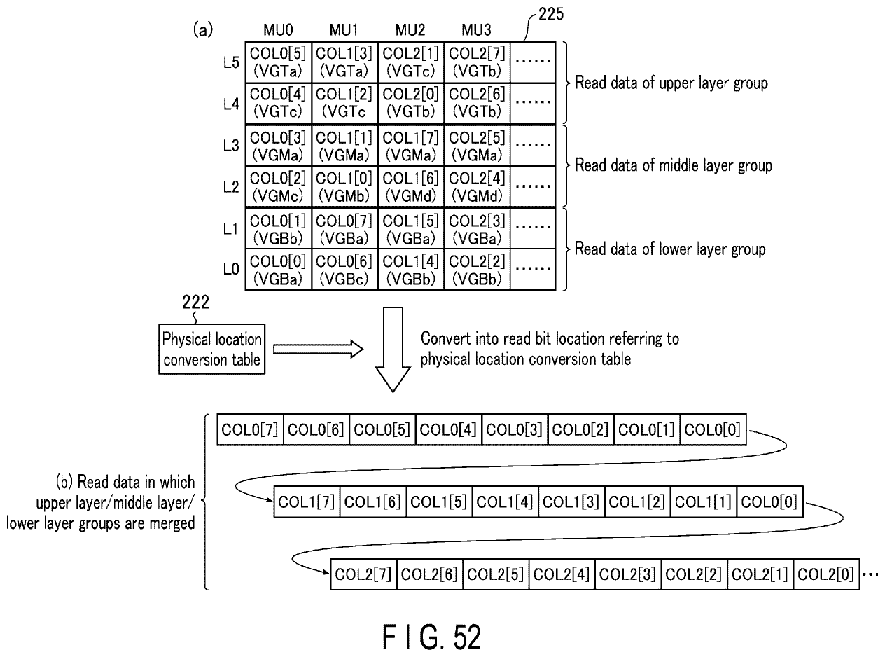

As described above, as illustrated in (a) in FIG. 52, data corresponding to the lower layer group GB, the middle layer group GM, and the upper layer group GT is merged with the read data reproduced into physical location.

Next, the CPU 230 converts the read data reproduced into physical location illustrated in (a) in FIG. 52 into read data corresponding to the read bit location as illustrated in (b) in FIG. 52 (S316).

As described above, the CPU 230 ends the reading using the adjacency correction, returns to step S37, and executes the processing in and after step S37.

Note that, for example, the read voltage used in the above-described shift read is a voltage obtained by adding a shift value to a read voltage as a default voltage. The shift value corresponding to the D rank is larger than the shift value corresponding to the C rank, and the shift value corresponding to the C rank is larger than the shift value corresponding to the B rank. Further, the shift value corresponding to the B rank is larger than the shift value corresponding to the A rank.

### 2.2.1.3 Soft Bit Read

Next, (iii) soft bit read will be described. In the soft bit read, hard bit data and soft bit data are acquired. The hard bit data is data obtained by reading using a read voltage based on the shift value history table 221. The soft bit data is data obtained by reading using a read voltage obtained by shifting a voltage from a read voltage used for reading hard bit data.

Hereinafter, soft bit data generation processing will be described. Here, an operation in a case where the soft bit data generation processing is executed for the lower page will be described.

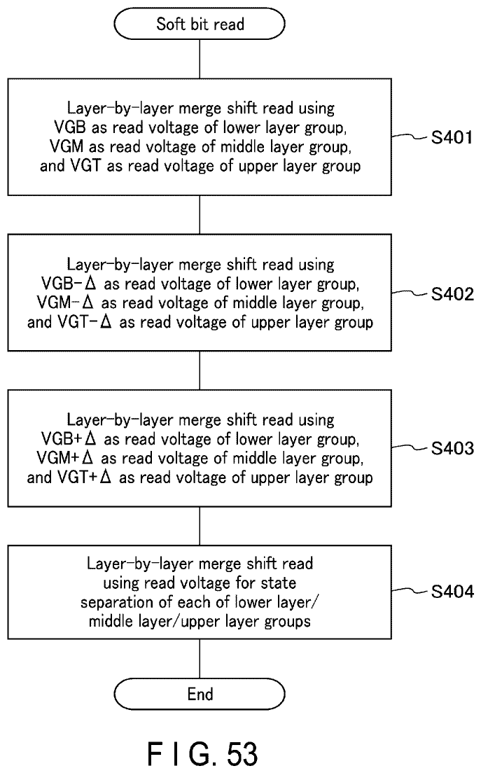

FIG. 53 is a flowchart illustrating an example of soft bit data generation processing in the memory system 1 according to the embodiment. The processing illustrated in the flowchart is executed by the CPU 230 of the memory controller 200 or the sequencer 15 of the memory device 100.

First, the layer-by-layer merge shift read in which VGB is used as the read voltage of the lower layer group GB, VGM is used as the read voltage of the middle layer group GM, and VGT is used as the read voltage of the upper layer group GT with respect to the lower page is performed (S401).

Specifically, the CPU 230 executes the processing of the layer-by-layer merge shift read illustrated in FIG. 29. That is, the CPU 230 causes the memory device 100 to execute shift read using the read voltage VGB corresponding to the lower layer group GB. Subsequently, the CPU 230 converts the read bit location of the read data by the read voltage VGB into the physical location of the memory cell transistor MC. Further, the CPU 230 fetches the data corresponding to the lower layer group GB into the lower layers (layers L0 and L1) in the read data reproduced into physical location in the converted physical location.

Similarly, the CPU 230 causes the memory device 100 to execute shift read using the read voltage VGM corresponding to the middle layer group GM. Subsequently, the CPU 230 converts the read bit location of the read data by the read voltage VGM into the physical location of the memory cell transistor MC, and fetches the data corresponding to the middle layer group GM into the middle layer (layers L2 and L3) in the read data reproduced into physical location.

Similarly, the CPU 230 causes the memory device 100 to execute shift read using the read voltage VGT corresponding to the upper layer group GT. Subsequently, the CPU 230 converts the read bit location of the read data by the read voltage VGT into the physical location of the memory cell transistor MC, and fetches the data corresponding to the upper layer group GT into the upper layer (layers L4 and L5) in the read data reproduced into physical location.

Next, the CPU 230 refers to the physical location conversion table 222 to convert the read data reproduced into physical location obtained by using the read voltages VGB, VGM, and VGT into the read bit location.

Next, the layer-by-layer merge shift read using VGB-Δ as the read voltage of the lower layer group GB, VGM-Δ as the read voltage of the middle layer group GM, and VGT-Δ as the read voltage of the upper layer group GT with respect to the lower page is executed (S402).

Specifically, the CPU 230 executes processing in which the read voltages VGB, VGM, and VGT are replaced with VGB-Δ, VGM-Δ, and VGT-Δ, respectively, in the processing of the layer-by-layer merge shift read illustrated in FIG. 29.

That is, the CPU 230 causes the memory device 100 to execute shift read using the read voltage VGB-Δ corresponding to the lower layer group GB. Subsequently, the CPU 230 converts the read bit location of the read data by the read voltage VGB-Δ into the physical location of the memory cell transistor MC. Further, the CPU 230 fetches the data corresponding to the lower layer group GB into the lower layers (layers L0 and L1) in the read data reproduced into physical location in the converted physical location.

Similarly, the CPU 230 causes the memory device 100 to execute shift read using the read voltage VGM-Δ corresponding to the middle layer group GM. Subsequently, the CPU 230 converts the read bit location of the read data by the read voltage VGM-Δ into the physical location of the memory cell transistor MC, and fetches the data corresponding to the middle layer group GM into the middle layer (layers L2 and L3) in the read data reproduced into physical location.

Similarly, the CPU 230 causes the memory device 100 to execute shift read using the read voltage VGT-Δ corresponding to the upper layer group GT. Subsequently, the CPU 230 converts the read bit location of the read data by the read voltage VGT-Δ into the physical location of the memory cell transistor MC, and fetches the data corresponding to the upper layer group GT into the upper layer (layers L4 and L5) in the read data reproduced into physical location.

Next, the CPU 230 refers to the physical location conversion table 222 to convert the read data reproduced into physical location obtained by using the read voltages VGB-Δ, VGM-Δ, and VGT-Δ into the read bit location.

Next, the layer-by-layer merge shift read using VGB+Δ as the read voltage of the lower layer group GB, VGM+Δ as the read voltage of the middle layer group GM, and VGT+Δ as the read voltage of the upper layer group GT with respect to the lower page is executed (S403).

Specifically, the CPU 230 executes processing in which the read voltages VGB, VGM, and VGT are replaced with VGB+Δ, VGM+Δ, and VGT+Δ, respectively, in the processing of the layer-by-layer merge shift read illustrated in FIG. 29.

That is, the CPU 230 causes the memory device 100 to execute shift read using the read voltage VGB+Δ corresponding to the lower layer group GB. Subsequently, the CPU 230 converts the read bit location of the read data by the read voltage VGB+Δ into the physical location of the memory cell transistor MC. Further, the CPU 230 fetches the data corresponding to the lower layer group GB into the lower layers (layers L0 and L1) in the read data reproduced into physical location in the converted physical location.

Similarly, the CPU 230 causes the memory device 100 to execute shift read using the read voltage VGM+Δ corresponding to the middle layer group GM. Subsequently, the CPU 230 converts the read bit location of the read data by the read voltage VGM+Δ into the physical location of the memory cell transistor MC, and fetches the data corresponding to the middle layer group GM into the middle layer (layers L2 and L3) in the read data reproduced into physical location.

Similarly, the CPU 230 causes the memory device 100 to execute shift read using the read voltage VGT+Δ corresponding to the upper layer group GT. Subsequently, the CPU 230 converts the read bit location of the read data by the read voltage VGT+Δ into the physical location of the memory cell transistor MC, and fetches the data corresponding to the upper layer group GT into the upper layer (layers L4 and L5) in the read data reproduced into physical location.

Next, the CPU 230 refers to the physical location conversion table 222 to convert the read data reproduced into physical location obtained by using the read voltages VGB+Δ, VGM+Δ, and VGT+Δ into the read bit location.

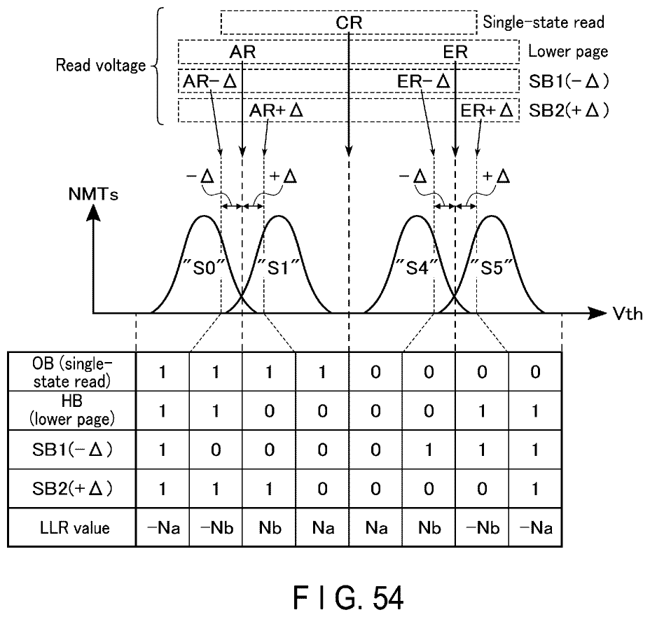

Next, the layer-by-layer merge shift read is performed using the read voltage for state separation for each group of the lower layer group GB, the middle layer group GM, and the upper layer group GT for the lower page (S404, single-state read illustrated in FIG. 54).

Specifically, the CPU 230 executes processing in which the read voltages VGB, VGM, and VGT are replaced with read voltages for state separation for each group in the processing of the layer-by-layer merge shift read illustrated in FIG. 29.

That is, the CPU 230 causes the memory device 100 to execute shift read using a read voltage for state separation corresponding to the lower-layer group GB. Subsequently, the CPU 230 converts the read bit location of the read data by the read voltage for state separation into the physical location of the memory cell transistor MC. Further, the CPU 230 fetches the data corresponding to the lower layer group GB into the lower layers (layers L0 and L1) in the read data reproduced into physical location in the converted physical location.

Similarly, the CPU 230 causes the memory device 100 to execute shift read using a read voltage for state separation corresponding to the middle layer group GM. Subsequently, the CPU 230 converts the read bit location of the read data by the read voltage for state separation into the physical location of the memory cell transistor MC, and fetches the data corresponding to the middle layer group GM into the middle layer (layers L2 and L3) in the read data reproduced into physical location.

Similarly, the CPU 230 causes the memory device 100 to execute shift read using a read voltage for state separation corresponding to the upper layer group GT. Subsequently, the CPU 230 converts the read bit location of the read data by the read voltage for state separation into the physical location of the memory cell transistor MC, and fetches the data corresponding to the upper layer group GT into the upper layer (layers L4 and L5) in the read data reproduced into physical location.

Next, the CPU 230 refers to the physical location conversion table 222 and converts the read data reproduced into physical location obtained by using the read voltage for state separation for each group of the lower layer group GB, the middle layer group GM, and the upper layer group GT into the read bit location.

As described above, the CPU 230 ends the soft bit read and proceeds to the soft bit decoding processing in step S40 in FIG. 24.

The read voltage VGB-Δ is a read voltage obtained by subtracting a predetermined value (Δ) from the read voltage VGB. The read voltage VGM-Δ is a read voltage obtained by subtracting a predetermined value (Δ) from the read voltage VGM. The read voltage VGT-Δ is a read voltage obtained by subtracting a predetermined value (Δ) from the read voltage VGT. The read voltage VGB+Δ is a read voltage obtained by adding a predetermined value (Δ) to the read voltage VGB. The read voltage VGM+Δ is a read voltage obtained by adding a predetermined value (Δ) to the read voltage VGM. The read voltage VGT+Δ is a read voltage obtained by adding a predetermined value (Δ) to the read voltage VGT.

Furthermore, the CPU 230 may execute the soft bit data generation processing using a method other than the method described with reference to FIG. 53. If a similar result can be obtained, the CPU 230 may appropriately replace the order of the processing illustrated in FIG. 53, or may utilize other operations. In addition, the CPU 230 can similarly execute the soft bit data generation processing illustrated in FIG. 53 for pages other than the lower page.

The soft bit decoding processing executed in step S40 will be described below. Here, a soft bit decoding processing executed for the read operation of the lower page will be described as an example.

The soft bit decoding processing is error correction processing using hard bit data and two types of soft bit data (−Δ soft bit data and +Δ soft bit data).

In the soft bit decoding processing, the hard bit data and the soft bit data of the read voltages AR and ER for the lower page are calculated using the soft bit data generation processing illustrated in FIG. 53.

Specifically, in step S401 illustrated in FIG. 53, the CPU 230 executes the layer-by-layer merge shift read using the optimum read voltage AR for each group instead of the read voltages VGB, VGM, and VGT for each group of the lower layer group GB, the middle layer group GM, and the upper layer group GT. Subsequently, in step S402, the layer-by-layer merge shift read is executed using the read voltage AR-Δ for each group instead of the read voltages VGB-Δ, VGM-Δ, and VGT-Δ for each group. In step S403, the layer-by-layer merge shift read is performed using the read voltage AR+Δ for each group instead of the read voltages VGB+Δ, VGM+Δ, and VGT+Δ for each group.

Similarly, also for the read voltage ER, the CPU 230 executes the layer-by-layer merge shift read using the optimum read voltage ER, read voltage ER-Δ, and read voltage ER+Δ for each group.

Similarly, the CPU 230 executes the layer-by-layer merge shift read using the optimum read voltage CR for each group also for the read voltage CR for state separation.

In the memory system 1, the RAM 220 in the memory controller 200 stores a log likelihood ratio (LLR) table. A log likelihood ratio table (hereinafter, referred to as an LLR table) is referred to by the error checking and correcting circuit 260 in the soft bit decoding processing.

The LLR table holds a relationship between each divided range and a log likelihood ratio (LLR) value in a case where a range of the threshold voltage that the memory cell transistor MC can have is divided into a plurality of ranges. The LLR value indicates the reliability (certainty) of data read by a certain read voltage, and is determined by prior evaluation.

FIG. 54 is a schematic diagram illustrating an example of setting of the LLR table in the memory system 1 according to the embodiment. FIG. 54 illustrates an operation in a case where the soft bit data generation processing is executed on the lower page. Furthermore, FIG. 54 illustrates an example of the LLR table in a case where two types of soft bit data (soft bit data SB1 of −A and soft bit data SB2 of +Δ) are used in the soft bit decoding processing for the lower page. Note that the data allocation and the LLR value in each LLR table are merely examples. The LLR value may be a value set in advance by pre-evaluation using the set read voltage of the soft bit.

In the example illustrated in FIG. 54, AR-Δ and ER-Δ are set as read voltages of the −Δ soft bit data SB1, and AR+Δ and ER+Δ are set as read voltages of the +Δ soft bit data SB1. The read voltage CR is set as the read voltage of the single-state read. Then, in this example, the LLR value of the lower page is determined based on the bit data OB of the single-state read, the hard bit data HB of the lower page, and the soft bit data SB1 and SB2 of +Δ and −Δ. Hereinafter, an example of data allocation and an LLR value in the LLR table will be listed.

(Example) “Bit data OB of single-state read/soft bit data SB1 of hard bit data HB/−Δ of lower page/soft bit data SB2 of soft bit data SB1/+Δ”: “LLR value”
“1111” “−Na”
“1101” “−Nb”
“1001” “Nb”
“1000” “Na”
“0000” “Na”
“0010” “Nb”
“0110” “−Nb”
“0111” “−Na”.

As described above, in the LLR table, eight combinations of the bit data OB of the single-state read, the hard bit data HB of the lower page, and the soft bit data SB1 and SB2 of −Δ and +Δ are formed. Then, the LLR value of the lower bit is allocated to each of the formed eight types of combinations.

The absolute value of “Na” is larger than the absolute value of “Nb”. The magnitude of the absolute value of the LLR value indicates the likelihood of hard bit=“0” data. For example, in two adjacent states, the smaller the absolute value of the LLR value is, the lower the ratio of bits that are erroneously reading is.

The error checking and correcting circuit 260 can execute soft bit decoding processing of the lower page data by using such an LLR table.

As described above, the CPU 230 ends the soft bit decoding processing in step S40, proceeds to step S41, and executes the processing in and after step S41.

### 2.3 Read Voltage Optimization Operation

The memory system 1 according to the embodiment can spontaneously execute the read voltage optimization operation in a period in which the operation based on an instruction from the host device 2 is not executed. In other words, the memory system 1 according to the embodiment can execute the read voltage optimization operation independently of the instruction from the host device 2 during the background operation.

The read voltage optimization operation is an operation of optimizing the read voltage used in the read operation in the memory system 1, and is an operation of calculating an appropriate read voltage used in the read operation and updating the shift value history table 221 based on the calculated read voltage.

The read voltage optimization operation contributes to reduction of reading errors in the memory system 1 and acceleration of the read operation. For example, the memory system 1 executes the read voltage optimization operation for all pages in all the blocks BLK of the memory device 100 every predetermined period.

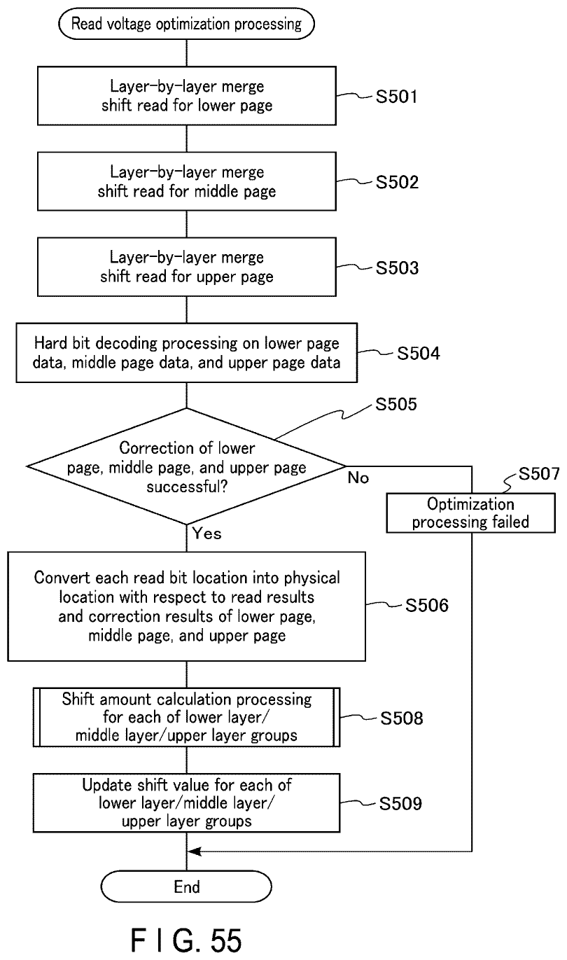

FIG. 55 is a flowchart illustrating an example of processing of the read voltage optimization operation in the memory system according to the embodiment. The processing illustrated in the flowchart is executed by the CPU 230 of the memory controller 200 or the sequencer 15 of the memory device 100.

As illustrated in FIG. 55, first, the layer-by-layer merge shift read for the lower page is executed (S501).

Specifically, the CPU 230 executes the processing of step S401 illustrated in FIG. 53 on the lower page. That is, the layer-by-layer merge shift read using VGB as the read voltage of the lower layer group GB, VGM as the read voltage of the middle layer group GM, and VGT as the read voltage of the upper layer group GT with respect to the lower page is executed. Specifically, as the read voltages VGB, VGM, and VGT, the layer-by-layer merge shift read is performed using the read voltage AR set for each group of the lower layer group GB, the middle layer group GM, and the upper layer group GT. Furthermore, as the read voltages VGB, VGM, and VGT, the layer-by-layer merge shift read is performed using the read voltage ER set for each group of the lower layer group GB, the middle layer group GM, and the upper layer group GT. As a result, the CPU 230 acquires the lower page data.

Next, the layer-by-layer merge shift read for the middle page is executed (S502).

Specifically, the CPU 230 executes the processing of step S401 illustrated in FIG. 53 on the middle page. That is, the layer-by-layer merge shift read using VGB as the read voltage of the lower layer group GB, VGM as the read voltage of the middle layer group GM, and VGT as the read voltage of the upper layer group GT with respect to the middle page is executed. Specifically, as the read voltages VGB, VGM, and VGT, the layer-by-layer merge shift read is performed using the read voltage BR set for each group of the lower layer group GB, the middle layer group GM, and the upper layer group GT. As the read voltages VGB, VGM, and VGT, the layer-by-layer merge shift read is performed using the read voltage DR set for each group of the lower layer group GB, the middle layer group GM, and the upper layer group GT. As the read voltages VGB, VGM, and VGT, the layer-by-layer merge shift read is performed using the read voltage FR set for each group of the lower layer group GB, the middle layer group GM, and the upper layer group GT. As a result, the CPU 230 acquires the middle page data.

Next, the layer-by-layer merge shift read for the upper page is executed (S503).

Specifically, the CPU 230 executes the processing of step S401 illustrated in FIG. 53 on the upper page. That is, the layer-by-layer merge shift read using VGB as the read voltage of the lower layer group GB, VGM as the read voltage of the middle layer group GM, and VGT as the read voltage of the upper layer group GT with respect to the upper page is executed. Specifically, as the read voltages VGB, VGM, and VGT, the layer-by-layer merge shift read is performed using the read voltage CR set for each group of the lower layer group GB, the middle layer group GM, and the upper layer group GT. Further, as the read voltages VGB, VGM, and VGT, the layer-by-layer merge shift read is performed using the read voltage GR set for each group of the lower layer group GB, the middle layer group GM, and the upper layer group GT. As a result, the CPU 230 acquires the upper page data.

In the read operation in steps S501 to S503, a read voltage based on the shift value held in the shift value history table 221 is used. In a case where the shift value corresponding to each group of the lower page, the middle page, and the upper page is not held in the shift value history table 221, a default voltage may be used, or a read voltage to which a shift value not corresponding to each group is applied may be used.

The CPU 230 executes hard bit decoding processing on the acquired lower page data, middle page data, and upper page data (S504).

Next, the CPU 230 determines whether or not error correction of all of the lower page data, the middle page data, and the upper page data has succeeded (S505).

In a case where the error correction is successful in step S505 (Yes in S505), the CPU 230 proceeds to step S506 and executes the processing in and after step S506. On the other hand, in a case where the error correction has failed (No in S505), the CPU 230 proceeds to step S507, determines that the read voltage optimization processing has failed, and ends the processing.

In step S506, the CPU 230 converts the read bit location into the physical location of the memory cell transistor MC for each of the reading result of the lower page (lower page data), the correction result thereof, the reading result of the middle page (middle page data), the correction result thereof, the reading result of the upper page (upper page data) and the correction result thereof.

Next, the CPU 230 executes shift amount calculation processing for each group of the lower layer group GB, the middle layer group GM, and the upper layer group GT (S508). Details of the shift amount calculation processing will be described later.

Next, the CPU 230 updates the shift value for the lower page of each group of the lower layer group GB, the middle layer group GM, and the upper layer group GT held in the shift value history table 221 to the shift amount (that is, the shift value) calculated by the shift amount calculation processing (S509). As described above, the CPU 230 ends the read voltage optimization processing.

### 2.3.1 Shift Amount Calculation Processing

In the shift amount calculation processing, an optimum correction value of the read voltage is calculated according to the number of fail bits generated between two adjacent states. In the memory system 1 according to the embodiment, the shift value of the read voltage is managed not only for each word line WL (alternatively, the page) but also for each group of the lower layer group GB, the middle layer group GM, and the upper layer group GT.

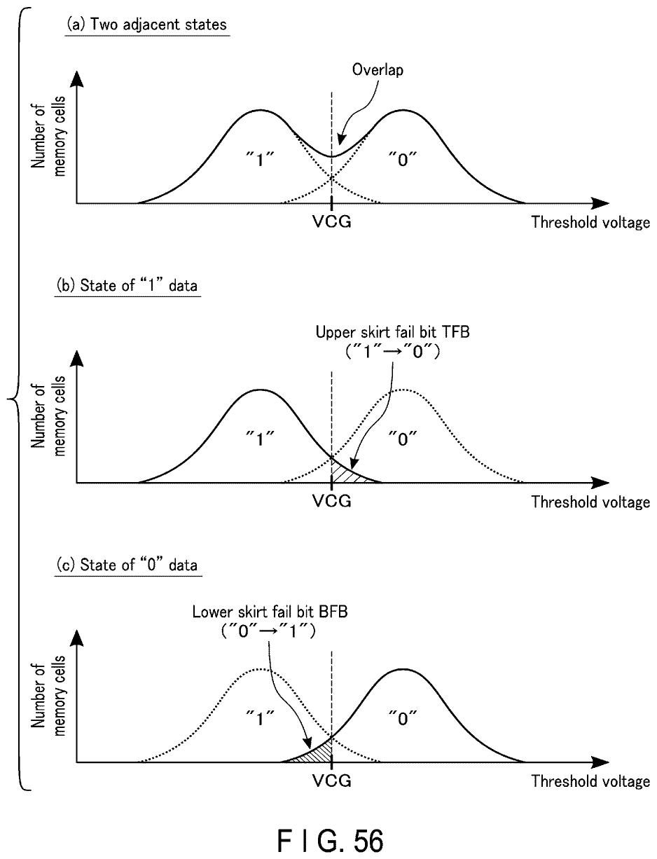

First, the fail bit used in the shift amount calculation processing will be described with reference to FIG. 56.

FIG. 56 is a schematic diagram illustrating an example of fail bits between two adjacent states in the memory system 1 according to the embodiment. In FIG. 56, (a) illustrates a state in which overlapping portions between two adjacent states are added. In FIG. 56, (b) and (c) illustrate overlapping portions between two adjacent states independently. Furthermore, in (b), (c) in FIG. 56, states corresponding to the “1” data and the “0” data are indicated by solid lines, and the other state is indicated by broken lines.

As illustrated in FIG. 56, one of the two states corresponds to “1” data, and the other corresponds to “0” data. In addition, the voltage VCG is a read voltage set between the state of “1” data and the state of “0” data. It is desirable that two adjacent states are separated. However, as illustrated in (a) in FIG. 56, an overlapping portion may be formed in two adjacent states. The overlapped portion includes a fail bit of one of the two adjacent states.

As shown in (b) in FIG. 56, in the state corresponding to the “1” data, data of the memory cell transistor MC whose threshold voltage is equal to or higher than the read voltage VCG is a fail bit. The fail bit is detected to be changed from “1” data to “0” data by error correction processing, and is corrected to “1” data.

As shown in (c) in FIG. 56, in the state corresponding to the “0” data, data of the memory cell transistor MC whose threshold voltage is less than the read voltage VCG is a fail bit. The fail bit is detected to be changed from “0” data to “1” data by error correction processing, and is corrected to “0” data.

Data definitions in two adjacent states illustrated in FIG. 56 may be interchanged. Hereinafter, among the two adjacent states, the fail bit generated at an upper skirt of the state having the lower threshold voltage is referred to as an upper skirt fail bit TFB, and the fail bit generated at a lower skirt of the state having the higher threshold voltage is referred to as a lower skirt fail bit BFB. In addition, the number of upper skirt fail bits TFB is referred to as an upper skirt fail bit number TFBC, and the number of lower skirt fail bits BFB is referred to as a lower skirt fail bit number BFBC.

The data allocation of the memory cell transistor MC is set such that only one bit is different between adjacent states. Therefore, in a case where the memory cell transistor MC stores multi-bit data, the CPU 230 can identify the type of fail bit detected by the error correction processing by a combination of data before error correction and data after error correction. In a case where the TLC method is used, for example, as listed below, an upper skirt fail bit TFB and a lower skirt fail bit BFB between two adjacent states are associated with each other.

(Example) If it is assumed that “uncorrected upper bit/uncorrected middle bit/uncorrected lower bit”→“corrected upper bit/corrected middle bit/corrected lower bit”: a corresponding fail bit type,
“110”→“111”: upper skirt fail bit TFB of “Er” state
“111”→“110”: lower skirt fail bit BFB of “A” state
“100”→“110”: upper skirt fail bit TFB of “A” state
“110”→“100” lower skirt fail bit BFB of “B” state
“000”→“100” upper skirt fail bit TFB of “B” state
“100”→“000” lower skirt fail bit BFB of “C” state
“010”→“000” upper skirt fail bit TFB of “C” state
“000”→“010” lower skirt fail bit BFB of “D” state
“011”→“010” upper skirt fail bit TFB of “D” state
“010”→“011” lower skirt fail bit BFB of “E” state
“001”→“011”: upper skirt fail bit TFB of “E” state
“011”→“001” lower skirt fail bit BFB of “F” state
“101”→“001” upper skirt fail bit TFB of “F” state
“001”→“101” lower skirt fail bit BFB of “G” state.

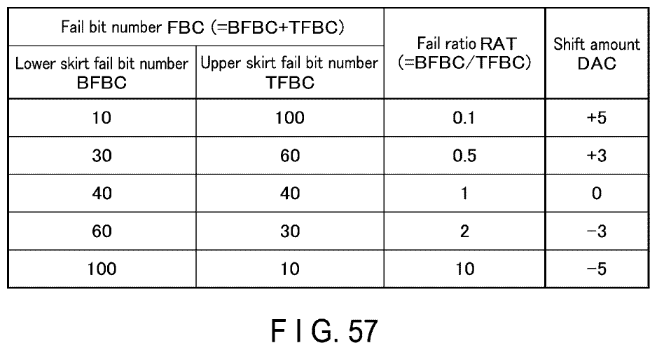

Next, the shift amount calculation processing will be described with reference to FIG. 57. FIG. 57 is a table illustrating an example of setting of the shift amount of the read voltage in the shift amount calculation processing of the memory system 1 according to the embodiment.

The number of fail bits FBC corresponds to the total number of fail bits between two adjacent states, and corresponds to the sum of the number of lower fail bits BFBC and the number of upper fail bits TFBC. The fail ratio RAT corresponds to a ratio between the number of bottom fail bits BFBC and the number of top fail bits TFBC between two adjacent states, and corresponds to, for example, a numerical value obtained by dividing BFBC by TFBC. The shift amount of the read voltage is managed by the DAC value.

As illustrated in FIG. 57, for example, in a case where BFBC=10 and TFBC=100, the number of fail bits FBC is “110”, and the fail ratio RAT is “0.1”. In a case where BFBC=30 and TFBC=60, the number of fail bits FBC is “90”, and the fail ratio RAT is “0.5”. In a case where BFBC=40 and TFBC=40, the number of fail bits FBC is “80”, and the fail ratio RAT is “1”. In a case where BFBC=60 and TFBC=30, the number of fail bits FBC is “90”, and the fail ratio RAT is “2”. In a case where BFBC=100 and TFBC=10, the number of fail bits FBC is “110”, and the fail ratio RAT is “10”.

As described above, the number of fail bits FBC tends to decrease as the fail ratio RAT approaches “1”, for example. In addition, in a case where the read voltage is shifted in the positive direction, it is considered that the lower skirt fail bit number BFBC increases and the upper skirt fail bit number TFBC decreases, and in a case where the read voltage is shifted in the negative direction, it is considered that the lower skirt fail bit number BFBC decreases and the upper skirt fail bit number TFBC increases.

Therefore, the shift amount of the read voltage is set in the positive direction in a case where the fail ratio RAT is smaller than “1”, and is set in the negative direction in a case where the fail ratio RAT is larger than “1”. Furthermore, the shift amount of the read voltage is set so as to increase as the fail ratio RAT deviates from 1. For example, in a case where RAT=0.1, the read voltage is shifted by +5 DAC. In a case where RAT=0.5, the read voltage is shifted by +3 DAC. In a case where RAT=1, the read voltage is not shifted. In a case where RAT=2, the read voltage is shifted by −3 DAC. In a case where RAT=10, the read voltage is shifted by −5 DAC.

Note that the shift amount of the read voltage with respect to the fail ratio RAT is not limited to the setting illustrated in FIG. 57. In the memory system 1 according to the embodiment, the shift amount of the read voltage in the shift amount calculation processing may be determined based on at least the fail ratio RAT.

The shift amount calculation processing described above is executed for each read voltage and for each group of the lower layer group GB, the middle layer group GM, and the upper layer group GT. Specifically, the CPU 230 extracts the threshold voltage distribution of the memory cell transistors MC for each group. Then, the CPU 230 executes the shift amount calculation processing for each threshold voltage distribution of the memory cell transistors MC extracted for each group.

In a case where the TLC method is used, the number of fail bits FBC corresponding to the read voltage AR corresponds to the sum of TFBC of the Er state and BFBC of the A state. The number of fail bits FBC corresponding to the read voltage BR corresponds to the sum of the TFBC of the A state and the BFBC of the B state. The number of fail bits FBC corresponding to the read voltage CR corresponds to the sum of the TFBC of the B state and the BFBC of the C state. The number of fail bits FBC corresponding to the read voltage DR corresponds to the sum of TFBC of the C state and BFBC of the D state. The number of fail bits FBC corresponding to the read voltage ER corresponds to the sum of the TFBC of the D state and the BFBC of the E state. The number of fail bits FBC corresponding to the read voltage FR corresponds to the sum of the TFBC of the E state and the BFBC of the F state. The number of fail bits FBC corresponding to the read voltage GR corresponds to the sum of TFBC of the F state and BFBC of the G state.

Then, the CPU 230 calculates a fail ratio RAT corresponding to the Er and the A states, a fail ratio RAT corresponding to the A and B states, a fail ratio RAT corresponding to the B and C states, a fail ratio RAT corresponding to the C and D states, a fail ratio RAT corresponding to the D and E states, a fail ratio RAT corresponding to the E and F states, and a fail ratio RAT corresponding to the F and G states for each group of the lower layer group GB, the middle layer group GM, and the upper layer group GT. Then, the shift amount of the read voltage with respect to each of the read voltages AR to GR is determined for each group. Further, the CPU 230 appropriately updates the shift value held in the shift value history table 221 based on the determined shift amount for each group of read voltages.

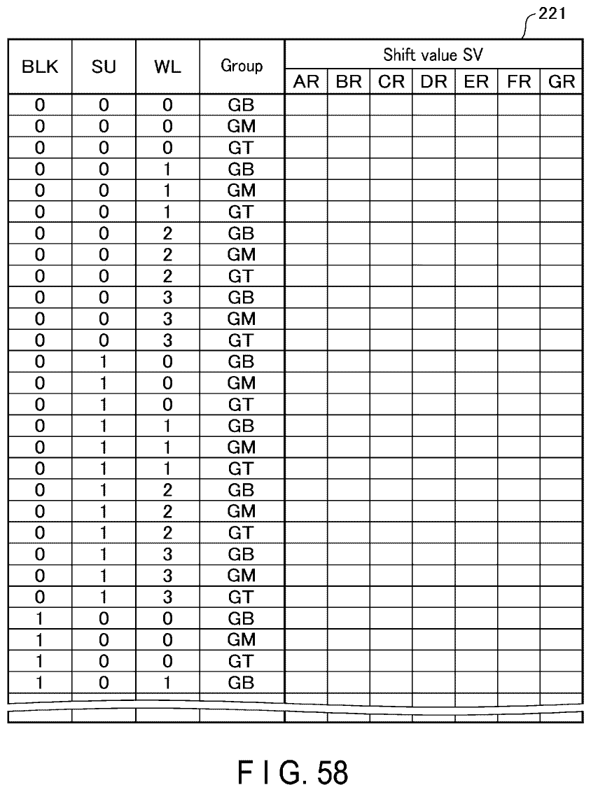

FIG. 58 is a table illustrating an example of the shift value history table 221 used in the memory system 1 according to the embodiment. As illustrated in FIG. 58, a shift value SV of the read voltage is managed, for example, for each combination of the block BLK, the string unit SU, the word line WL, and the group. The shift value SV corresponds to a correction value of each read voltage used in the read operation. For example, the shift value SV is managed by the DAC value for each read voltage.

In the read operation, the CPU 230 refers to the shift value SV for the lower layer group GB, the middle layer group GM, and the upper layer group GT corresponding to the selected word line WL (alternatively, the cell unit CU, the page), and uses a voltage shifted from the default voltage based on the shift value SV as the read voltage. In this case, for example, the CPU 230 causes the memory device 100 to execute the read operation to which the optimum shift value SV is applied for each group of the lower layer group GB, the middle layer group GM, and the upper layer group GT.

In the read operation for each page, only the shift value SV of the read voltage used in the read operation of the page to be read may be referred to. In addition, the memory system 1 may apply a common shift value SV to a plurality of word lines WL having similar characteristics. As a result, the memory system 1 can reduce the size of the shift value history table 221.

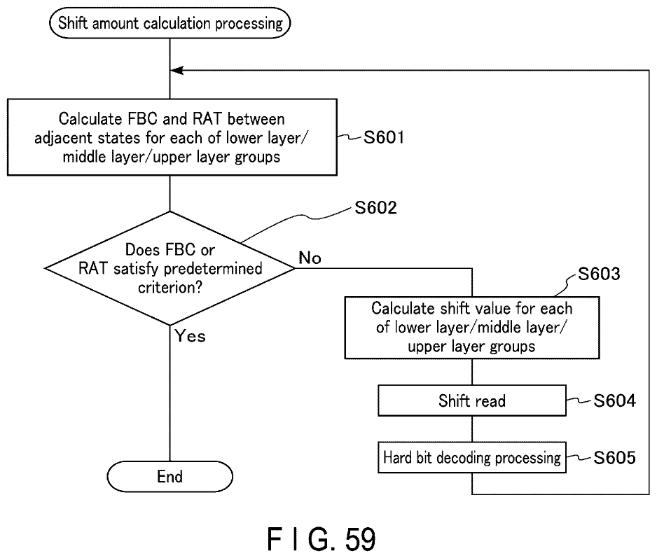

FIG. 59 is a flowchart illustrating an example of shift amount calculation processing of the memory system 1 according to the embodiment. The processing illustrated in the flowchart is executed by the CPU 230 of the memory controller 200 or the sequencer 15 of the memory device 100.

As illustrated in FIG. 59, in a case where the shift amount calculation processing is started, the CPU 230 calculates the number of fail bits FBC and the fail ratio RAT between adjacent states based on the results of the error correction processing in steps S504 and S505 (S601).

Next, the CPU 230 checks whether the calculated number of fail bits FBC or fail ratio RAT satisfies a predetermined criterion (S602). The predetermined criterion is set to each of the number of fail bits FBC and the fail ratio RAT. For example, a criterion of the number of fail bits FBC is that the FBC falls below a predetermined numerical value, and a criterion of the fail ratio RAT is that the RAT is included within a predetermined range including “1”.

In a case where the FBC or RAT does not satisfy the criterion in step S602 (S602, No), the CPU 230 calculates a shift value of the read voltage for each group of the lower layer group GB, the middle layer group GM, and the upper layer group GT based on the fail ratio RAT (S603). For example, the CPU 230 applies the method described with reference to FIG. 57 to the calculation of the shift value.

Next, the CPU 230 causes the memory device 100 to execute shift read using the calculated shift value of the read voltage (S604). This shift read is a read operation in which the read voltage to be used is shifted with respect to the shift read in steps S501, S502, and S503.

Next, the CPU 230 executes hard bit decoding processing on the reading result of the shift read (S605). In the error correction processing in step S605, since the reading result of the shift read using the corrected read voltage is used, the error correction succeeds with a higher probability than before the correction of the read voltage.

In a case where the hard bit decoding processing in step S605 is completed, the CPU 230 returns to the processing in step S601. That is, the CPU 230 repeats the processing of steps S601 to S605 as appropriate until the FBC or RAT satisfies the criterion in step S602.

In a case where the FBC or RAT satisfies the criterion in step S602 (S602, Yes), the CPU 230 ends the shift amount calculation processing and returns to the processing of step S509.

Note that the processing of steps S601 to S603 in the shift amount calculation processing described above is executed for each set read voltage. That is, in step S602, the read voltage satisfying the condition and the read voltage not satisfying the condition may be mixed. In this case, for example, the CPU 230 preferentially selects the next operation of step S602 in a case where the condition is not satisfied. As a condition for the processing to transition from step S602 to step S509, it may be set that the processing of steps S601 to S605 is repeated a predetermined number of times, a predetermined state passes the condition of step S602, or the like.

The number of fail bits FBC and the fail ratio RAT may be calculated by the error checking and correcting circuit 260. After step S603, the CPU 230 may update the shift value history table 221 based on the calculated shift value. In this case, the CPU 230 executes the read operation based on the shift value history table 221 in step S604.

### 3. Effects of Embodiments

According to the present embodiments, it is possible to provide a memory system capable of improving reliability of read data.

Hereinafter, effects of the memory system of the embodiment will be described.

For example, in a case where the sizes (gate length, gate width, etc.) of the plurality of memory cell transistors MC included in one cell unit CU in the memory device are different for each layer L, the threshold voltage distribution of the memory cell transistors MC may be different depending on the size. In addition, the state of the memory cell transistor MC adjacent to the reading target memory cell transistor MC may affect the threshold voltage of the reading target memory cell transistor MC. Therefore, in a case where the read operation is executed on the memory cell transistors MC having different threshold voltage distributions for each layer L under the same condition, there is a high possibility that erroneous reading occurs. In a case where the number of error bits of the read data increases due to erroneous reading, error correction cannot be performed by the ECC processing, and the reliability of the read data decreases.

In the configuration of the present embodiment, in the read operation, different reading conditions can be applied according to the state of the adjacent memory cell transistor MC for each layer L or for each group of the lower layer group GB, the middle layer group GM, and the upper layer group GT. Specifically, for each layer L or each group, the adjacency influence degree (rank) is set based on the state of the reading target memory cell transistor MC and the state of the adjacent memory cell transistor MC. Then, for each layer L or each group, the read operation is executed using the read voltage according to the adjacency influence degree. As a result, it is possible to use the optimum read voltage according to the adjacency influence degree for each layer or for each group, and thus, it is possible to reduce erroneous reading. Therefore, the reliability of the read data can be improved.

In the above embodiments, the case where the TLC method is applied to the data storage method has been exemplified, but the present invention is not limited thereto. For example, even in a case where the memory cell transistor MC stores 1 bit, 2 bits, or 4 bits or more of data, the operation described in the embodiment can be executed.

In the present specification, “connection” indicates electrical connection, and does not exclude that another element is interposed between elements, for example. The “H” level indicates a voltage at which the n-channel MOS transistor is turned on and the p-channel MOS transistor is turned off. The “L” level indicates a voltage at which the p-channel MOS transistor is turned on and the n-channel MOS transistor is turned off.

Although some embodiments of the present invention have been described, these embodiments have been presented as examples, and are not intended to limit the scope of the invention. These embodiments can be implemented in various other forms, and various omissions, substitutions, and changes can be made without departing from the spirit of the invention. These embodiments and modifications thereof are included in the scope and spirit of the invention and are included in the invention described in the claims and the equivalent scope thereof.

What is claimed is:

1. A memory system comprising:
a memory device; and
a controller configured to control the memory device, wherein
the memory device comprises:
a first memory cell provided in a first layer above a substrate;
a second memory cell provided in a second layer above the first layer;
a first word line connected to the first memory cell and the second memory cell;
a first bit line connected to the first memory cell; and
a second bit line connected to the second memory cell,
the controller is configured to:
store a first conversion table in which read bit locations of read data obtained by reading from the first memory cell and the second memory cell are associated with physical locations of the first memory cell and the second memory cell;
cause the memory device to execute reading using a first correction value of a first read voltage corresponding to the first layer on the first memory cell and the second memory cell;
receive first read data read using the first correction value from the memory device;
convert a read bit location of the first read data into physical locations of the first memory cell and the second memory cell with reference to the first conversion table;
acquire first data corresponding to the first layer from first conversion data converted into the physical locations;
cause the memory device to execute read using a second correction value of the first read voltage corresponding to the second layer on the first memory cell and the second memory cell;
receive second read data read using the second correction value from the memory device;
convert a read bit location of the second read data into the physical locations of the first memory cell and the second memory cell with reference to the first conversion table;
acquire second data corresponding to the second layer from second conversion data converted into the physical locations; and
merge the first data and the second data to acquire third data.

2. The memory system according to claim 1, wherein
the controller configured to convert the third data into a read bit location of read data for the first memory cell and the second memory cell with reference to the first conversion table.

3. The memory system according to claim 1, wherein
the controller further comprises a storage circuit that stores a first shift value associated with the first layer and the first read voltage and a second shift value associated with the second layer and the first read voltage, and
the controller configured to acquire the first correction value based on the first shift value and acquire the second correction value based on the second shift value.

4. The memory system according to claim 1, wherein
the memory device further comprises a plurality of memory cells connected to the first word line and including the first memory cell and the second memory cell, and
the controller is configured to:
cause the memory device to execute reading using a first shift read voltage, a second shift read voltage, a third shift read voltage, and a fourth shift read voltage different from each other on the plurality of memory cells, the second shift read voltage being lower than the first shift read voltage, the third shift read voltage being lower than the second shift read voltage, and the fourth shift read voltage being lower than the third shift read voltage;
receive a first shift read data read using the first shift read voltage from the memory device;
convert a read bit location of the first shift read data into physical locations of the first memory cell and the second memory cell with reference to the first conversion table;
acquire a first shift data corresponding to the first layer from the data converted into the physical locations;
receive a second shift read data read using the second shift read voltage from the memory device;
convert a read bit location of the second shift read data into physical locations of the first memory cell and the second memory cell with reference to the first conversion table;
acquire a second shift data corresponding to the first layer from the data converted into the physical locations;
calculate, from the first shift data and the second shift data, a first section cell number of memory cells transitioning from an on state to an off state in a case where a read voltage changes from the first shift read voltage to the second shift read voltage;
receive third shift read data read using the third shift read voltage from the memory device;
convert a read bit location of the third shift read data into physical locations of the first memory cell and the second memory cell with reference to the first conversion table;
acquire third shift data corresponding to the first layer from the data converted into the physical locations;
calculate, from the second shift data and the third shift data, a second section cell number of memory cells transitioning from the on state to the off state in a case where a read voltage changes from the second shift read voltage to the third shift read voltage;
receive fourth shift read data read using the fourth shift read voltage from the memory device;
convert a read bit location of the fourth shift read data into physical locations of the first memory cell and the second memory cell with reference to the first conversion table;
acquire fourth shift data corresponding to the first layer from the data converted into the physical locations;
calculate, from the third shift data and the fourth shift data, a third section cell number of memory cells transitioning from the on state to the off state in a case where a read voltage changes from the third shift read voltage to the fourth shift read voltage; and
calculate the first correction value based on the first section cell number, the second section cell number, and the third section cell number.

5. The memory system according to claim 1, wherein
the memory device further comprises a plurality of memory cells connected to the first word line and including the first memory cell and the second memory cell, and
the controller is configured to:
acquire, from the memory device, correspondence information between a read bit location of read data and physical locations of the plurality of memory cells in a case where a defective memory cell among the plurality of memory cells is not replaced with a redundancy memory cell;
acquire, from the memory device, redundancy information indicating that the defective memory cell in a case where there is replacement of the defective memory cell with a redundancy memory cell has been replaced with a redundancy memory cell; and
generate the first conversion table based on the correspondence information and the redundancy information.

6. The memory system according to claim 1, wherein
the memory device further comprises:
a first plurality of memory cells provided in the first layer and including the first memory cell and stacked in a first direction intersecting a main surface of the substrate; and
a second plurality of memory cells provided in the second layer and including the second memory cell and stacked in the first direction,
the first plurality of memory cells and the second plurality of memory cells are connected to the first word line, and
the controller is configured to:
store a second conversion table in which read bit locations of read data obtained by reading from the first plurality of memory cells and the second plurality of memory cells are associated with physical locations of the first plurality of memory cells and the second plurality of memory cells;
cause the memory device to execute reading using the first correction value of the first read voltage corresponding to the first layer on the first plurality of memory cells and the second plurality of memory cells;
receive a plurality of pieces of first read data read by using the first correction value from the memory device;
convert read bit locations of the plurality of pieces of first read data into physical locations of the first plurality of memory cells and the second plurality of memory cells with reference to the second conversion table;
acquire a plurality of pieces of first data corresponding to the first layer from a plurality of pieces of first conversion data converted into the physical locations;
cause the memory device to execute reading using the second correction value of the first read voltage corresponding to the second layer on the first plurality of memory cells and the second plurality of memory cells;
receive a plurality of pieces of second read data read using the second correction value from the memory device;
convert read bit locations of the plurality of pieces of second read data into physical locations of the first plurality of memory cells and the second plurality of memory cells with reference to the second conversion table;
acquire a plurality of pieces of second data corresponding to the second layer from a plurality of pieces of second conversion data converted into the physical locations; and
merge the plurality of pieces of first data and the plurality of pieces of second data to acquire fourth data.

7. The memory system according to claim 1, wherein
the first bit line is electrically connected to a first semiconductor layer disposed in the first layer, and the first semiconductor layer extends in a first direction parallel to a main surface of the substrate,
the second bit line is electrically connected to a second semiconductor layer disposed in the second layer, and the second semiconductor layer extends in the first direction, and
the first word line extends in a second direction intersecting the first semiconductor layer and the second semiconductor layer extending in the first direction.

8. A memory system comprising:
a memory device; and
a controller configured to control the memory device, wherein
the memory device comprises:
a first memory cell provided in a first layer above a substrate;
a second memory cell provided in a second layer above the first layer;
a first word line connected to the first and second memory cells;
a first bit line connected to the first memory cell; and
a second bit line connected to the second memory cell, and
the controller is configured to execute first reading processing of reading data stored in the first memory cell using a first read voltage based on the first layer in which the first memory cell is provided, a first state that is a state of the first memory cell, and a second state that is a state of the second memory cell.

9. The memory system according to claim 8, wherein
the first memory cell and the second memory cell are arranged in a first direction orthogonal to a main surface of the substrate, and are adjacent to each other.

10. The memory system according to claim 8, wherein
the controller is configured to read data stored in the second memory cell using a second read voltage based on the second layer in which the second memory cell is provided, the second state, and the first state.

11. The memory system according to claim 8, wherein
the memory device further comprises a third memory cell provided in a third layer that is above the first layer and below the second layer, and
the controller is configured to read data stored in the third memory cell using a third read voltage based on the third layer in which the third memory cell is provided, a third state which is a state of the third memory cell, the first state, and the second state.

12. The memory system according to claim 8, wherein
the controller is configured to:
stores a plurality of parameters according to the first layer in which the first memory cell is provided, each of a plurality of states corresponding to the first memory cell, and each of the plurality of states corresponding to the second memory cell,
acquires, in the first reading processing, a first parameter corresponding to the first layer in which the first memory cell is provided, the first state, and the second state from among the parameters, and
performs reading using the first read voltage based on the first parameter.

13. The memory system according to claim 8, wherein
the controller further comprises a storage circuit that stores a shift value indicating a correction value of a read voltage used in the read operation, and
the controller configured to update the shift value stored in the storage circuit based on the first read voltage.

14. The memory system according to claim 8, wherein
the controller is configured to:
execute second reading processing of reading data stored in the first memory cell and the second memory cell before the first reading processing, and
determine the first state of the first memory cell and the second state of the second memory cell by the second reading processing.

15. The memory system according to claim 8, wherein
the memory device further comprises a plurality of memory cells connected to the first word line and including the first memory cell and the second memory cell,
the controller configured to cause n-bit data to be stored in the plurality of memory cells by causing the n-bit data to correspond to 2ⁿ threshold voltage regions that are first to 2ⁿ-th threshold voltage regions whose regions are defined in ascending order of voltages, in which in a case where k is an integer larger than 1 and smaller than 2ⁿ, a voltage of a (k+1)-th threshold voltage region is higher than a voltage of a k-th threshold voltage region,
the first state corresponds to any one of first to 2ⁿ-th threshold voltage regions, and
the second state corresponds to any one of first to 2ⁿ-th threshold voltage regions.

16. The memory system according to claim 8, wherein
the controller is configured to determine, in the first reading processing, a first parameter based on the first layer, the first state, and the second state, and determine the first read voltage based on the first parameter.

17. The memory system according to claim 16, wherein
the first state corresponds to an x-th threshold voltage region among first to 2ⁿ-th threshold voltage regions (x is an integer of 1 or more and 2ⁿ or less),
the second state corresponds to a y-th threshold voltage region among the first to 2ⁿ-th threshold voltage regions (y is an integer of 1 or more and 2ⁿ or less), and
the first parameter in a case where the y is larger than the x is different from the first parameter in a case where the y is smaller than the x.

18. The memory system according to claim 8, wherein
the memory device further comprises a plurality of memory cells connected to the first word line and including the first memory cell and the second memory cell, and
the controller is configured to
generate correspondence information indicating a correspondence relationship between a first bit location and a second bit location among bit locations of read data from the plurality of memory cells, and a physical location of the first memory cell and a physical location of the second memory cell, and
identify that data at the first bit location corresponds to the first layer and data at the second bit location corresponds to the second layer based on the correspondence information.

19. The memory system according to claim 18, wherein
the memory device is configured to store information indicating that two memory cells of the plurality of memory cells are replaced, and
the controller is configured to, in a case where the information indicates that the first memory cell is replaced with a third memory cell among the plurality of memory cells, generate the correspondence information in such a way that the correspondence information indicates a correspondence relationship between the first bit location and the second bit location among bit locations of the read data and a physical location of the third memory cell and a physical location of the second memory cell.

20. The memory system according to claim 8, wherein
the memory device comprises:
a third memory cell provided on the substrate; and
a memory cell array that stores a table that holds a first address corresponding to the first memory cell and a third address corresponding to the third memory cell in association with each other in a case where the first memory cell is replaced with the third memory cell, and
the memory device is configured to, in a case where the first reading processing is executed,
output data read from the second memory cell if a second address corresponding to the second memory cell does not match the first address held in the table, and
output data read from the third memory cell if the first address corresponding to the first memory cell matches the first address held in the table.

21. The memory system according to claim 1, wherein
in the third data, the physical locations of the first memory cell and the second memory cell are reproduced.

22. The memory system according to claim 6, wherein
in the fourth data, the physical locations of the first plurality of memory cells and the second plurality of memory cells are reproduced.
